(19) United States
(12) Patent Application Publication
(10) Pub. No.: US 2012/0206566 A1
(43) Pub. Date: Aug. 16, 2012

(54) METHODS AND SYSTEMS FOR RELATING TO THE CAPTURE OF MULTIMEDIA CONTENT OF OBSERVED PERSONS PERFORMING A TASK FOR EVALUATION

(75) Inventor: Inna Fedoseyeva, San Francisco, CA (US)

(73) Assignee: Teachscape, Inc., San Francisco, CA (US)

(21) Appl. No.: 13/271,224

(22) Filed: Oct. 11, 2011

Related U.S. Application Data
(60) Provisional application No. 61/392,017, filed on Oct. 11, 2010.

(51) Int. Cl. H04N 7/00; H04R 29/00; H03G 3/20

(52) U.S. Cl. 348/38; 381/57; 348/36; 348/E07.001

(57) ABSTRACT

A computer implemented method for recording of audio for use in remotely evaluating performance of a task by of one or more observed persons, the method comprises: receiving a first audio input from a first microphone recording observed persons performing the task; receiving a second audio input from a second microphone recording persons reacting to the performance; outputting for display a first sound meter corresponding to the volume of the first audio input; outputting for display a second sound meter corresponding to the volume of the second audio input; providing a first volume control and a second volume control, wherein a first volume of the first audio input and a second volume of the second audio input are amplified volumes, wherein, the first and second sound meters each comprises an indicator for suggesting a volume range suitable for recording the observed persons and the persons reacting to the performance.

This application claims the benefit of U.S. Provisional Application No. 61/392,017 filed Oct. 11, 2010, which is incorporated in its entirety herein by reference.

This application is related to the following U.S. patent applications filed concurrently herewith, each of which is incorporated in its entirety herein by reference: U.S. patent application Ser. No. ______ (“METHODS AND SYSTEMS FOR SHARING CONTENT ITEMS RELATING TO MULTIMEDIA CAPTURED AND/OR DIRECT OBSERVATIONS OF PERSONS PERFORMING A TASK FOR EVALUATION”, Attorney Docket No. 9182-100047); U.S. patent application Ser. No. ______ (“METHODS AND SYSTEMS FOR MANAGEMENT OF EVALUATION METRICS AND EVALUATION OF PERSONS PERFORMING A TASK BASED ON MULTIMEDIA CAPTURED AND/OR DIRECT OBSERVATIONS”, Attorney Docket No. 9182-100048); U.S. patent application Ser. No. ______ (“METHODS AND SYSTEMS FOR USING MANAGEMENT OF EVALUATION PROCESSES BASED ON MULTIPLE OBSERVATIONS OF AND DATA RELATING TO PERSONS PERFORMING A TASK TO BE EVALUATED”, Attorney Docket No. 9182-100049); and U.S. patent application Ser. No. ______ (“METHODS AND SYSTEMS RELATING TO CODING AND/OR SCORING OF OBSERVATIONS OF AND CONTENT OBSERVED PERSONS PERFORMING A TASK TO BE EVALUATED”, Attorney Docket No. 9182-100050).

### BACKGROUND OF THE INVENTION

1. Field of the Invention

The present invention relates generally to observational assessment systems, and more specifically relates to observational assessment systems useful for evaluative purposes in an environment.

2. Background

Observation based evaluation has been an important tool in the training and development of various skills sets. Traditionally, such observations are performed in person and in situ.

In an in-person observation, an evaluator would enter the environment where the person or persons being evaluated are performing a task, and observe the performance of the task and any other persons participating in the task. The evaluator would then provide feedback and evaluation based on the in-person observation to help the person being evaluated identify areas needing additional development. One obstacle present in this traditional method of observation is that the presence of the evaluator sometimes becomes obtrusive to the environment in which the task is performed. For example, in the education environment, the presence of an evaluator could cause the students to behave differently knowing that someone other than the teacher is observing the class. As such, an in-person observation conducted for evaluation purposes may not accurately reflect the subject's abilities and skills. The presence of multiple observers can further compound this problem.

Methods for a live video stream observation have been described in, for example, U.S. Application 2009/0215018 to Edmondson et al (hereinafter the “Edmondson et al.”) Edmondson et al. describes a system for performing remote observation which enables the immediate sharing of metadata and performance feedback between the observer(s) and the observed.

### SUMMARY OF THE INVENTION

A computer implemented method for recording of audio for use in remotely evaluating performance of a task by of one or more observed persons, the method comprises: receiving a first audio input from a first microphone recording the one or more observed persons performing the task; receiving a second audio input from a second microphone recording one or more persons reacting to the performance of the task; outputting, for display on a display device, a first sound meter corresponding to the volume of the first audio input; outputting, for display on the display device, a second sound meter corresponding to the volume of the second audio input; providing a first volume control for controlling an amplification level of the first audio input and a second volume control for controlling an amplification level of the second audio input, wherein a first volume of the first audio input and a second volume of the second audio input are amplified volumes, wherein, the first sound meter and the second sound meter each comprises an indicator for suggesting a volume range suitable for recording the one or more observed persons performing the task and the one or more persons reacting to the performance of the task for evaluation.

In another embodiment, a computer system for recording a video for use in remotely evaluating performance of one or more observed persons, the system comprises: a panoramic camera system for providing a first video feed, the panoramic camera system comprising a first camera and a convex mirror, wherein an apex of the convex mirror points towards the first camera; a user terminal for providing a user interface for calibrating a processing of the first video feed; a memory device for storing calibration parameters received through the user interface, wherein the calibration parameters comprise a size and a position of a capture area within the first video feed; and a display device for displaying the user interface and the first video feed, wherein, the calibration parameters stored in the memory device during a first session are read by the user terminal during a second session and applied to the first video feed.

### BRIEF DESCRIPTION OF THE DRAWINGS

The aspects, features and advantages of several embodiments of the present invention will be more apparent from the following more particular description thereof, presented in conjunction with the following drawings.

FIG. 1 illustrates a diagram of a general system for use in capturing, processing, sharing, and evaluating content corresponding to a multi-media observation of the performance of a task to be evaluated, according to one or more embodiments.

FIG. 2 illustrates a diagram of a system for use in capturing, processing, sharing, and evaluating content corresponding to a multi-media observation of the performance of a task to be evaluated, according to one or more embodiments.

FIG. 3 illustrates a diagram of a flow process for capturing, processing, sharing, and evaluating content of a multi-media observation, according to one or more embodiments.

FIG. 4 illustrates a diagram of the functional application components of a remotely hosted application, such as a web application, according to one or more embodiments.

FIG. 5 illustrates an exemplary embodiment of a process for displaying multi-media content to a user accessing a web application, according to one or more embodiments.

FIG. 6 illustrates a diagram of the functional application components of a capture application, according to one or more embodiments.

FIG. 7A illustrates an exemplary system diagram and flow of a multimedia capture application, according to one or more embodiments.

FIG. 7B illustrates another exemplary system diagram and flow of a multimedia capture application, according to one or more embodiments.

FIG. 8 illustrates an exemplary flow diagram of a multimedia capture application for processing and uploading multi-media content, according to one or more embodiments.

FIGS. 9-15 illustrate an exemplary set of user interface display screens presented to a user via a multimedia capture application according to one or more embodiments.

FIGS. 16-26 illustrate another exemplary set of user interface display screens presented to a user via a multimedia capture application according to one or more embodiments.

FIGS. 27-39 illustrate an exemplary set of user interface display screens of a web application that are displayed to the user, according to one or more embodiments.

FIG. 40 illustrates a diagram of a general system for use with a direct observation of the performance of a task including one or more of recording, processing, commenting, sharing and evaluating the performance of the task according to one or more embodiments.

FIG. 41 illustrates an exemplary panoramic video capture hardware device including a video camera and panoramic reflector for use in one or more embodiments.

FIG. 42 illustrates a simplified block diagram of a processor-based system for implementing methods described according to one or more embodiments.

FIG. 43 illustrates a flow diagram of a process useful in performing a formal evaluation in accordance with one or more embodiments.

FIG. 44 illustrates a flow diagram of a process useful in performing an informal evaluation in accordance with one or more embodiments.

FIG. 45A illustrates an exemplary general system for performing video capture, according to one or more embodiments.

FIGS. 45B and 45C illustrate exemplary images for before and after a panoramic camera calibration, according to one or more embodiments.

FIG. 46 illustrates an exemplary system for audio capture, according to one or more embodiments.

FIG. 47 illustrates an exemplary interface display screen for video and audio capture, according to one or more embodiments.

FIG. 48 illustrates a flow diagram of a process for previewing a video capture, according to one or more embodiments.

FIG. 49 illustrates a flow diagram of a process for creating video segments, according to one or more embodiments.

FIG. 50 illustrates and exemplary interface display screen for creating video segments, according to one or more embodiments.

FIGS. 51A and 51B illustrate flow diagrams of processes for customizing an evaluation rubric, according to one or more embodiments.

FIG. 52 illustrates a flow diagram of a process for adding free form comments to a video capture, according to one or more embodiments.

FIG. 53 illustrates an exemplary interface display screen for adding free form comments to a video capture, according to one or more embodiments.

FIG. 54 illustrates a flow diagram of a process for sharing a video, according to one or more embodiments.

FIG. 55 illustrates a flow diagram of a process for changing camera views, according to one or more embodiments.

FIGS. 56A and 56B illustrate two exemplary camera view display screens, according to one or more embodiments.

FIG. 57 illustrates a flow diagram of a process for sharing a comment on a captured video, according to one or more embodiments.

FIG. 58 illustrates a flow diagram of a process for assigning a rubric node to a comment, according to one or more embodiments.

FIG. 59 illustrates an exemplary interface display screen for assigning a rubric node to a comment, according to one or more embodiments

FIG. 60 illustrates a structure of an exemplary performance evaluation rubric hierarchy, according to one or more embodiments.

FIG. 61A illustrates a flow diagram of a process for navigating a hierarchical evaluation rubric, according to one or more embodiments.

FIG. 61B illustrates an exemplary interface display screen for dynamically navigating a performance rubric, according to one or more embodiments.

FIG. 62A illustrates a flow diagram of a process for managing an evaluation workflow, according to one or more embodiments.

FIGS. 62B and 62C illustrate exemplary interface screen displays of a workflow dashboard application, according to one or more embodiments.

FIG. 63 illustrates a flow diagram of a process for associating observations to a workflow, according to one or more embodiments.

FIGS. 64A and 64B illustrate flow diagrams of processes for generating weighted scores from one or more observations, according to one or more embodiments.

FIG. 65 illustrates a flow diagram of a process for suggesting professional development (PD) resources based on observation scores, according to one or more embodiments.

FIG. 66 illustrates a flow diagram of a process for sharing a collection, according to one or more embodiments.

FIG. 67 illustrates a flow diagram of a process for displaying sound meters according to one or more embodiments.

FIG. 68 illustrates a flow diagram of a process for adding a video capture in a professional development resource library, according to one or more embodiments.

FIGS. 69A and 69B illustrate flow diagrams of a evaluation process involving a direct observation, according to one or more embodiments.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention.

### DETAILED DESCRIPTION

The following description is not to be taken in a limiting sense, but is made merely for the purpose of describing the general principles of exemplary embodiments. The scope of the invention should be determined with reference to the claims.

In some embodiments, this application variously relates to systems and methods for capturing, displaying, critiquing, evaluating, scoring, sharing, analyzing one or more of multimedia content, instruments, artifacts, documents, and observer and/or participant comments relating to one or both of multimedia captured observations and direct observations of the performance of a task by one or more observed persons and/or one or more persons participating, witnessing, reacting to and/or engaging in the performance of the task, wherein the performance of the task is to be evaluated. In one embodiment, the content refers to audio, video and image content captured in an instructional environment, such as a classroom or other education environment. In some embodiments, the content may comprise a collection of content including two or more videos, two or more audios, photos and documents. In some embodiments, the content comprises notes and comments taken by the observer during a direct observation of the observed person/s performing the task.

Throughout the specification, several embodiments of methods and systems of are described with respect to capturing, viewing, analyzing, evaluating and sharing multimedia content in a teaching environment. However, it should be understood by one skilled in the art that the described embodiments may be used in any context with respect to providing a user with means for recording and analyzing multi-media content or a live or direct observation of a person performing a task to be evaluated.

Throughout the specification, several embodiments of methods and systems of are described as functions for evaluating a captured video displayed in the same application. In some embodiments, the functions can be applied to multiple modalities of observation as well as using multiple evaluation instruments, such as captured observations recorded for later viewing and analysis and/or direct observations, such as real time observations in which the observers are located at the location where the task is being performed, or real time remote observations in which the performance of the task is streamed or provided in real-time or near real-time to observers not at the location of the task performance. For example, some evaluation functions can be used during a live observation conducted in person and in situ to record observations made during the live observation session. In some embodiments, the ability to make use of multiple observations of the task, as well as multiple criteria to evaluate the observed task performance, result in increased flexibility and improved ability to evaluate the performance of the task depending in some cases, on the particulars of the task at hand.

In accordance with some embodiments in which the systems and methods are applied in an educational environment, one or more embodiments allow for the performance of activities or tasks that may to be useful to evaluate and improve the performance of the task, e.g., to evaluate and improve teaching and learning. For example, in some embodiments, teachers, principals, administrators, etc. can observe classroom teaching events in a non-obtrusive manner without having to be physically present in the classroom. In some embodiments, it is felt that such teaching experiences are more natural since evaluating users are not present in the classroom during the teaching event. In some embodiments, a direct observation (e.g., direct in classroom observation or remote real-time observation) can be conducted in addition to the video capture observation to provide a more complete evaluation of the performance. Further, in some embodiments, multiple different users are able to view the same captured in-classroom teaching event from different locations, at any time, providing for greater convenience and greater opportunities for collaborative analysis and evaluation. In some embodiments, users can combine multiple artifacts including one or more of video data, imagery, audio data, metadata, documents, lesson plans, etc into a collection or observation. Further, such observations may be uploaded from storage at a server for later retrieval for one or more of sharing, commenting, evaluation and/or analysis. Still further, in some embodiments, while a teacher can use the system to view and review their own teaching techniques.

In some embodiments, the described systems and methods may be applied in other environments in which a person or persons could also benefit from being observed and evaluated by person or persons with related expertise and knowledge. For example, the systems and methods may be applied in the training of counselors, trainers, speakers, sales and customer service agents, medical service providers, etc.

### System Overview

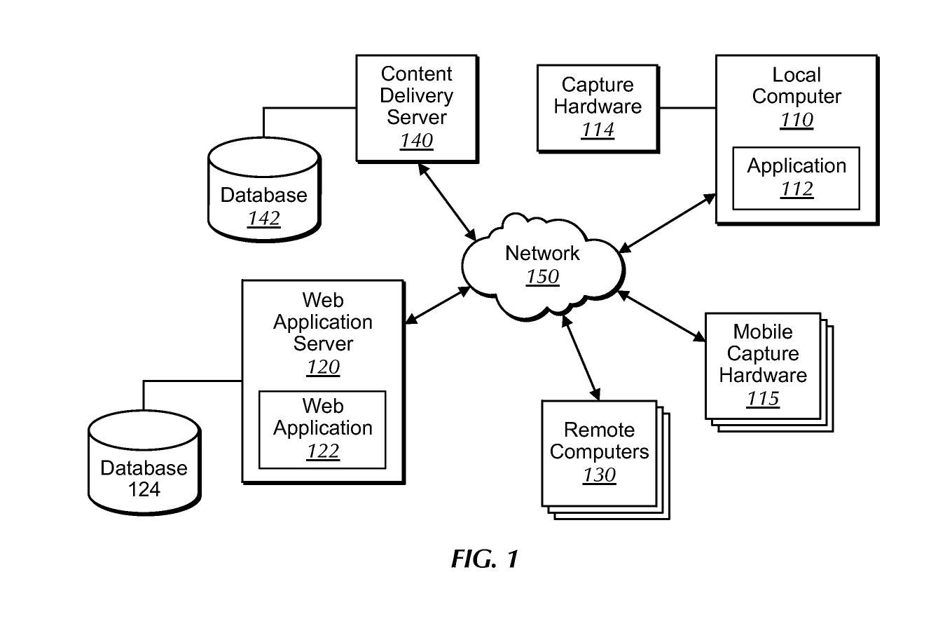

FIG. 1 illustrates the system 100 according to several embodiments. As shown, the system comprises a local computer 110 (which may be generically referred to as a computer device, a computer system and/or a networked computer system, for example), a web application server 120 (which may be generically referred to as a remote server, a computer device, a computer system and/or a networked server system, for example), one or more remote computers 130 (which may be generically referred to as a remote user devices, remote computer devices, and/or a networked computer devices, for example), and a content delivery server 140 (which may be generically referred to as a remote storage device, a remote database, and so on). As illustrated, in some embodiments, the local computer 110, mobile capture hardware 115, web application server 120, remote computers 130 and content delivery server 140 are in communication with one another over a network 150. The network 150 may be one or more of any wired and/or wireless point-to-point connection, local area network, wide area network, internet, and so on.

In one embodiment, the user computer 110 has stored thereon software for executing a capture application 112 for receiving and processing input from capture hardware 114 which includes one or more capture hardware devices. In one embodiment, the capture application 112 is configured to receive input from the capture hardware 114 and provide a multi-media collection that is transferred or uploaded over the network to the content delivery server 150. In one embodiment, the capture application 112 further comprises one or more functional application components for processing the input from the capture hardware before the content is sent to the content delivery server 140 over the network. In one or more embodiments, the capture hardware 114 comprises one or more input capture devices such as still cameras, video cameras, microphones, etc., for capturing multi-media content. In other embodiments, the capture hardware 114 comprises multiple cameras and multiple microphones for capturing video and audio within an environment proximate the capture hardware. In some embodiments, the capture hardware 114 is proximate the local computer 110. In one embodiment, for example, the capture hardware 114 comprises two cameras and two microphones for capturing two different sets of video and two different sets of audio. In one embodiment, the two cameras may comprise a panoramic (e.g., 360 degree view) video camera and a still camera.

In one or more embodiments, the mobile capture hardware 115 comprises one or more input capture devices such as mobile cameras, mobile phones with video or audio capture capability, mobile digital voice recorders, and/or other mobile video/audio mobile devices with capture capability. In one embodiment, the mobile capture hardware may comprise a mobile phone such as an Apple® iPhone® having video and audio capture capability. In another embodiment the mobile capture hardware 115 is an audio capture device such as an Apple® iPod® or another iPhone. In one embodiment, the mobile capture hardware comprises at least two mobile capture devices. In one embodiment, for example, the mobile capture hardware comprises at least a first mobile device having video and audio capturing capability and a second mobile device having audio capturing capability. In one embodiment, the mobile capture hardware 115 is directly connected to the network and is able to transmit captured content over the network (e.g., using a Wifi connection to the network) to the content delivery server 140 and/or the web application server 120 without the need for the local computer 110. In some embodiments, the capture hardware 115 comprises at least two devices having the capability to communicate with one another. For example, in one embodiment each mobile capture device comprises Bluetooth capability for connecting to another mobile capture device and transmits information regarding the capture. For example, in one embodiment, the devices may communicate to transmit information that is necessary to synchronize the two devices.

In one embodiment, the local computer 110 is in communication with the content delivery server 150 and is configured to upload the output of the capture hardware 114 processed by the capture application 112 to the content delivery server 140.

The web application server 120 has stored thereon software for executing a remotely hosted application, such as a web application 122. In some embodiments, the web application server 120 further comprises one or more databases 124. In some embodiments, the database 124 is part of the web application server 120 or may be remote from the web application server 120 and may provide data to the web application server 120 over the network 150. In one embodiment, the web application 122 is configured to receive the content collection or observation uploaded from the user computer 110 to the content delivery server 140 by accessing the content delivery server 140 over the network. In one embodiment, the web application 122 may comprise one or more functional application components for allowing one or more users to interact with the content collections uploaded from the user computer 110. That is, in one or more embodiments, the remote computers 130 are able to access the content collection or observation captured at the user computer 110 by accessing the web application 122 hosted by the web application server 120 over network 150.

In one embodiment, the one or more local computers 130 comprise personal computers in communication with the web application server 120 or other computing devices, including, but not limited to desktop computers, laptop computers, personal data assistants (PDAs), smartphones, touch screen computing devices, handheld computing devices, or any other computing device having functionality to couple to the network 150 and access the web application 122. The user computers 130 have web browser capabilities and are able to access the web application 122 using a web browser to interact with captured content uploaded from the local computer 110. In some embodiments, one or more of the remote computers 130 may further include capture hardware and have installed therein a capture application and may be able to upload content similar to the local computer 110.

In one or more embodiments, in addition to the capture application, one or more of the user computer 110 and the remote computers 130 may further store software for performing one or more functions with respect to content captured by the capture application locally and without being connected to the network 150 and/or the application server 120. In one embodiment, this additional capability may be implemented as part of the capture application 112 while in other embodiments, a separate application may be installed on the computer for allowing the computer to interact with the captured content without being connected to the web server. In some embodiments for example, users may be able to edit content, e.g., edit the captured content, metadata, etc. in the local application and the edited content may then be synched with the web application server 120 and content delivery server 140 the next time the user connects to the network. Editing content, in some cases, may comprise altering properties of the captured content itself (e.g., changing video display contrast ratio, extracting portions of the content, indicating start and stop times defining a portion of the captured content, etc.). In other cases, editing means adding information to, tagging, associating comments, information, documents, etc to the content and/or a portion thereof. In some embodiments, the combination of one or more of captured multimedia content, metadata, tags, comments, added documents/information may be referred to as an observation. In one embodiment, the actual original video/audio content is protected and cannot be edited after the capture is complete. In some embodiments, copies of the content may be provided for editing for several purposes such as creating a preview segment or for later creation of collections and segments in the web application, and the actual original video/audio content is retained.

In one embodiment, it may be desirable to limit editing content such that content may not be edited after content has been captured. That is, in some embodiments, the captured content and the settings associated with the capture such as brightness, focus, etc., may not be altered once the content has been captured. In another embodiment, certain settings of the captured content may be altered post-capture, while the actual content and/or other content settings are protected and therefore may not be modified once the content has been captured. In one embodiment, while content cannot be edited, post capture photos and or other documents may be associated with the content after the content has been captured. In other embodiments, a user may be able to edit the content including one or more settings after the capture has been completed and/or content has been uploaded. In some cases, at least a portion of the observation is uploaded to the content delivery server 140 for later retrieval.

In one or more embodiments, the content delivery server 140 comprises a database 142 for storing the uploaded content collections received from the local computer 110. In one embodiment, the web application server 120 is in communication with the content delivery server 140 and accesses the stored content to provide the stored content to one or more users of the local computer 110 and the remote computers 130. While the content delivery server 140 is shown as being separate from the web application server 120, in one or more embodiments, the content delivery server and web application may reside on same server and/or location.

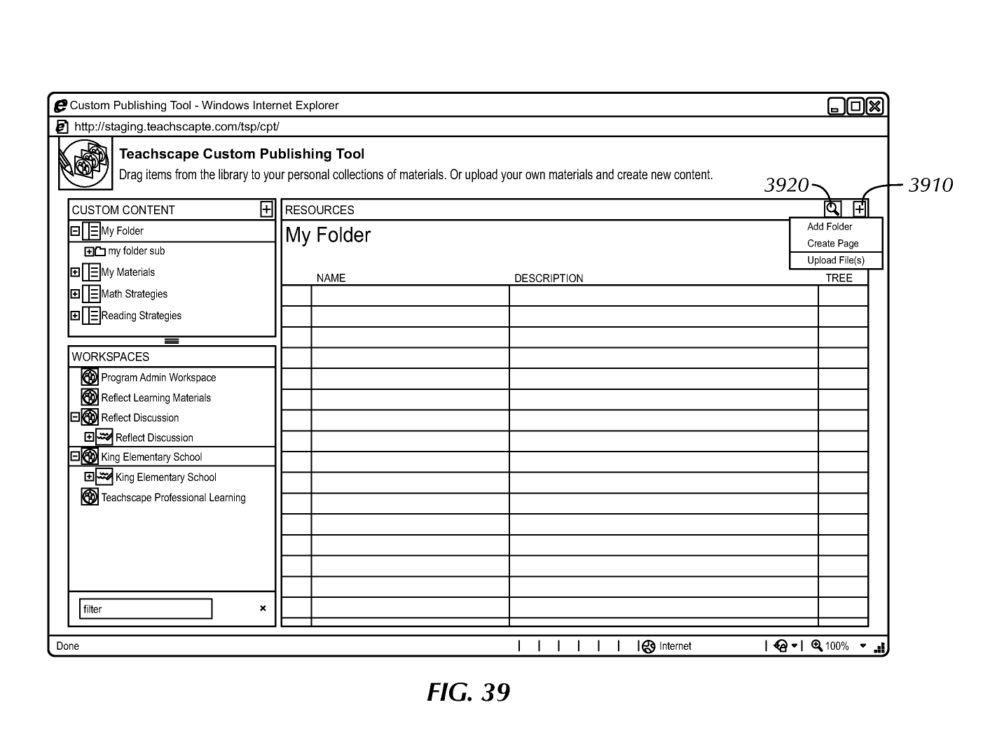

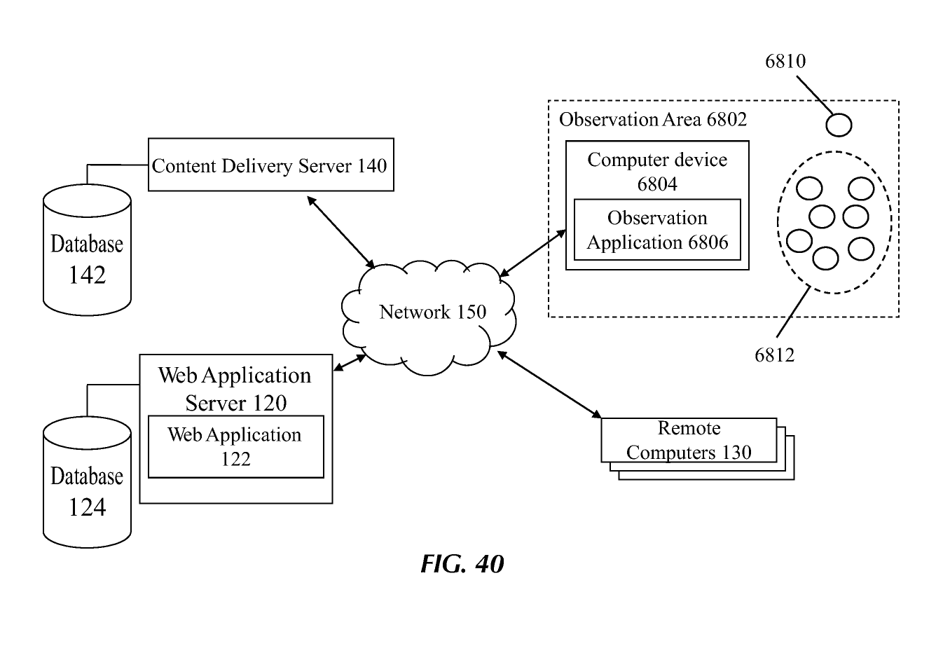

FIG. 40 illustrates a diagram of another general system for recording, processing, sharing, and evaluating a live or direct observation, according to one or more embodiments. In one form, a live observation or a direct observation is observation observed and at least partially processed during the real-time or near real-time performance of a task. In this illustrated embodiment, the observation is conducted in the environment the observed person performs the task. In other embodiments, live observations may be conducted through a live video stream of the performance of the task such that the observer is not physically present at the location of the task performance. Throughout the descriptions, live observation is sometimes also referred to as direct observation. The system comprises a computer device 6804 (which may be generically referred to as a local computer, a computer system and/or a networked computer system, for example), a web application server 120 (which may be generically referred to as a remote server, a computer device, a computer system and/or a networked server system, for example), one or more remote computers 130 (which may be generically referred to as a remote user devices, remote computer devices, and/or a networked computer devices, for example), and a content delivery server 140 (which may be generically referred to as a remote storage device, a remote database, and so on). As illustrated, in some embodiments, the computer device 110, web application server 120, remote computers 6804, and content delivery server 140 are in communication with one another over a network 150. The network 150 may be one or more of any wired and/or wireless point-to-point connection, local area network, wide area network, internet, and so on. The web application server 120, the web application 122, the remote computer 130, the content delivery sever 140, the database 142, and the network 150 are previously described with reference to FIG. 1 and a detailed description is there omitted herein.

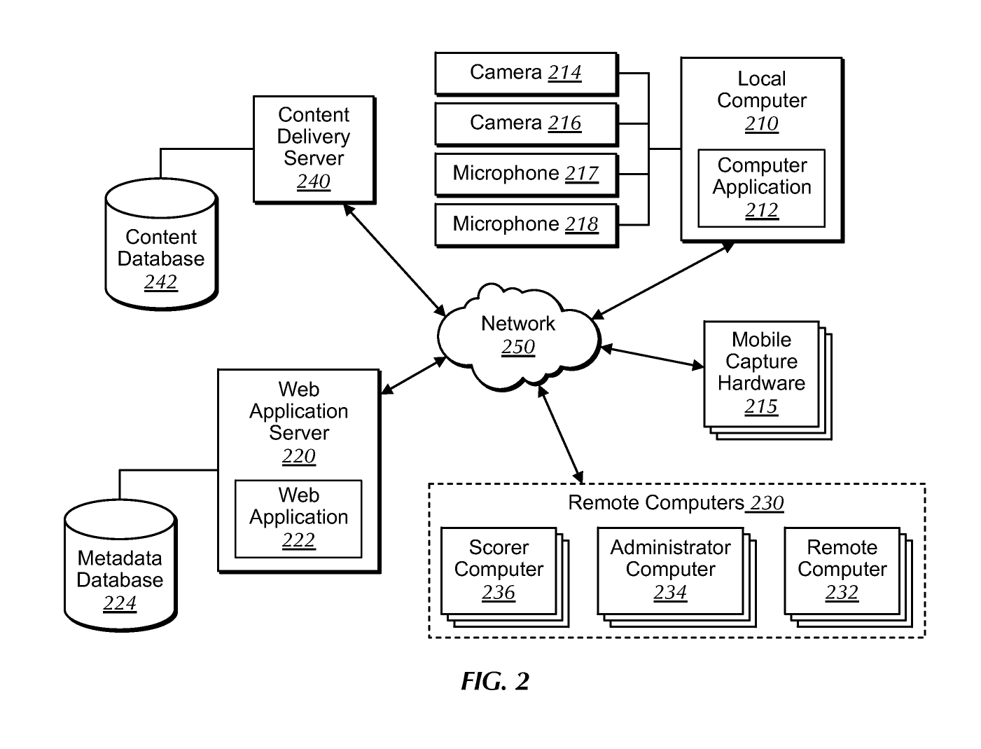

As illustrated in FIG. 40, the computer device 6804 is situated in an observation area 6802 with one or more observed persons 6810 performing a task to be evaluated, and with one or more audience persons 6812 reacting to the performance of the task. For example, as applied to an education environment, the observation area 6802 may be a classroom, the one or more observed persons 6810 may be one or more educators teaching a lesson, and the one or more audience persons 6812 may be students. In some embodiments, the computer device 6804 may be a network connectable (e.g., web accessible) device, such as a notebook computer, a netbook computer, a tablet computer, or a smart phone. The computer device 6804 executes an observation application 6806 which implements functionalities that facilitates the observation and evaluation of the performance. In some embodiments, the application 6806 allows the evaluator to enter comments regarding the live performance of the task, assign rubric nodes to the comments, capture video and audio segments of the performance of the task, and/or take photographs of the performance of the task. In some embodiments, the observation application 6806 is an offline application, capable of functioning independent of connectivity to the network 150. The off-line application may store the data entered and captured and/or attached during an observation session, and upload the data to the content delivery data server 140 at a subsequent time. In some embodiments, the observation application 6806 is incorporated in the web application 122, and is accessed on the computer 6804 through a network accessing application such as a web browser. For example, in one embodiments, the computer device is a standard web accessible device, such as an APPLE IPAD, and the observation application 6806 is a downloaded program or app installed which is configured to access software serving the user interface needed to allow the observer to comment on, evaluate, attach documents and other artifacts to, for example, a direct observation. In some embodiments, the observation application 6806 can be used to record notes and assign nodes to rubrics during a viewing of a live streaming video or a captured video of the performance of the task. In some embodiments, the observation application 6806 further includes workflow management functionalities. One or more of the features and functions described herein may apply to the systems relating to one or both of multimedia captured observations or direction observations. In some embodiments, systems involving components of both FIGS. 1 and 2 may be implemented such that a captured observation and a direct observation are conducted relative to the task being performed.

FIG. 2 illustrates a more detailed system diagram of a system 200 for use in an education environment. In some embodiments, the education environment is a classroom environment for any pre-Kindergarten through grade 12 and any post-secondary education program environment. The system 200 comprises a local computer 210 (which may be generically referred to as a computer device, a computer system and/or a networked computer system, for example), mobile capture hardware 215, a web application server 220 (generically, a remote server, a computer device, a computer system and/or a networked server system, and so on), one or more remote computers 230 (which may be generically referred to as a remote user devices, remote computer devices, and/or a networked computer devices, for example), and a content delivery server 240 (which may be generically referred to as a remote storage device, a remote database, and so on) in communication with one another over a network 250.

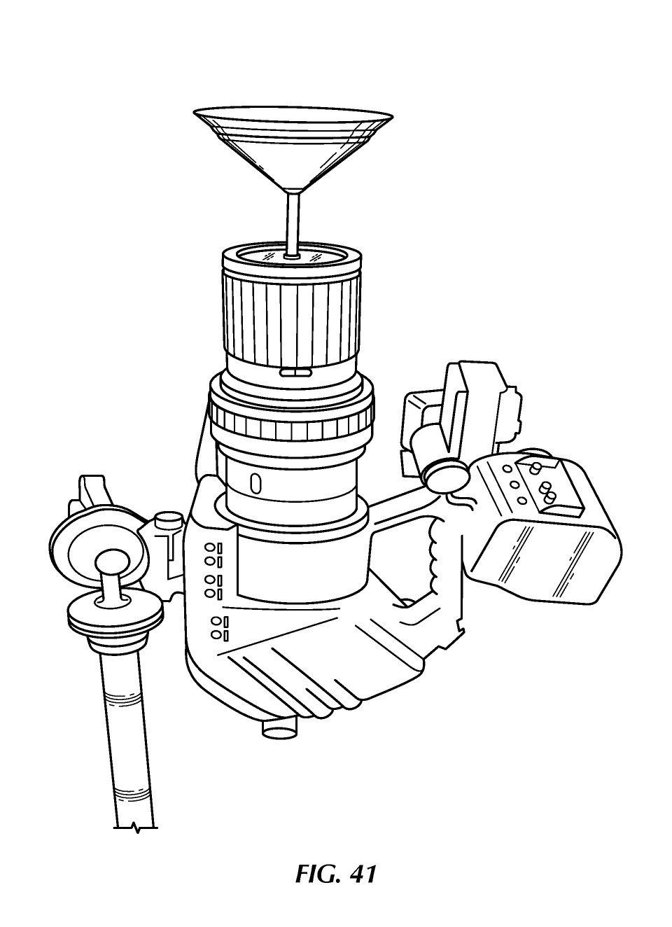

In one embodiment, the local computer 210 is a desktop or laptop computer in a classroom and is coupled to a first camera 214 and a second camera 216 as well as two microphones 217 and 218 for capturing audio and video from a classroom environment, for example, during teaching events. In other embodiments, additional cameras and microphones may be utilized at the local computer 210 for capturing the classroom environment. In one exemplary embodiment, the first camera may be a panoramic camera that is capable of capturing panoramic video content. In one embodiment, the panoramic camera is similar to the camera illustrated in FIG. 41. The panoramic camera of FIG. 41 comprises a generic video camcorder being connected to a specialized convex mirror such that the camera records a panoramic view of the entire classroom. The camera of FIG. 41 is described in detail in U.S. Pat. No. 7,123,777, incorporated herein by reference.

The second camera, in one or more embodiments, comprises a video or still camera, for example, pointed or aimed to capture a targeted area within the classroom. In some embodiments the still camera is placed at a location within the classroom that is optimal for capturing the classroom board and therefore may be referred to as the board camera throughout this application.

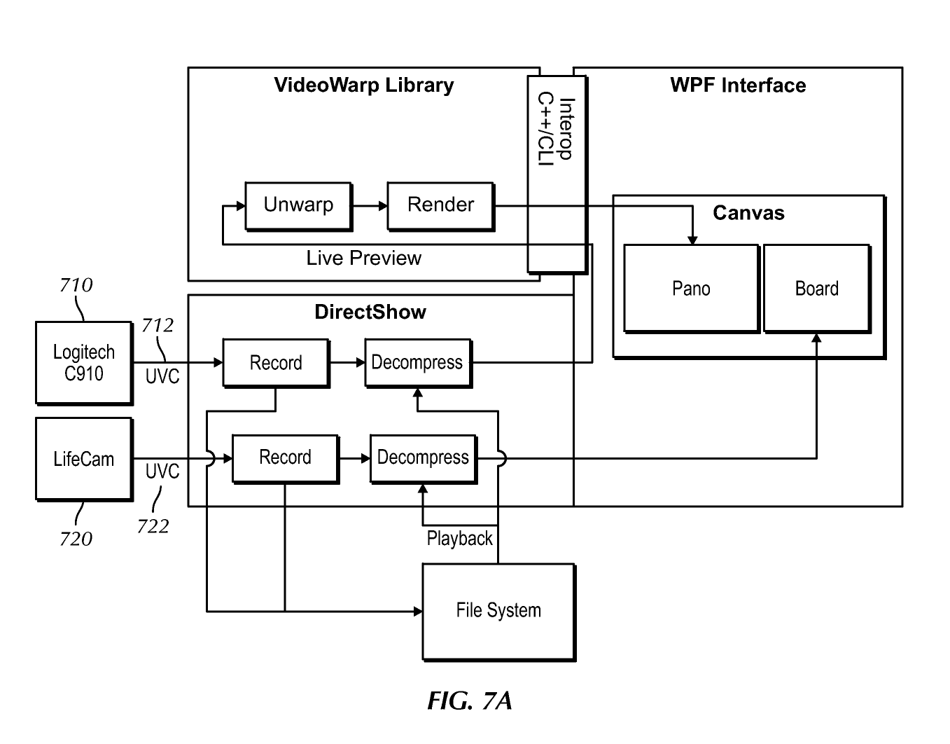

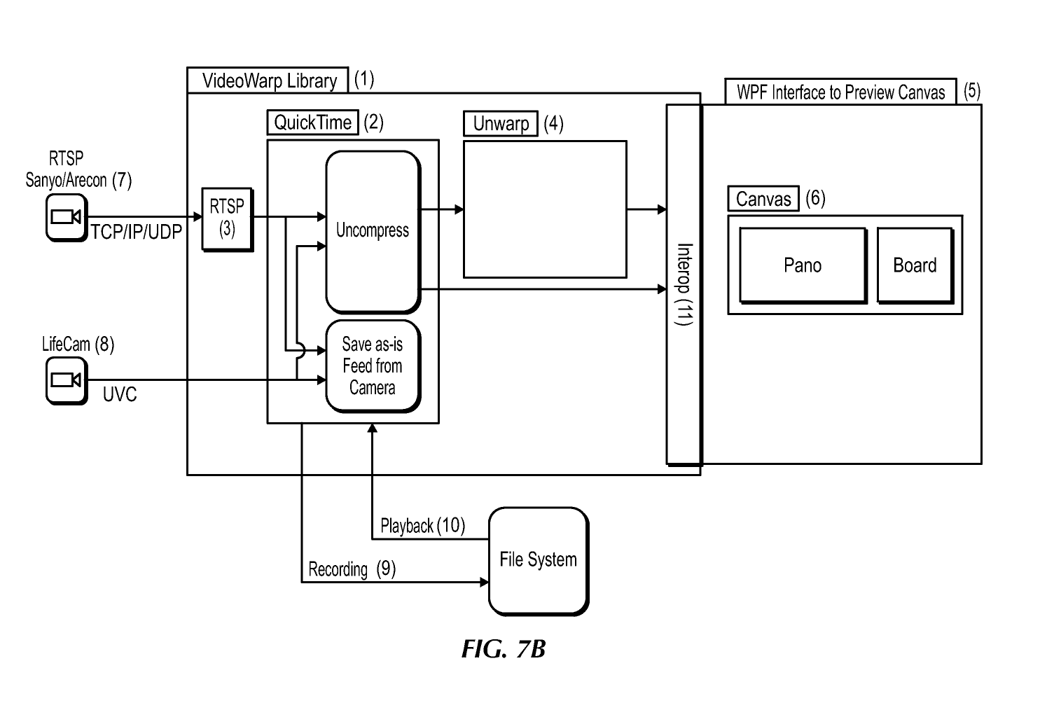

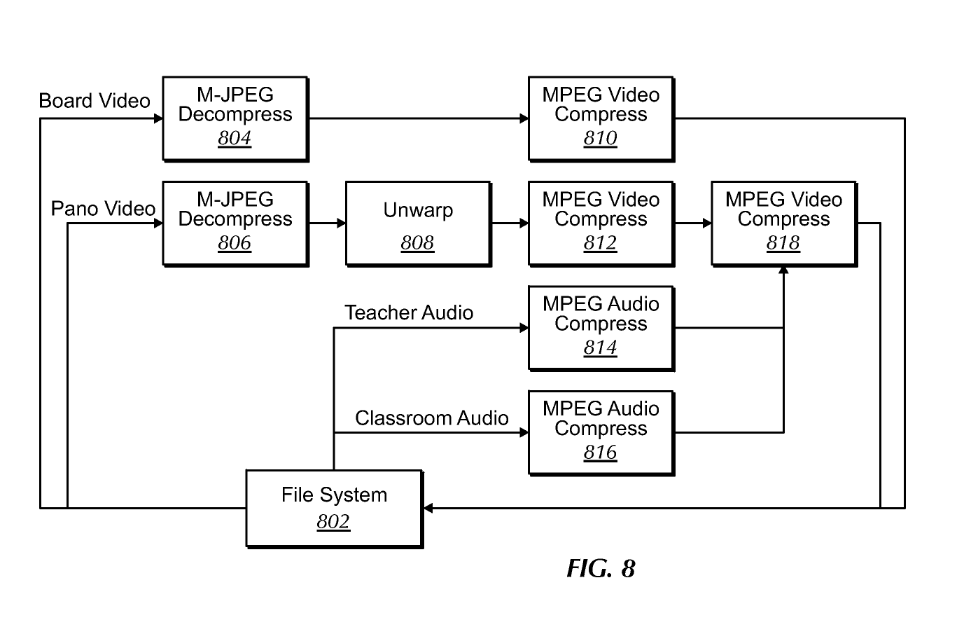

In one embodiment, software is stored onto the local computer for executing a capture application 212 that allows a teacher or other user to initialize the one or more cameras and microphones for capturing a classroom environment and is further configured to receive the captured video content from the cameras 214 and 216 and the audio content captured by microphones 217 and 218 and process the content before uploading the content to the content delivery server 240. Some embodiments, of the processing of the capturing content is described in further detail below with respect to FIGS. 7A, 7B and 8.

In one or more embodiments, similar to that described in FIG. 1, the mobile capture hardware 215 is similar to mobile capture hardware 115 and also comprises one or more input capture devices such as mobile cameras, mobile phones with video or audio capture capability, mobile digital voice recorders, and/or other mobile video/audio mobile devices with capture capability. Further details relating to the mobile capture hardware 115 and 215 are described later in this specification.

The web application server 220 has stored thereon software for executing a remotely hosted or web application 222. In one embodiment, the web application server may have or be coupled to one or more storage media for storing the software or may store the software remotely. In some embodiments, the web application server 220 further comprises one or more databases 224. In some embodiments, the database 224 may be remote from the web application server 220 and may provide data to the web application server 220 over the network 250. In one embodiment, for example, the web application server is coupled to a metadata database 224 for storing data and at least some content associated with captured content stored on the content delivery server 240. In other embodiments, the additional data, metadata and/or content may be stored at the content database 242 of the content delivery server.

In one embodiment, the web application 222 is configured to access the content collections or observations uploaded from the user computer 210 to the content delivery server 240.

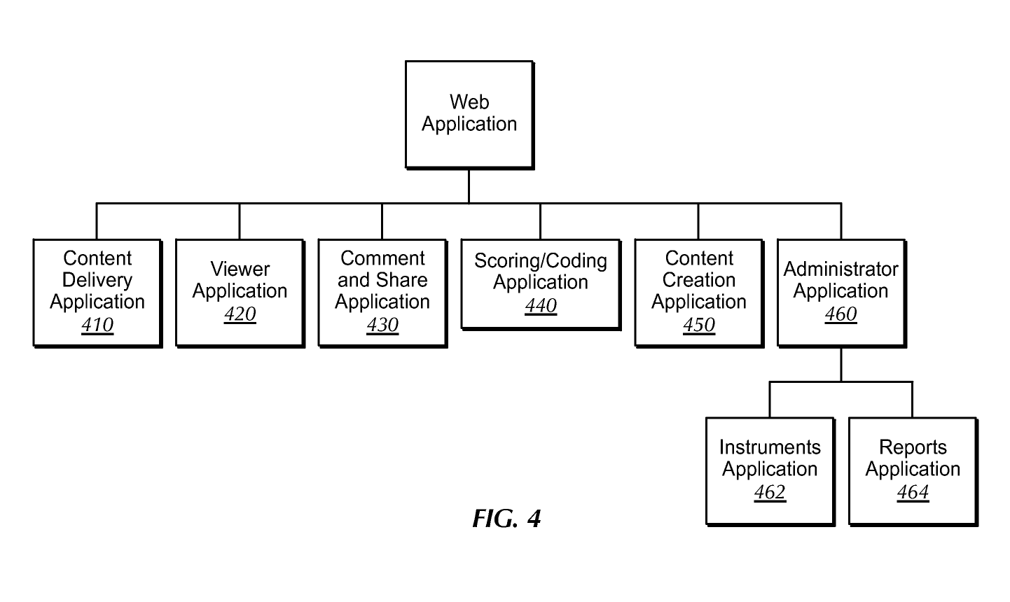

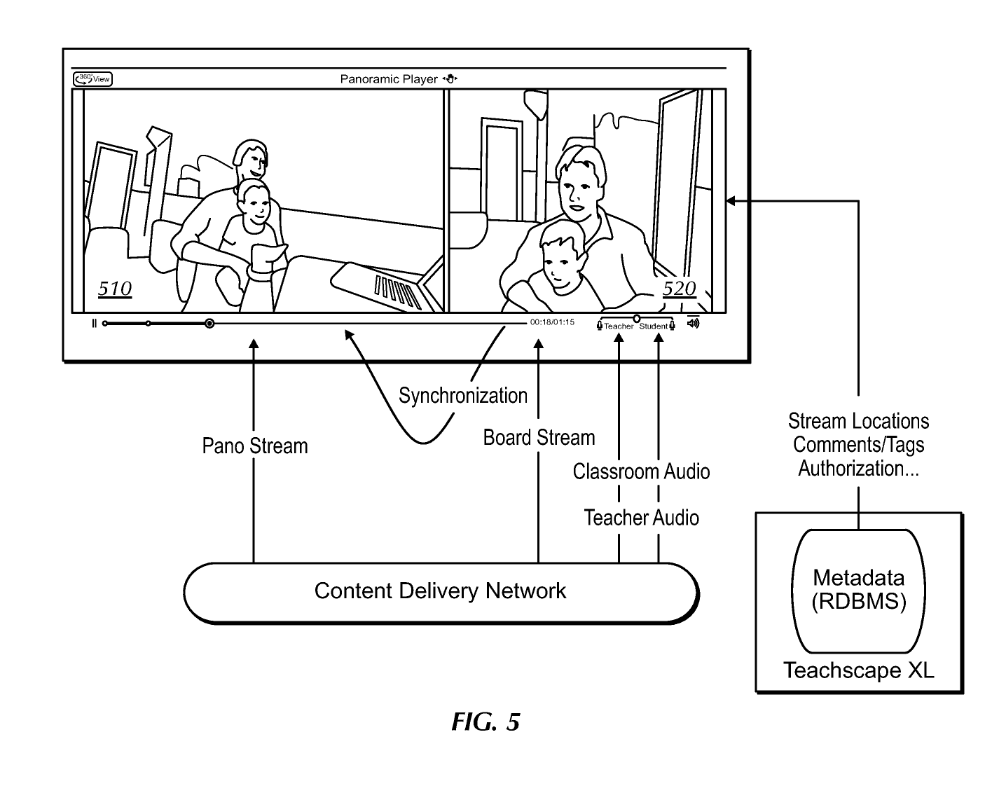

In one embodiment, the web application 222 may comprise one or more functional application components accessible by remote users via the network for allowing one or more users to interact with the captured content uploaded from the user computer 210. For example, the web application may comprise a comment and sharing application component for allowing the user to share content with other remote users, e.g., users at remote computer 230. In one embodiment, the web application may further comprise an evaluation/scoring application component for allowing users to comment on and analyze content uploaded by other users in the network. Additionally, a viewer application component is provided in the web application for allowing remote users to view content in a synchronized manner. In one or more embodiments, the web application may further comprise additional application components for creating custom content using one or more of the content stored in the content delivery server and made available to a user through the web application server, an application component for configuring instruments, and a reporting application component for extracting data from one or more other applications or components and analyzing the data to create reports, and other components such as those described herein. Details of some embodiments of the web application are further discussed below with respect to FIGS. 4 and 5.

In one or more embodiments, users of user computer 210 and remote computers 230 are able to access the content collection or observation captured at the user computer 210 by accessing the web application server 220 over network 250, and interact with the content for various purposes. For example, in one embodiment, the web application allows remote users or evaluators, such as teachers, principals and administrators to interact with the captured content at the web application for the purpose of professional development. In some embodiments, this provides the ability for teachers, principals, administrators, etc. to observe classroom teaching events in a non-obtrusive manner without having to be physically present in the classroom. In some embodiments, it is felt that the teaching experience is more natural since evaluating users are not present in the classroom during the teaching event. Further, in some embodiments, this provides for multiple different users to view the same observation captured from the classroom from different locations, at different times if desired, providing for greater opportunities for collaborative analysis and evaluation. While only the local computer 210 is described herein as having content capture and upload capabilities it should be understood by one skilled in the art that one or more of the remote computers 230 may further have capture capabilities similar to the local computer 210 and the web application allows for sharing of content uploaded to the content delivery server by one or more computers in the network.

In one embodiment, the one or more local computers 230 comprise personal computers in communication with the web application server 220 via the network. In one embodiment, the local computer 210 and remote computers 230 have web browser capabilities and are able to access the web application 222 to interact with captured content stored at the content delivery server 240. As described above, in some embodiment, one or more of the remote computers 230 may further comprise capture hardware and a capture application similar to that of local computer 210 and may upload captured content to the content delivery server 240.

As illustrated in this embodiment, the remote computers 230 may comprise teacher computers 232, administrator computers 234 and scorer computers 236, for example. In one embodiment, teacher computers 232 are similar to the local computer 210 in that they are used by teachers in classroom environments to capture lessons and educational videos and to share videos with others in the network and interact with videos stored at the content delivery server. Administrator computers 234 refer to computers used by an administrators and/or educational leaders to administer one or more work spaces, and/or the overall system. In one embodiment, the administrator computers may have additional software locally stored at the administrator computer 234 that allows the administrators to generate customized content while not connected to the system that can later be uploaded to the system. In one embodiment, the administrator may further be able to access content within the content delivery server without accessing the web application and may have the capability to edit or add to the content or copies of the content remotely at the computer for example using software stored and installed locally at the administrator computer 234.

Scorer computers 236 refer to computers used by special observers, such as teachers or other professionals, having training or knowledge of scoring protocols for reviewing and evaluating/scoring observations stored at the content delivery server and/or the web application server 220. In one embodiment, the scorer computer accesses the web application 222 hosted by the web application server 220 to allow its user to perform scoring functionality. In another embodiment, the scorer computers may have local scoring software stored and installed at the scorer computers 236 separate from the web application and may have access to videos or other content while not connected to the network and/or the web application 220. In one embodiment, the user can score and comment on videos and may upload the results to the content delivery server or a separate server or database for later retrieval. In some embodiments, the scorer computers may be similar to the teacher computers and may further include capture capabilities for capturing content to be uploaded to the content delivery server.

In one or more embodiments, in addition to the capture application, one or more of the user computer 210 and remote computers 230 may further store software for performing one or more functions with respect to the images, audio and/or videos captured by the capture application locally. In one embodiment, this additional capability may be implemented as part of the capture application 212 while in other embodiments, a separate application may be installed on the computer for allowing the computer to interact with the captured content without being connected to the web server. For example, in one embodiment, a user may download content from the content delivery server, store this content locally and may then terminate connection and perform one or more local functions on the content. In one embodiment, the downloaded content may comprise a copy of the original content. In some embodiments for example, users may be able to edit content, e.g. edit or add to the captured content, metadata, etc. in the local application and the edited content may then be synched with the web application server 220 and content delivery server 240 the next time the user connects to the network.

In one or more embodiments, the content delivery server 240 comprises a database 242 for storing the uploaded content collections received from the local computer 210 and other computers in the network having capturing capabilities. While the database 242 is shown as being local to the server, in one embodiment, the database may be remote with respect to the content delivery server and the content delivery server may communicate with other servers and or computers to store content onto the database. In one embodiment, the web application server 220 is in communication with the content delivery server 240 and accesses the stored content to provide to the one or more users of the local computer 210 and the remote computers 230. It is understood while the system of FIG. 2 is specific to a general educational environment, this system may be applied to other environments in which it may be desirable to capture audio, images, and/or video that may be tagged, edited, commented, have associated documents comprising an observation, where the observation is uploaded for retrieval and analysis. While the content delivery server 240 is shown as being separate from the web application server 220, in one or more embodiments, the content delivery server and web application may reside on same server and/or location.

### Process Overview—Capture

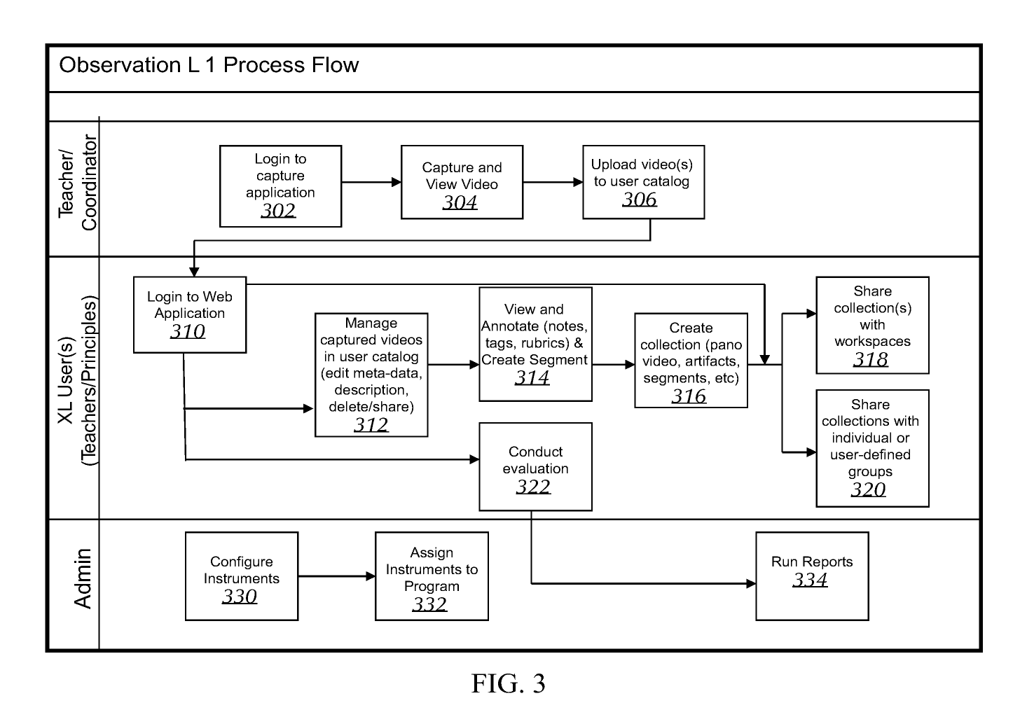

Referring next to FIG. 3, a diagram of a flow process 300 for capturing, processing, sharing, and analyzing multi-media content relating to a multimedia captured observation is illustrated according to one embodiment. The process of FIG. 3 is illustrated with respect to the system being used in an educational environment, such as that illustrated in FIG. 2. It should be understood that this is only for exemplary purposes and that the system may be used in different environments and for various purposes. As illustrated the process begins in step 302 when a teacher/coordinator logs into the capture application, for example, at the user computer 110.

Once the teacher/coordinator has logged into the system, the process then continues to step 304, where the teacher/coordinator will initiate the capture process. In one embodiment, during the capture process, the teacher/coordinator will input information to identify the content that will be captured. For example, the teacher/coordinator will be asked to input a title for the lesson being capture, the identity of the teacher conducting the lesson, the grade level of the students in the classroom, the subject the lesson is associated with, and/or a description of the lesson. In one embodiment, other information may also be entered into the system during the capture process. In one embodiment, one or more of the above information may be entered by use of drop down menus which allow the user to choose from a list of options.

Next, during step 304, the teacher coordinator will begin the capture process. For example, in one embodiment the teacher/coordinator will be provided with a record button once all information is entered to begin the capture process.

In several embodiments, once the teacher initializes the capture process by, for example, inputting the initial information, making any necessary adjustments and pressing the record button, no other input is required from the teacher/coordinator while the lesson is being captured until the teacher chooses to terminate the capture.

After the teacher/coordinator has finished recording/capturing the content, e.g. the teacher/coordinator presses the record/stop button to stop recording the lesson/classroom environment, the content is then saved onto local or remote memory or file system for later retrieval where the content is processed and uploaded to the content delivery server to be shared with other remote users through the web application. In one embodiment, after the capturing process is terminated, the user may be given an option to add one or more photos including photos of the classroom environment, or photos of artifacts such as lesson plans, etc.

The process at step 304 also allows the user to view the captured and stored content prior to being uploaded. In another embodiment, the user may be provided with a preview of only a portion of the content during the capture process or after the capturing has been terminated and the content is available in the upload queue for upload. For example, in some embodiments, a time limited preview is available, such as a ten second preview. In some cases, such preview may be displayed at a lower resolution and/or lower frame rate than the content that will be uploaded.

At this time, step 304 is completed and the process continues to step 306 where the captured content or observation including the video, audio and photos and other information is processed and uploaded to the web application. That is, in one embodiment, once the capture is completed, the one or more videos (e.g. the panoramic video, and the board camera video), the photos added by the teacher/coordinator, and the audio captured through one or more microphones are processed and combined with one another and associated with the information or metadata entered by the teacher/coordinator to create a collection of content or observation to be uploaded onto the web application. The processing and combining the video is described in further detail below with respect to FIGS. 7 and 8.

Once the content is uploaded onto the content delivery server, the content is then accessible to the teacher/coordinator as well as other remote users, such as administrators or other teachers/coordinators, who may access the content and perform various functions including analyzing and commenting on the content, scoring the content based on different criteria, creating content collections using some or all of the content, etc. In on embodiment, upon upload the captured content is only made available to the owner/user and the user may then access the web application and make the content available to other users by sharing the content. In other embodiments, the user or administrator may set automatic access rights for captured content such that the content can be shared or not with a predefined group of users once it is uploaded to the system. By allowing one or more of this analyzing, commenting, scoring, etc, this provides for many possibilities useful for the purposes of improving educational instruction techniques.

It is noted that in some embodiments and as described throughout this specification, the teacher/coordinator may be generally referred to as one of the observed persons that an observation will be created when the observed person performs the task to be processed and/or evaluated. In some embodiments, administrators, evaluators, etc. may be generally referred to as observing persons.

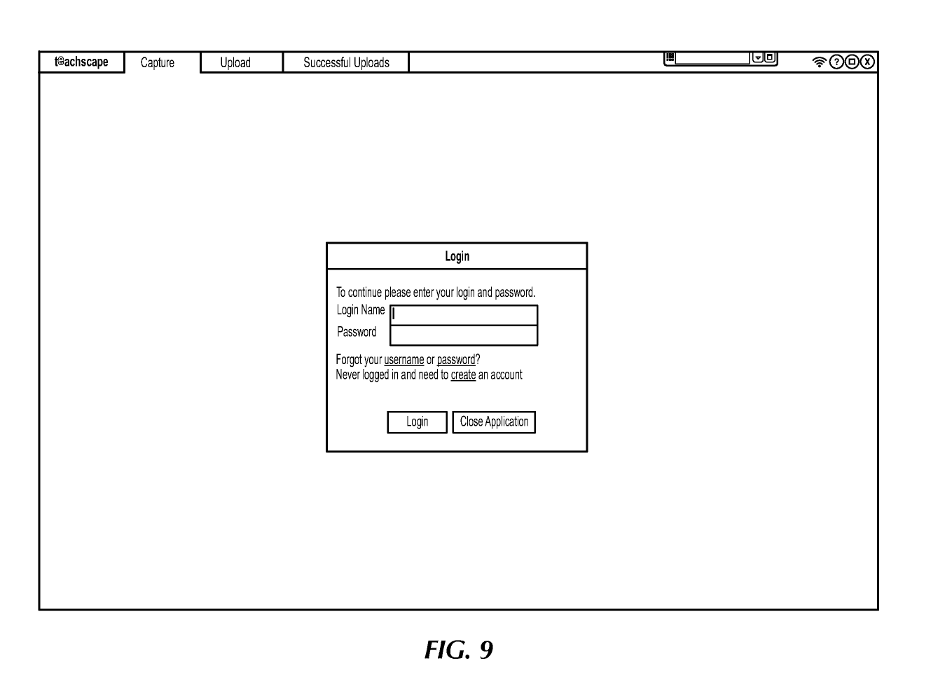

FIGS. 9-15 illustrate an exemplary set of user interface display screens that are presented to the user via the multimedia capture application for performing steps 302-306 of FIG. 3. FIG. 9 illustrates an exemplary screen shot of the login screen that may appear when a teacher (e.g., a person to be observed performing a teaching task) initializes the capture application. As illustrated in FIG. 9, the teacher/coordinator will be prompted to enter a user name and password to enter the capture application. In some embodiments, each account associated with a unique user name and password is specifically linked with a specific teacher/coordinator.

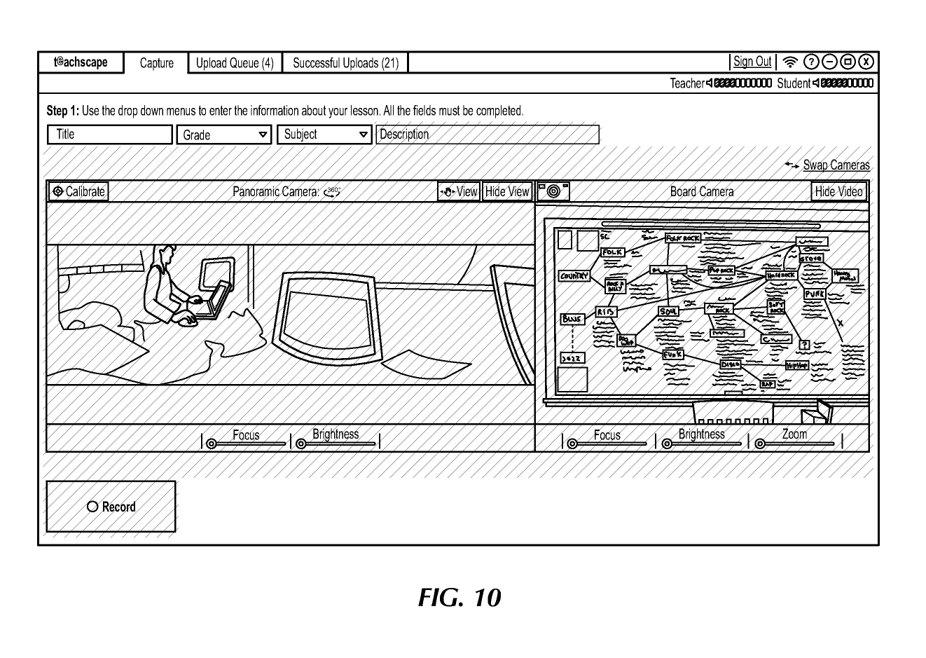

FIG. 10 illustrates an exemplary user interface display screen presented to the teacher once the teacher has logged into the system and enters the capture page. As shown, the screen provides one or more information fields that must be filled out by the teacher/coordinator. For example, the illustrated fields request that the teacher enter the grade and subject corresponding to the event to be captured. In some embodiments, the capture component may require that some or all of the information is entered before the capture can begin.

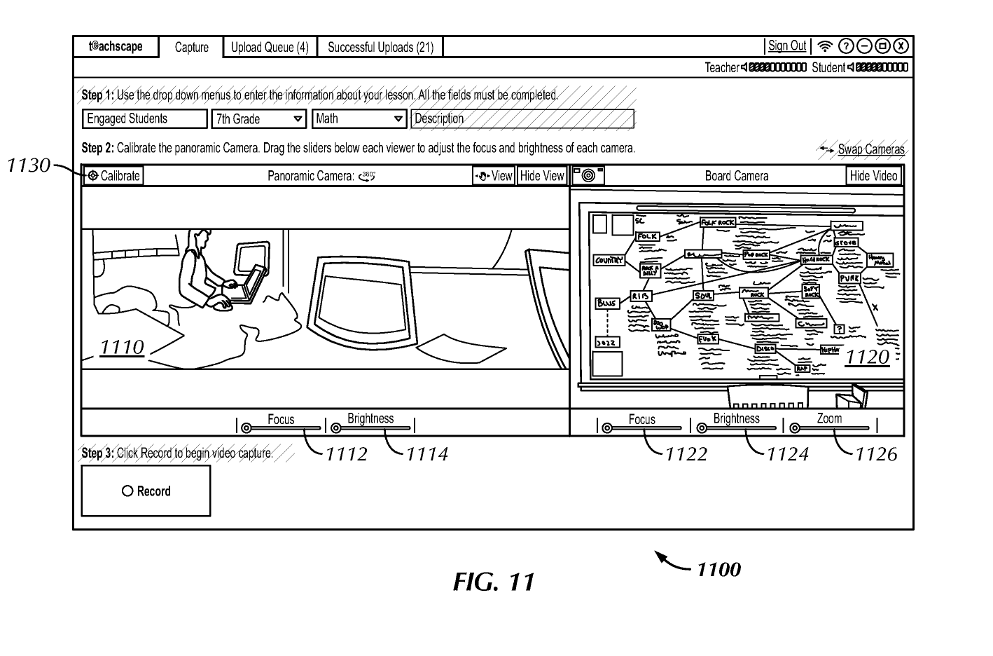

Once all information is entered and saved, as shown in FIG. 11 the teacher/coordinator will then begin the recording/capturing of content by selecting the record button. Upon selecting the record button, the capture application will begin recording the event, e.g., the lesson being conducted in the classroom environment. As shown in FIG. 10, in some embodiments the record button is not available (e.g., shown as grayed out) to the user until the user enters all necessary information. That is, according to one or more embodiments, the teacher/coordinator will gain access to the capturing elements of the screen once all necessary information has been entered and saved as shown in FIG. 11. In some embodiments as illustrated in FIG. 11, the teacher/coordinator is able to adjust the characteristics of the video being captured such as the focus and brightness, and zoom of the videos before beginning the capture process. In one embodiment, for example, the teacher/coordinator may be asked to calibrate one or more of the cameras, and adjust the characteristics of the images being captured before beginning the recording/capturing process.

As mentioned above, the capture process content may be captured using one or more cameras, microphones, etc. and may be further supplemented with photos, lesson plans, and/or other documents. Such material may be added either during the capture process or at a later time. As shown in FIG. 11, in this exemplary embodiment, the classroom lesson is being captured using two cameras which are displayed on the screen side-by-side. A first panoramic camera captures the entire classroom and displays the panoramic video in a first panoramic camera window 1110 of the screen 1100. Another camera is focused on the blackboard in the classroom and captures the camera and is displayed in a second board camera window 1120 of the screen 1100.

In one embodiment, the displayed content is of a different resolution or frame rate than the final content that will be loaded to the delivery server. That is, in one embodiment, the displayed content comprises preview content as it does not undergo the same processing as the final uploaded content. In one embodiment, the display of captured content is performed in real time while in another embodiment, the preview is displayed with a delay, or displayed after completion of the capture.

In one or more embodiments, in addition to providing display areas for displaying the video content being captured, screen 1100 further provides the teacher/coordinator with one or more input means for adjusting what is being captured. In one embodiment, the teacher/user is able to adjust the capture properties of one or both the panoramic camera and the board camera using adjusters provided on the screen, e.g., in the form of slide adjusters. For example, as illustrated in FIG. 11, the display area 1110 provides a Focus and Brightness adjuster 1112 and 1114 for adjusting the characteristics of the panoramic camera capture. Furthermore, the display area 1120 provides focus, brightness and zoom adjusters 1122, 1124, 1126 for adjusting the characteristics of the board camera. Furthermore, in some embodiments, a calibrate button 1130 is provided to allow for calibrating the video feed from one or more of the cameras. For example, in one embodiment, the teacher/coordinator may calibrate the panoramic camera using the calibrate button shown on display area 1120. In one embodiment the user may for example be asked to calibrate the panoramic camera before clicking on or selecting the record button and therefore starting the recording/capturing of content. In one embodiment, calibration may for example be performed in order to crop the image recorded by the panoramic camera in order to remove any unwanted capture, such as for example the ridge of the mirror in embodiments where the panoramic camera comprises the mirror as described in FIG. 41.

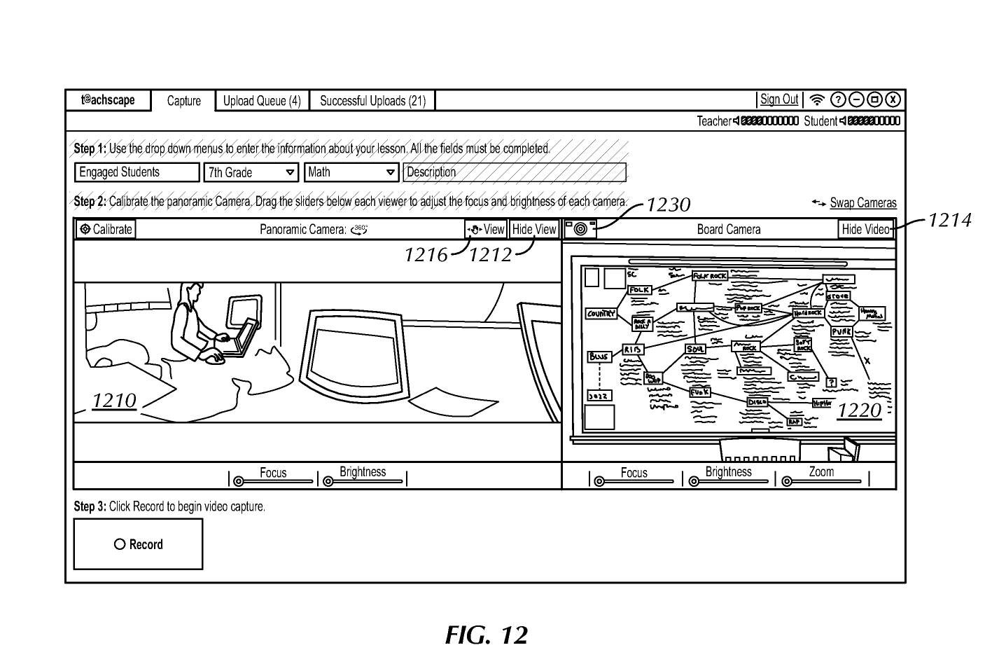

In some embodiments, once the user (e.g., teacher/coordinator) has made all necessary adjustments, then the capture process begins when the teacher selects or clicks the record button 1140. It is understood that when generally referring to pressing, selecting or clicking a button in this and other user interface displays, display screens or screen shots described herein, that when implemented as a display within a web browser, the user can simply position a pointer or cursor (e.g., using a mouse) over the button (icon or image) and click to select. In some embodiments, selecting can also mean hovering a pointer or cursor over a button, icon, or text. It is understand that the record button may alternatively be implemented as a hardware button implemented by a given key of the user computer or other dedicated hardware button, for example, coupled to the user computer or to the camera equipment. FIG. 12 illustrates an exemplary user interface display screen once the user has completed all necessary tasks before starting to record the lesson. At this point during the capture process the user, i.e. teacher/coordinator, is asked to press, click or select the record button to begin the capture. Once the recording process is started, the one or more cameras and microphones will begin capturing the classroom environment.

According to several embodiments, either before or during the capture process, in addition to being able to control the recording properties of the cameras, the user (teacher/coordinator) may be provided with further options for different viewing options during the capture process. For example, in some embodiments, the teacher/coordinator is able to hide one or more of the board camera or the panoramic camera by pressing, clicking or selecting the Hide Video buttons 1212 and 1214 provided on each of the display areas 1210 and 1220 of FIG. 12. Still further, in one or more embodiments, the teacher/coordinator is able to switch between views of the panoramic video by selecting a view button 1216. For example, the teacher is able to switch between views of the content being captured by the panoramic camera. For example, in one embodiment, the user may switch between a 360 view or a side-by side view of content. In one embodiment, the user may choose between a cylindrical view that allows the user to pan through the classroom, i.e. cylindrical view, while in another embodiment, the user may select an unwarped view of the classroom for example as illustrated in FIGS. 11 and 12. In one embodiment, a first view, e.g. cylindrical view, only shows part of the complete video and lets users pan around in the videos. This provides the user with an option to look around in the video and provides an immersive experience. In the perspective view, the entire video is displayed at once and the user is able to view the entire captured/monitored environment.

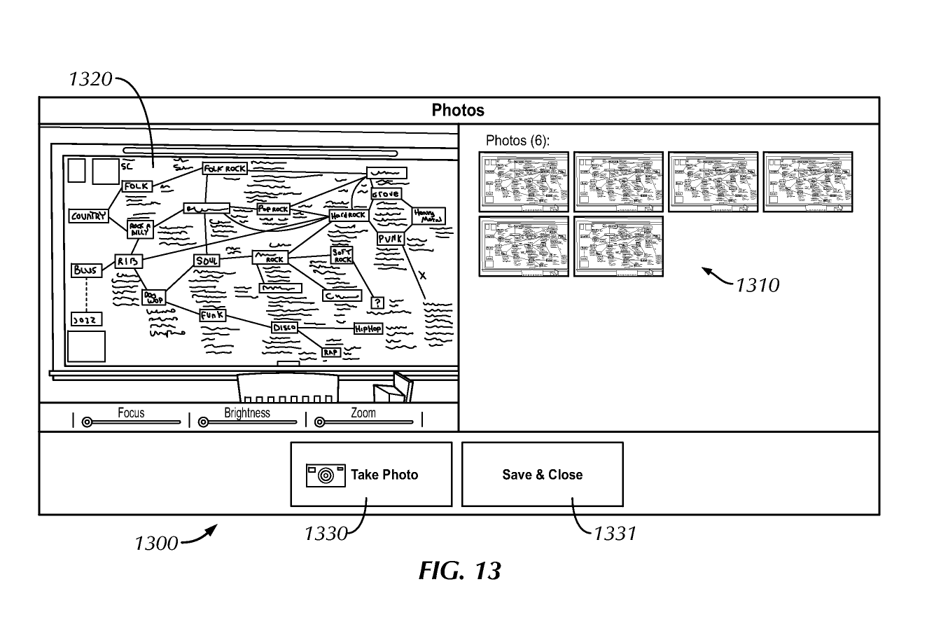

Still further, the teacher/coordinator is provided with a means for adding one or more photos before, during and after the video is being captured. In another embodiment, the user may be able to add photos to the lesson before beginning the capture, i.e. selecting the record button, or after the recording has terminated. In some embodiments, the user may not be able to add photos while the classroom environment is being captured/recorded. For example, as shown in FIG. 12, a button 1230 with a camera symbol is provided on the screen. The user is able to select the camera button 1230 to access one or more photos, captured before or during the lesson and add these photos to the captured content. FIG. 13 illustrates an exemplary embodiment of the photo display screen that opens or pops up once the teacher/coordinator chooses to add photos to the content being captured by selecting the button 1230. As shown in the display screen of FIG. 13, the teacher may have stored photos that may be added to the content, or may be given the option to take new photos. These photos can become part of the collection of captured content, and thus, may become part of the captured observation. For example, as shown in display screen 1300 of FIG. 13, the teacher has six existing photos 1310 that are added to or associated with the captured content 1320. Further, the teacher may capture additional photos to be added to the content. For example, as shown in FIG. 13, the teacher is able to take additional photos using a “take photo” button 1330 and add them to the photos. As shown, once the teacher/coordinator has captured the photos then the photos may be saved and the window is closed by selecting the Save & Close button 1331 as shown in screen 1300 of FIG. 13.

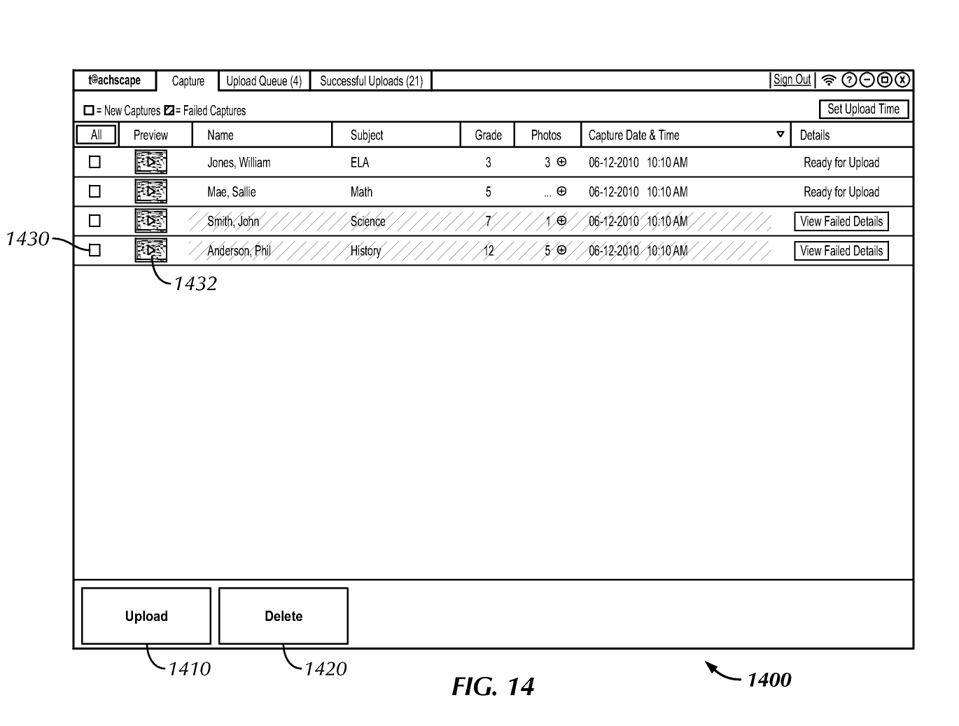

When the teacher/coordinator is logged onto the capture application, during the capture process, the teacher/coordinator has access to two additional screens showing the content that is already captured and ready for upload, and all successful uploads that have occurred. As shown in FIGS. 10-15, the capture application comprises of three separate pages selectable by tabs on top of the screen. The teacher/coordinator is able to select between the capture, upload queue, and successful uploads screen by pressing or selecting the tabs that appear on top of the screen for the capture application once the teacher/coordinator is logged onto the system. An exemplary upload queue display screen is illustrated in FIG. 14. As shown, a listing of captured content 1430 is provided to the teacher/coordinator for the specific account the teacher/coordinator is logged into. The list provides the user with information about the captured content, such as the name of the teacher or instructor, the subject corresponding to the captured content, the grade level associated with the captured content, the capture date and time, and/or other information. In addition, in one or more embodiments, the teacher/coordinator may further be provided with a preview for each of the captured content. For example, in one embodiment, as show in FIG. 14, next to each content a preview button 1432 is available, which is selectable by the user to display at least a portion of the content to help the teacher/coordinator identify the content. Furthermore, as illustrated in FIG. 14, the list may further provide a status for each of the captured content, such as whether the content is ready for upload or if the content contains some errors. In situations where the content contains an error the teacher/coordinator is able to view the details of the errors.

As shown, each list further enables the teacher/instructor to select one or more of the captured content for upload or deletion using the buttons shown on the bottom of the screen 1400. When the user is ready to upload a captured content or observation, which as stated above includes one or more videos, audios, photos, basic information, and optionally other documents or content, the user selects the captured content from the list as shown in FIG. 14 and select the upload button 1410. The application then retrieves the content and processes the content to upload the content to the web application over the network. In one embodiment, the captured content is stored onto a storage medium and added to the list shown in FIG. 14 after being captured without any processing. For example, in one embodiment, as the content is being captured it is written to an internal or external memory in its raw format along with additional audio, photos and metadata. In such embodiments once the content is selected for upload, the content is then processed and combined to be sent over the network to the web application. The capturing, processing and uploading of the content is described in further detail below with respect to the FIG. 7A, 7B and 8.

In one embodiment the user is able to assign an upload time where all selected items for uploading will be uploaded to the system. For example, in one embodiment the user may use a time of the day where the network is less busy and therefore bandwidth is available. In another embodiment other considerations will be taken into account to assign the upload time.

Furthermore, while in the upload queue display screen of FIG. 14, the user is able to delete one or more of the captured content in the upload queue by selecting the Delete button 1420.

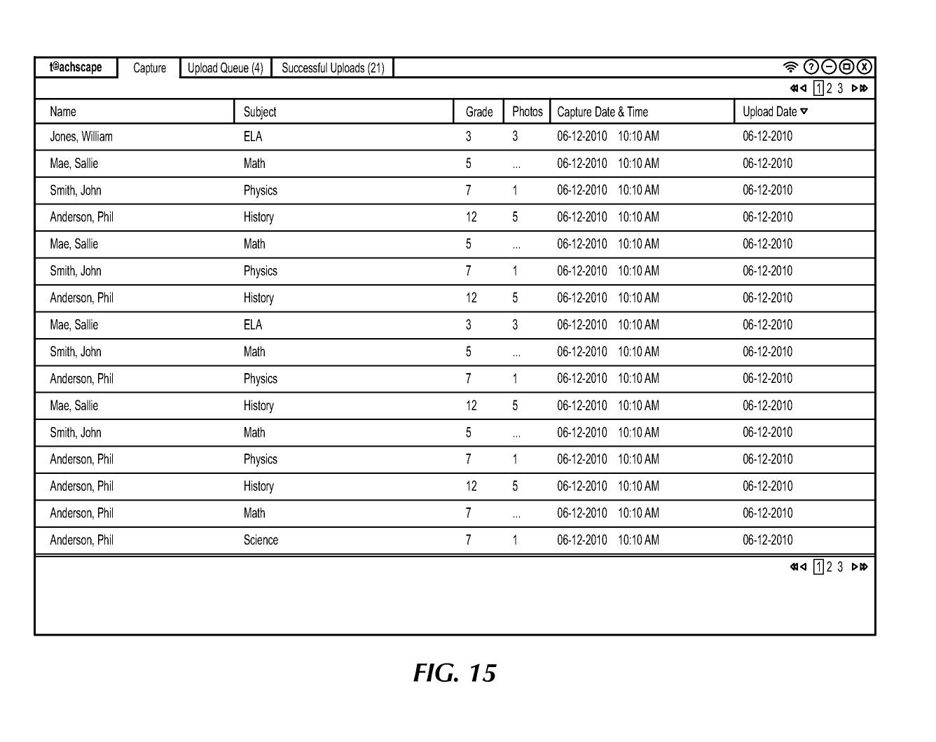

The teacher/coordinator logged onto the system is further able to view the successful uploads that have occurred under the account. FIG. 15 illustrates an exemplary user interface display screen of the successful uploads screen according to one or more embodiments. The successful upload screen will display a list of content that has been successfully uploaded. In some embodiments, as displayed in FIG. 15, the screen will comprise a list with information for each of the successfully uploaded content, including the name of the instructor, subject, grade, number of photos and capture date and time associated with the content, as well as a time and date the upload was completed.

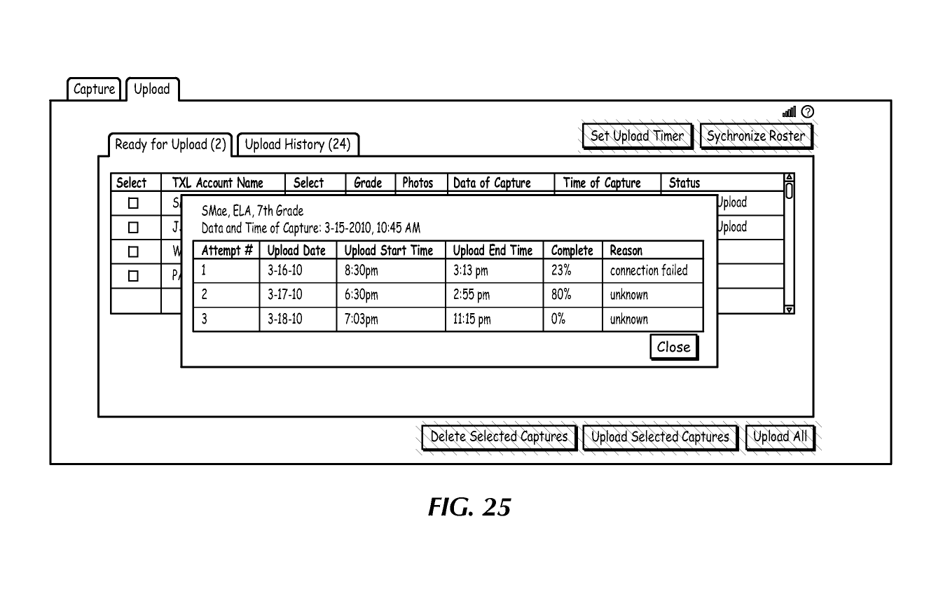

In one embodiment, content having failed an upload attempt is further displayed. In one embodiment, a user may select to view the details of the failed upload and may be presented with details regarding the failed upload. For example, in one embodiment a screen similar to that of FIG. 25 may be presented to the user when the user selects the view failed details. The screen may display information about the capture as well as the number of attempts made to upload the captured content as well as details relating to each attempt. For example, in one embodiment, as shown in FIG. 25 a table is provided listing each attempt along with the upload date, upload start time, upload end time, percent of content uploaded/completed and reason for upload failure for each attempt.

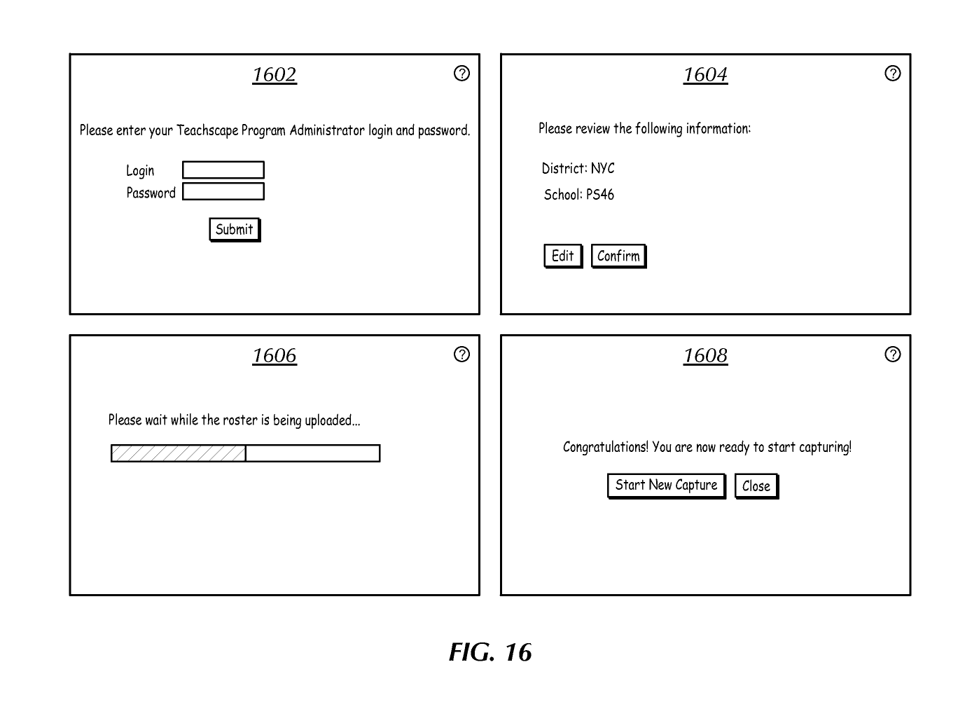

FIGS. 16-26 illustrate yet another embodiment of screens that may be displayed to the user for completing steps 302-306 of FIG. 3.

FIG. 16 illustrates several login related screens. Screen 1602 a login screen similar to the display screen illustrated in FIG. 9 above. The login screen prompts the teacher or coordinator to enter their login and password to enter the capture application. Once the teacher/coordinator enters their information, as illustrated in display screen 1604 in one embodiment, the user may be prompted to review the entered information for accuracy. After the teacher/coordinator confirms that the entered information is correct, as shown in display screen 1606, the system begins to log the teacher/coordinator into the system and accesses the account information and content that is associated with the user. In one embodiment, as shown in display screen 1608, once the login process is completed, the teacher/coordinator may be presented with a screen indicating successful login to the system and may select the start new capture button to begin the capture process. In one embodiment the login process shown in screens 1602, 1604, 1606 and 1608 is only performed for a first time user and the user will only see the screen 1602 and/or in FIG. 9, the next time the user attempts to access the capture application.

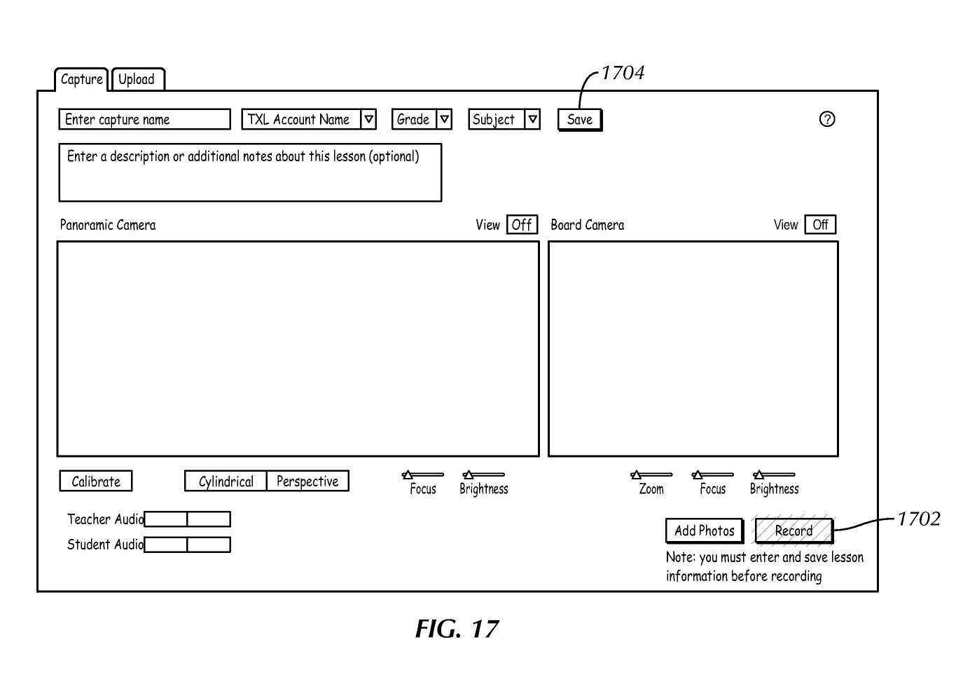

Once the user enters the system in this exemplary embodiment, the teacher is then provided with a capture display screen illustrated in FIG. 17 to initiate the capturing of content. Similar to the capture display screen of FIG. 12, the capture display screen in this embodiment comprises various information fields for basic information regarding the content that the teacher/coordinator wishes to capture. For example, the capture screen may include one or more data fields such as capture name, account name, grade level, subject and a description and notes fields. In some embodiments, other data fields may be displayed to the user.

In one or more embodiments, some or all of the information may be mandatory such that the recording process may not be initiated before the information is entered. For example, as illustrated in FIG. 17, the capture name, account name, grade and subject fields are mandatory while the description and notes field are optional fields. The screen indicates to the user that the lesson information must be entered and saved before the recording can be initiated. For example, as shown in FIG. 17, the record button 1702 may be grayed out (dimly illuminated indicating that it is not selectable) until the user enters the necessary lesson information and selects the save button. In one embodiment, to initiate the capture process the teacher/coordinator enters the required information into the fields and selects the save button 1704 to save the information. In one embodiment, one or more fields may comprise drop down menus having a list of pre-assigned values from which the user may choose, while other information fields allow the user to enter any desired text string.

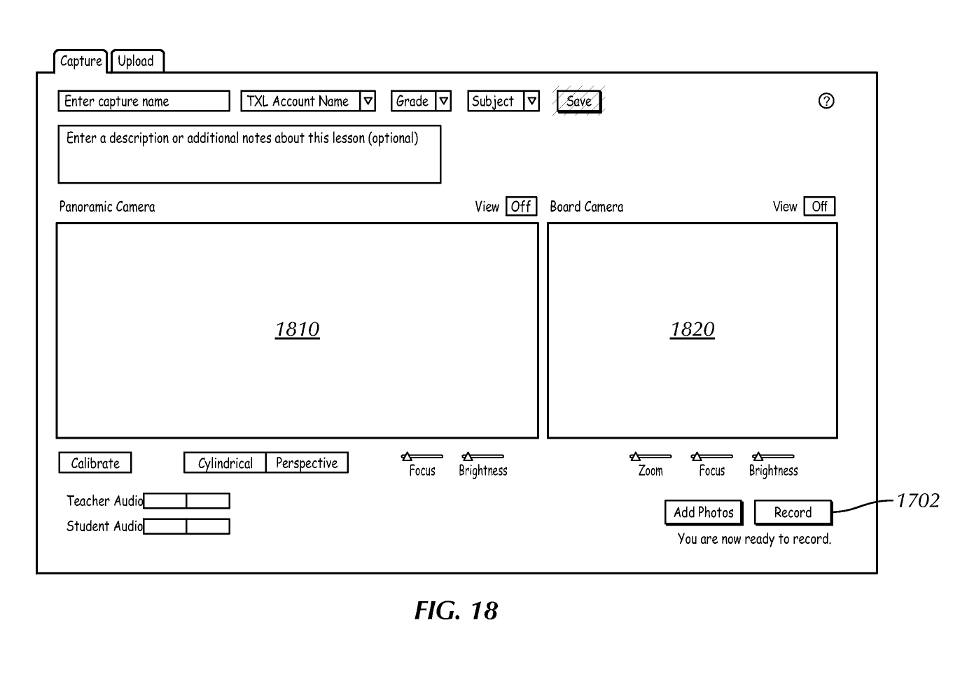

Once the user has entered all necessary information and presses the save button, the user is then able to begin recording the lesson by pressing the record button 1702 as illustrated in FIG. 18. In addition, some time before or during the recording the user may use one or more of the user input means of the capture screen to adjust what is being captured. For example, as illustrated, the teacher/coordinator is able to turn one or both video displays off by using the view off buttons appearing on top of each of display areas 1810 and 1820. These display areas each correspond to video being captured from a separate camera. In this embodiment, the display area 1810 displays video being captured by a panoramic video, while display area 1820 displays video being captured by a board camera. The teacher/coordinator is further able to calibrate the panoramic camera before initiating the recording process by selecting the calibrate button placed below the display area 1810. In addition, the view of the panoramic camera video may be switched between a cylindrical and perspective view. For example, in the illustrated embodiment, the cylindrical button is illuminated and as such the video being captured from the panoramic camera will be display in a cylindrical view. By pressing the perspective button the user is able to change the way the video is displayed in the display area 1810. In addition, the user is able to modify other characteristics of the panoramic video and board video such as zoom, focus and brightness.

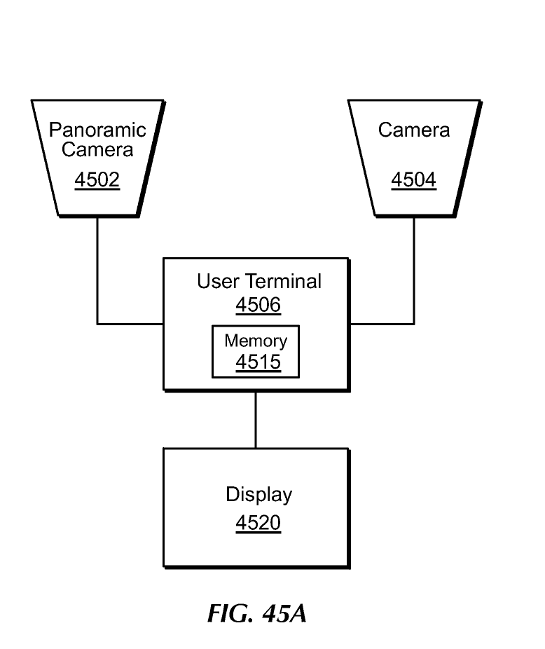

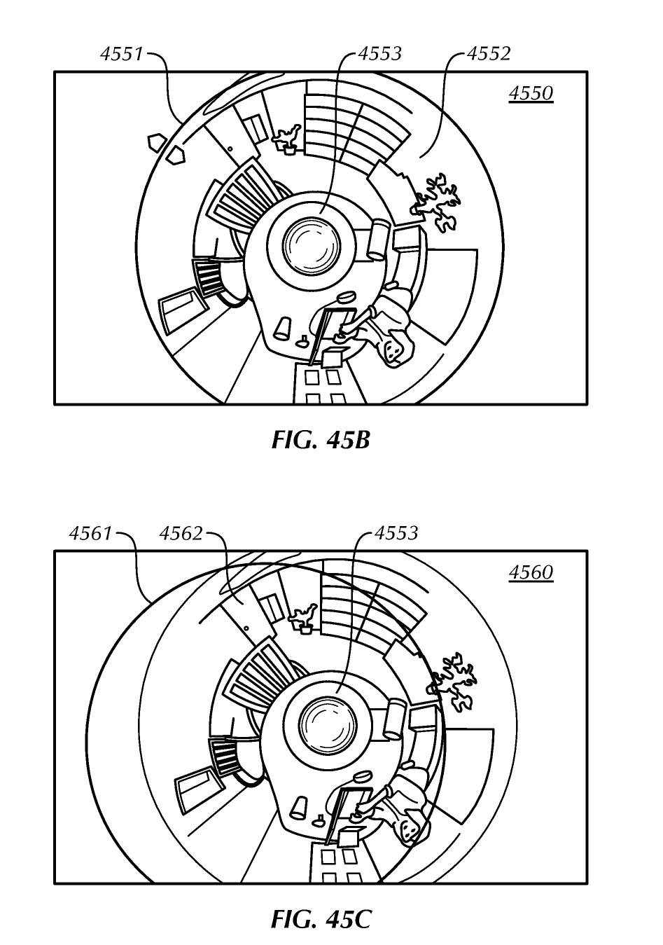

FIG. 45A illustrates a system for performing video capture of multimedia captured observations according to some embodiments. The system shown in FIG. 45A includes a panoramic camera 4502, a second camera 4504, a user terminal 4510, a memory device 4515 coupled to the user terminal, and a display device 4520. One example of a panoramic camera 4502 is shown in FIG. 41, which comprises a generic camcorder capturing images through the reflection of a specialized convex mirror with its apex pointing towards the camera, such that the camera captures a 360 degree panoramic view around the camera while the camera is stationary. A mounting structure is provided to support the specialized convex mirror and the camera placed under the mirror to capture images reflected on the mirror. Specific details regarding the mirror and panoramic capture using the camera of FIG. 41 is described in detail in U.S. Pat. No. 7,123,777 incorporated herein by reference.

In some panoramic cameras such as the one shown in FIG. 41, calibrating the camera prior to capture is can ensure that the panoramic image is properly captured and processed. The purpose of calibration is to align an image capture area with the reflection of the convex mirror captured by the camera. When properly calibrated, reflection of the camera in the convex mirror is centered in the capture area, such that when the image is processed (i.e., unwarped), the top edge of the unwarped image corresponds to the outer edge of the convex mirror reflection. In FIGS. 45A and 45B, an exemplary aligned video feed 4550 and an exemplary unaligned image video feed 4560 are shown. In the aligned video feed 4550, the edge of a convex mirror 4552 lines up with the capture area 4551, and the mirror reflection of the camera 4553 is centered in the capture area 4551. In the unaligned image 4560, the capture area 4562 is offset from the convex mirror 4562, and the mirror reflection of the camera 4553 is not centered in the capture area 4561.

In some embodiments, a user can press the “calibrate” button shown in the display area of FIG. 18 to bring up a calibration module for calibrating the processing of panoramic camera 4502 video feed. In some embodiments, the calibration module allows a user to move and resize the capture area circle 4551 to match the area of the convex mirror in the video feed through an input device such as a mouse. In some embodiments, the calibration is performed through touch gestures on the touch screen. In other embodiments, calibration can be performed automatically through an automatic calibration application executed on a computer. The automatic calibration application is able to analyze the panoramic video feed to determine size and position of the capture area. In some embodiments, the video capture includes more than one panoramic camera and a calibration module is provided for each panoramic camera.

In some embodiments, the calibrated parameters, which include the size and position of the calibrated capture area, are stored in the memory device 4515 and can be retrieved and used in subsequent video captures (e.g., subsequent video capture sessions) as presets. The use of calibration presets eliminates the need to calibrate the panoramic camera before each video capture session and shortens the set up time before video capture session. In some embodiments, other video feed setting such as focus, brightness, and zoom shown in FIG. 18 can similarly be stored and retrieved for subsequent video capture sessions as presets. In some embodiments, the second (board) video can also have preset settings such as focus, brightness, and zoom. While the memory device is illustrated in FIG. 45A as part of the user terminal 4510, in other embodiments, the memory device 4515 can be located on a remote server, or be a removable memory device, such as a USB drive.

According to some embodiments, a method and system are provided for recording a video for use in remotely evaluating performance of one or more observed persons. The system comprises: a panoramic camera system for providing a first video feed, the panoramic camera system comprising a first camera and a convex mirror, wherein an apex of the convex mirror points towards the first camera; a user terminal for providing a user interface for calibrating a processing of the first video feed; a memory device for storing calibration parameters received through the user interface, wherein the calibration parameters comprise a size and a position of a capture area within the first video feed; and a display device for displaying the user interface and the first video feed, wherein, the calibration parameters stored in the memory device during a first session are read by the user terminal during a second session and applied to the first video feed.

In this embodiment, the user is further provided with an input means to control the manner in which audio is captured through the microphones, the audio being a component of a multimedia captured observation in some embodiments. In one or more embodiments, audio may be captured from multiple channels, e.g., from two different microphones as discussed above. In this embodiment, for example, as illustrated in the capture screen there are two sources of audio, teacher audio and student audio. In one or more embodiments, the teacher/coordinator is provided with means for adjusting each audio channel to determine how audio from the classroom is captured. For example, the user may choose to put more focus on the teacher audio, i.e. audio captured from a microphone proximate to the teacher, rather than the student audio, i.e. audio captured by a microphone recording the entire classroom environment. In the illustrated example of FIG. 18 both audios are being captured with equal intensity however, the teacher/coordinator is able to change the values weight of each audio source.

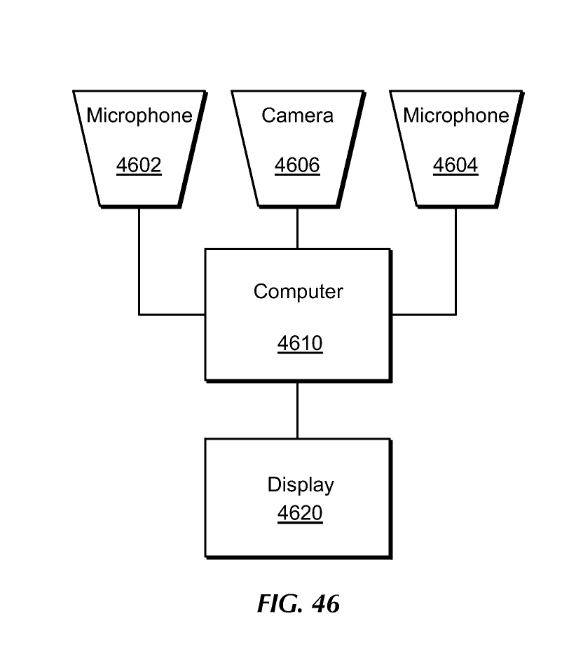

FIG. 46 illustrates a system for video and audio capture having one camera/video capture device 4606 and two microphones/audio capture devices 4602 and 4604 which are coupled to a local computer 4610 with a display device 4620. Microphones 4602 and 4604 may be integrated with one or more video cameras or be a separate audio recording devices. In one embodiment, the first microphone 4602 is placed proximate to the camera 4606 to capture audio from the entire monitored environment, while another microphone 4604 is attached to a specific person or location within the classroom for capturing a more specific sound within the monitored environment. For example, in an education embodiment, microphone 4602 may be positioned to capture audio from the entire classroom while microphone 4604 may be attached to a teacher for capturing audio of the lesson given. In one embodiment, microphones 4602 and 4604 may further be in communication with the computer 4610 through USB connectors or other means such as wireless connection. In one or more embodiment, the computer 4610 is configured to display, on the display device 4620, a visual presentation of audio input volumes received at microphones 4602 and 4604.

FIG. 67 illustrates a process for displaying audio meters. In step 6701, a computer receives multiple audio inputs. In step 6703, the computer displays, on a display screen, sound meters corresponding to the volume of the audio inputs.

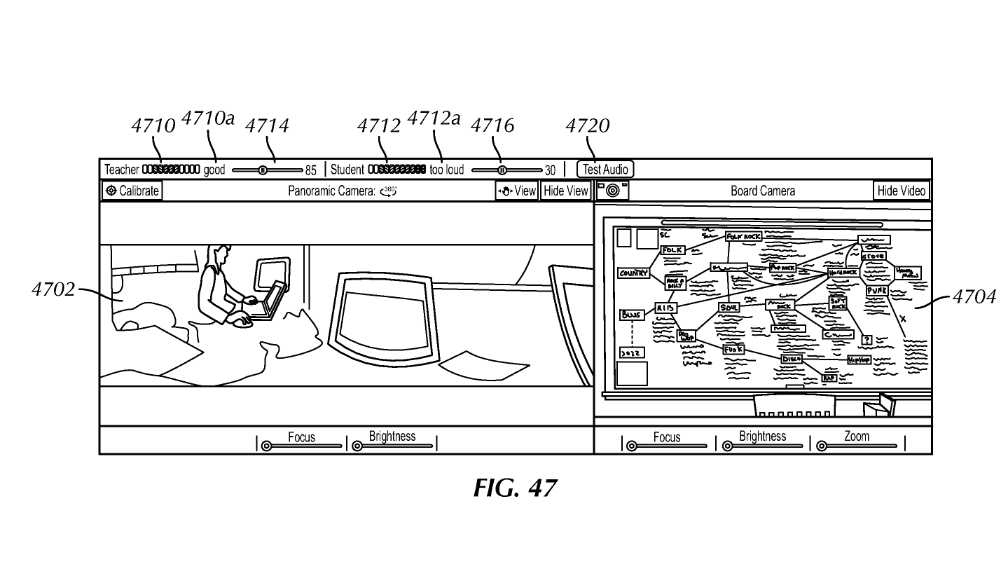

FIG. 47 illustrates one embodiment of a user interface display for previewing and adjusting audio input for capture to include in some embodiments of a multimedia captured observation. The user interface shown in FIG. 47 comprises video displays areas 4702 and 4704, sounds meters 4710 and 4712, volume controls 4714 and 4716, and a test audio button 4720. The video display areas 4702 and 4704 may display one or more still images, a blank screen, or one or more real-time video signals received from one or more cameras placed in proximity of two microphones during the adjustment of audio inputs described hereinafter. Sound meters 4710 and 4712 are visual representations volumes of two audio inputs received at two microphones. Volume controls 4714 and 4716 allow a user to individually adjust the recording volume of the two audio inputs. The test audio button 4720 allows the user to test record an audio segment prior to performing a full video capture.

In some embodiments, sound meters 4710 and 4712 consist of cell graphics that are filled in sequentially as the volume of their respective audio inputs increase. Cells in sound meters 4710 and 4712 may further be colored according to the volume range they represent. For example, cells in a barely audible volume range may be gray, cells in a soft volume range may be yellow, cells in a preferable volume range may be green, and cells in a loud volume range may be red. In some embodiments, sound meters 4710 and 4712 each also include a text portion 4710a and 4712a for assisting the user performing the capture to obtain a recording suitable for playback and performance evaluation. For example, the text portions may read “no sound,” too quiet,” “better,” “good,” or “too loud” depending on the volumes of the audio inputs and their amplification setting. In other embodiments, input audio volumes may be visually represented in other ways known to persons skilled in the art. For example, a continuous bar, a bar graph, a scatter plot graph, or a numeric display can also be used to represent the volume of an audio input. While two audio inputs and two sound meters are illustrated in FIGS. 46 and 67, in some embodiments, there may be only one sound meter or more than three sound meters displayed on the display device 4520, depending on the number of audio inputs that are provided to the computer.

In some embodiment, the volume controls 4714 and 4716 are provided on the user interface for adjusting amplification levels of the audio inputs. In FIG. 47, the volume controls 4714 and 4716 are shown as slider controls. A user can individually adjust the volume of the two audio inputs by selecting and dragging the indicator on the volume controls 4714 and 4716. A user can make adjustments based on information provided on the sound meters 4710 and 4712, or by a test audio recording, to obtain a recording volume suitable for evaluation purposes. In some embodiments, when the user interface is first initiated, the amplification levels of the audio inputs are set at a default level. For example, the default volume might be set at 85 for a microphone that is recording the person being evaluated, and at 30 for a microphone that is monitoring the environment. In other embodiments, volume controls 4714 and 4716 may be other types of controls known to persons skilled in the art. For example, volume controls 4714 and 4716 can be displayed as dials, arrows, or a vertical slider.

In some embodiments, when the test audio button 4720 is selected, the interface displays a test audio module. The test audio module allows a use to record, stop, and playback an audio segment to determine whether the placement of the microphones and/or the volumes set for recording are satisfactory, prior to the commencement of video capture. In other embodiments, a test audio feed may be played to provide real-time feedback of volume adjustment. For example, the person performing the capture may listen to the processed real-time audio feed on an audio headset while adjusting volume controls 4714 and 4716. In some embodiments, one or more audio feeds can be muted during audio testing to better adjust the other audio feed(s).

According to some embodiments, a system and method are provided for recording of audio for use in remotely evaluating performance of a task by of one or more observed persons. The method comprises: receiving a first audio input from a first microphone recording the one or more observed persons performing the task; receiving a second audio input from a second microphone recording one or more persons reacting to the performance of the task; outputting, for display on a display device, a first sound meter corresponding to the volume of the first audio input; outputting, for display on the display device, a second sound meter corresponding to the volume of the second audio input; providing a first volume control for controlling an amplification level of the first audio input and a second volume control for controlling an amplification level of the second audio input, wherein a first volume of the first audio input and a second volume of the second audio input are amplified volumes, wherein, the first sound meter and the second sound meter each comprises an indicator for suggesting a volume range suitable for recording the one or more observed persons performing the task and the one or more persons reacting to the performance of the task for evaluation.

Another button provided to the user throughout the capture process is the Add Photos button which enables the user to take photos to add to the video and audio being captured, e.g., in some embodiments, such photos become part of the multimedia captured observation of the performance of the task.

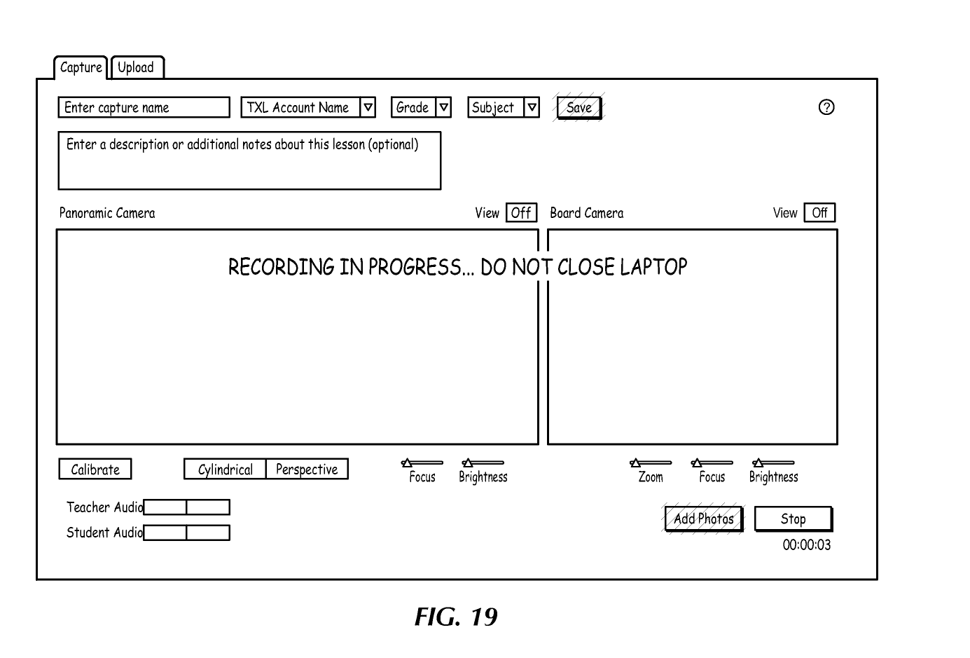

After the teacher/coordinator makes any desirable adjustments to the manner in which video and/or audio will be captured, the user then presses the record button to begin recording the lesson. FIG. 19 illustrates an exemplary user interface display screen displayed to the user while recording is in process. In one embodiment, as shown a message may appear on the screen to prompt the teacher/coordinator that recording is in progress. Furthermore, in this exemplary embodiment, while recording is in progress the add photos button is grayed out such that the teacher cannot add any new photos during the recording process. While the recording is in progress, the capture screen may display a stop button to allow the teacher/coordinator to stop recording at any desired time. Further, as illustrated in FIG. 19 a timer may be provided to display the duration of the recording. In one or more embodiments, once the teacher/coordinator presses the record button no further interaction is needed from the teacher/coordinator until the teacher/coordinator chooses to stop the recording at which time the stop button will be pressed.

When the lesson has finished and the teacher presses the stop button the capture application will automatically save the recorded audio/video to a storage area for later processing and uploading. In one embodiment, once the recording has been terminated, the system may prompt the user automatically to add additional photos to the lesson video. In another embodiment, the add photos button may simply reappear and teacher/coordinator will have the option of pressing the button.

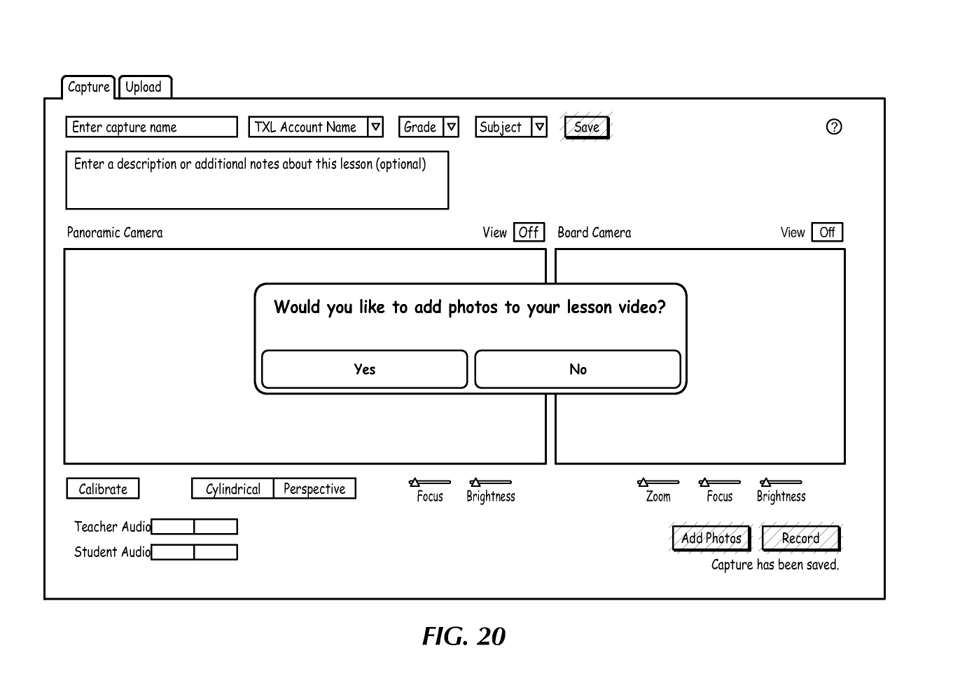

FIG. 20 illustrates an exemplary user interface display screen that will be shown once recording has been terminated and the user is prompted to add additional photos either automatically or after pressing the add photos button. If the user wishes to add photos to the video the user will then be taken to the add picture display screen as shown in FIG. 21. The user is able to take additional photos and select one or more photos for being added to the captured video. Once the teacher/coordinator has made the desired selection, the selection will be confirmed by pressing the OK button and the add photos screen will be closed. In one embodiment, once the add photos screen is closed, the user returns to the capture screen. In another embodiment, the user is taken to the upload screen to begin the upload process.

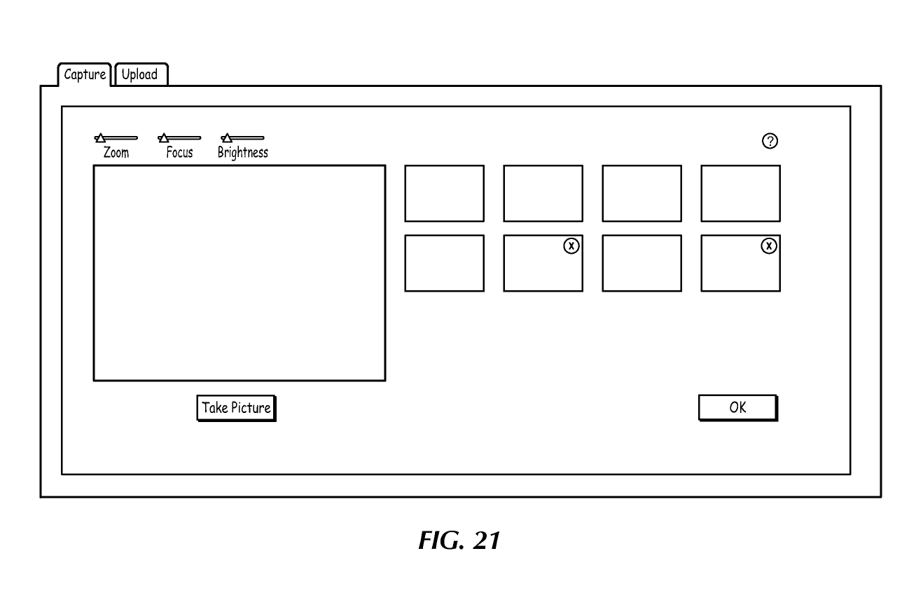

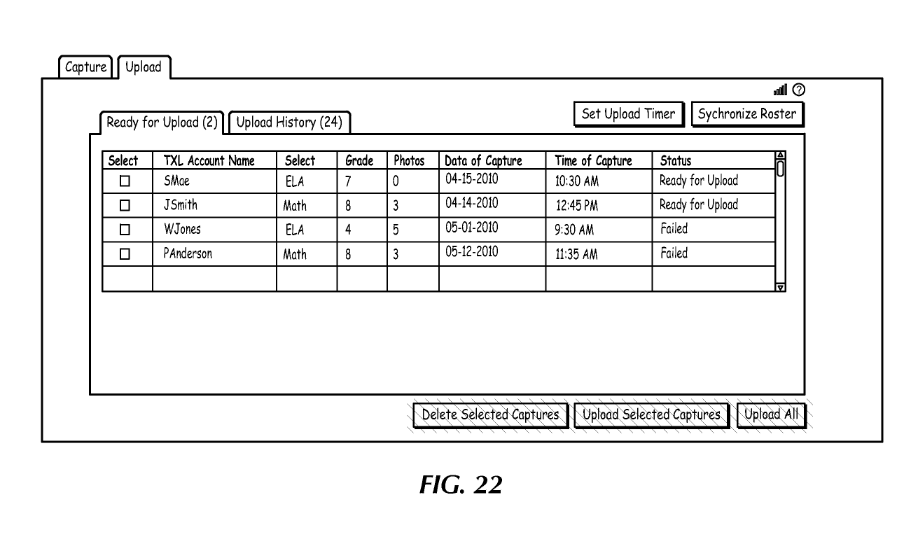

Once the user is at the upload screen, for example, by selecting the upload tab in the capture application, the user will be presented with a list of captured content that is ready to be uploaded to the web application 120. FIG. 22 illustrates an exemplary upload display screen. As illustrated, in one embodiment, the upload screen provides a user with a list of content that has been captured including content that is ready for upload as well as content that includes an error and therefore cannot be uploaded. In another embodiment, content displayed with an error indicator comprise content that have previously failed to be uploaded. In one embodiment, the user has the option of attempting to upload the content or may choose to delete the content from the list. As shown in FIG. 22, the list comprises the account name, subject, grade level, and date and time of the capture of the content, as well as the number of photos included with the content. Further, a status of the content specifying whether the content is ready for upload is provided. In one embodiment, a check box next to each of the content allows the teacher/coordinator to select one or more of the content for upload.

As illustrated in FIG. 22, while viewing the upload display screen, the teacher/coordinator may choose to delete one or more captures, upload selected captures or upload all captures. In one embodiment, one or more of the buttons are grayed out as being unselectable (as shown in FIG. 22) until the user selects one or more of the captures. In addition, the upload screen provides the user with a set upload timer and synchronize roster button.

The set upload timer in one or more embodiments allows the user to select when to start the upload process. For example, a user may consider bandwidth issues, and may set the upload time for a time during the day where there is more bandwidth available where the upload can occur. In one embodiment, the user may select both when to start and end the upload process for one or more selected content within the upload queue. The synchronize roster button, also referred to as the update user list option, allows an update of the list of users that will be available in one or more drop down menus in one or more of FIGS. 11, 12 and 17 of basic information. For example, in one embodiment, the list of users that are available in the drop down menu and can be chosen from may be updated using the update roster/update user list button. In one embodiment, this functionally may require a connection to the internet and may only be made available to the user when the user is connected to the internet.

According to one or more embodiments, the capture application does not have to be connected to the network throughout the capture process and will only need to be connected during the upload process. In one embodiment, to allow for such functionality, the capture application may store any relevant data (available schools, teachers, etc.) locally, for example in the user's data directory residing on a local drive or other local memory. In one embodiment, the content may for example be pre-loaded so that it can be used without having to get the data on-demand. Initial pre-loading may be done when logging in the first time and both aforementioned buttons regulate when that pre-loaded data is verified and possibly updated, which is done either at a certain time (as configured using the ‘set upload timer’ button), or immediately as is the case when pressing the ‘synchronize roster’ button.

In one embodiment, the user may select one or more of the captures ready for upload and select the upload selected capture buttons, at which point, the process of uploading the content is initialized. Once the teacher/coordinator starts the upload process by selecting the upload button, the system then begins to process and upload the content. The capture and upload process is explained in further detail below with respect to FIGS. 7 and 8. In one embodiment, while the content is being uploaded the user may be provided with a message notifying the user that upload is in progress. FIG. 22 illustrates an exemplary embodiment of a display that may be presented to the user (e.g., displayed on the display of the user's computer device) during the upload. Once the upload has been completed and/or terminated for any other reason such as loss of connection, errors in upload, etc., the user may be presented with another pop-up screen notifying the user of the upload status.

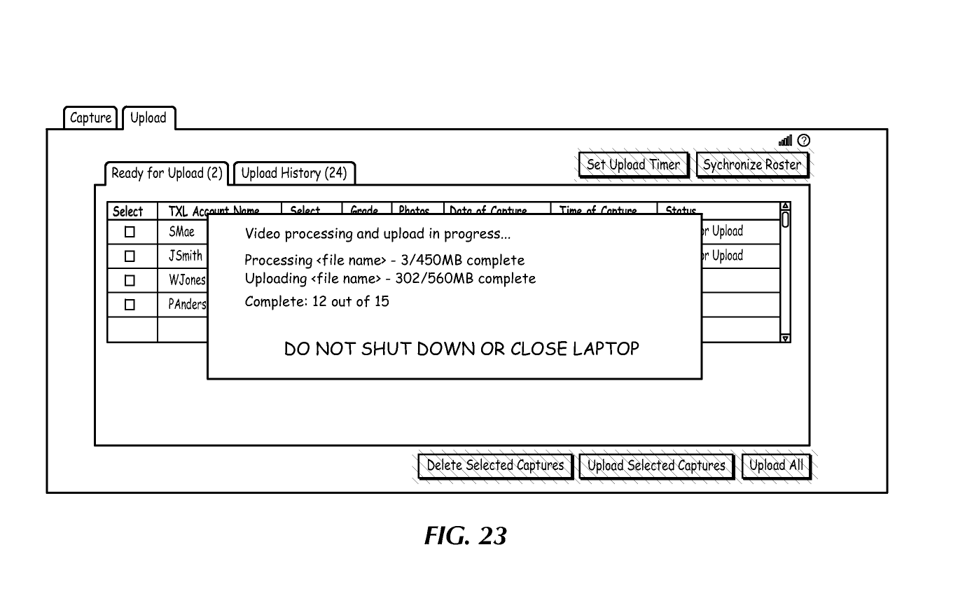

FIG. 23 illustrates an exemplary display screen that may be displayed to the user while the upload is in process. As shown in FIG. 23, the screen may display one or more information regarding the status of the upload such as what content is being uploaded and what percentage of the upload is complete, etc. In other embodiments, other information regarding the upload process may also be displayed while the uploading is being performed.

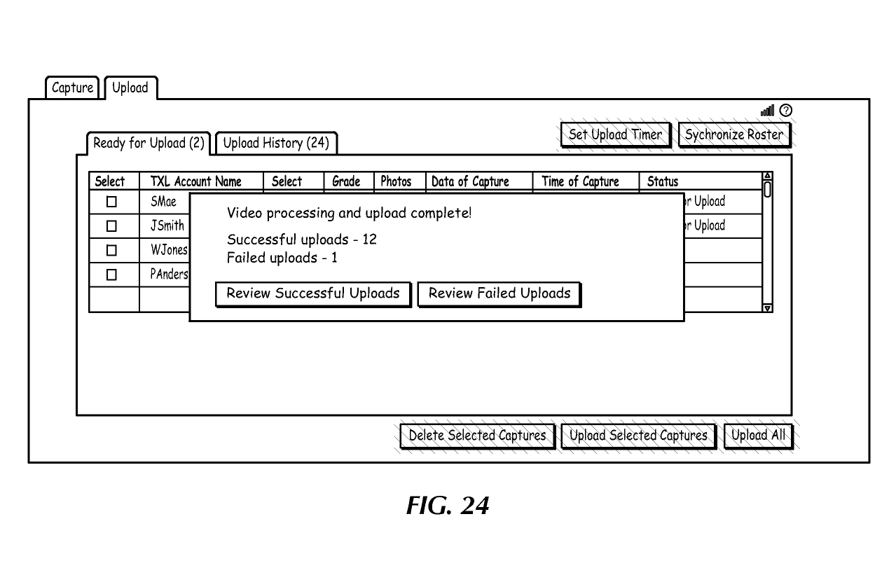

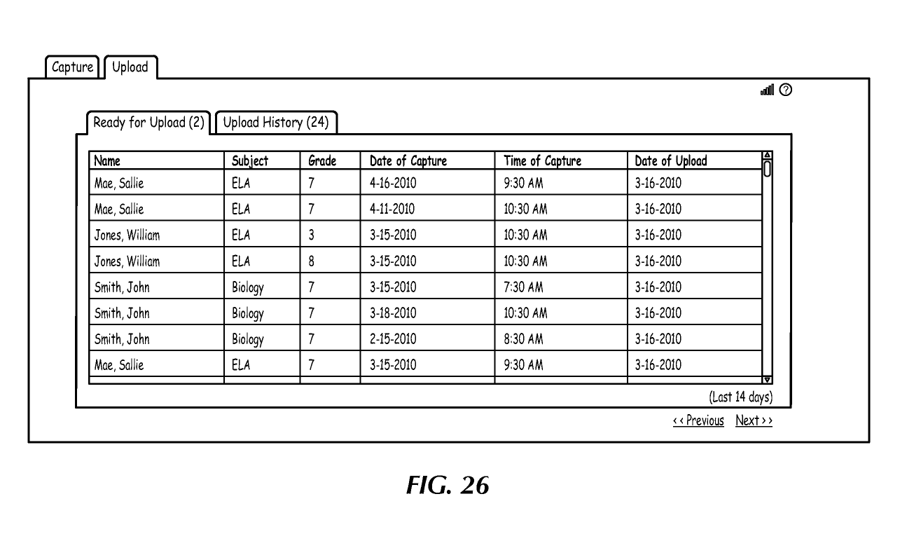

FIG. 24 illustrates the screen displayed upon completion of the upload process. As illustrated, the screen of FIG. 24 notifies the user of the status of successful uploads as well as failed uploads. In one embodiment, a list of each of the successful and failed uploads may be presented to the user enabling the user to attempt to resend the failed uploads. For example, as shown in FIG. 24, two buttons are provided for the user to allow the user to review the successful and failed uploads. FIG. 25 illustrates an exemplary display screen that may be presented to the user when the user selects the view failed uploads button. As shown the screen may display information about the capture as well as the number of attempts made to upload the captured content as well as details relating to each attempt. For example, in one embodiment, as shown in FIG. 25 a table is provided listing each attempt along with the upload date, upload start time, upload end time, percent of content uploaded/completed and reason for upload failure for each attempt. In another embodiment, when the user selects the view failed upload buttons the user is taken back to the upload queue page similar to FIG. 15 or 22 and the user may then select to view the details regarding a specific failed upload. In one embodiment, for example, as shown in FIG. 15 the user may be presented with an option with each upload having a failed upload to view the failed upload details. In such embodiments, when the user selects this option, a screen similar to that of FIG. 25 will be presented to the user for the selected content. A similar screen may be provided for successful uploads with same or similar information as provided for the failed uploads. In another embodiment the successful upload button may direct the user to the upload history tab shown in FIG. 26. The user upon reviewing the information may close the window and return to the upload window.

In addition to the ready for upload screen the upload screen in one or more embodiment also includes a second tab displaying an upload history for all uploads completed in the specific account. In another embodiment, the upload history tab may be presented in a separate tab as illustrated in for example FIGS. 14 and 15. The history may list all uploads completed within a specific period of time. FIG. 26 illustrates an exemplary embodiment of the upload history display screen. As shown, the upload history screen display a list of all uploads along with information relating to each upload including for example the name of the instructor/account name, subject, grade, date of capture, time of capture and date of upload. Other information such as time of capture, etc., may also be displayed in the list. In this exemplary embodiment, the history includes all uploads with the last 14 days. It should be obvious however that a list of uploads for other durations may be available. In one embodiment, for example, the system administrator or owner may be able to customize the application settings to determine what uploads are displayed in the upload history tab. In another embodiment, the user may be able to select between different periods while viewing the upload history list. The upload history screen further provides the teacher/coordinator with navigation buttons to move through the list of uploaded captured content.

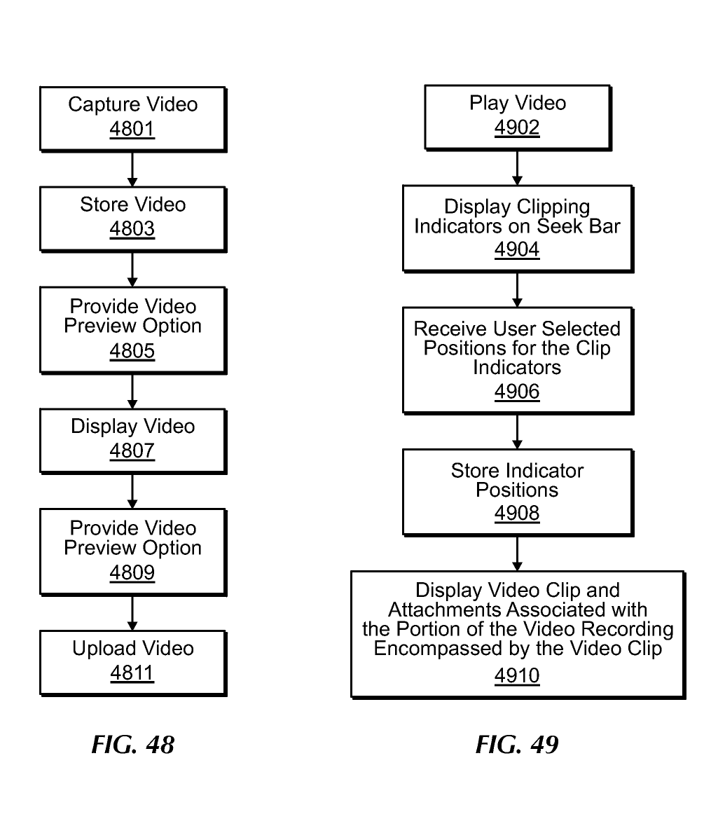

FIG. 48 illustrates an exemplary process for video preview. In step 4801 a video is captured. In step 4803 the captured video is stored. In step 4805 video preview option is provided. In some embodiments, the video preview option is provided in an interface display screen listing videos stored on the local computer. In step 4807, the preview video is displayed on a display device. The preview may be displayed in one or more of the display screens of the user interfaces shown herein or in other exemplary user interfaces. In step 4809, after the video is displayed, an upload option is provided. In some embodiments, the upload option is provided in an interface display screen for listing videos stored on the local computer. In step 4811, the video is uploaded to a server. In some embodiments, by allowing the video preview feature, the user is able to determine if the captured video is complete and suitable for uploading or if another video capture should be performed.

In some embodiments, a similar upload process is used to upload observation notes taken during a live or direct observation session. For example, after a direct observation is recorded on a computer device, a list of direct observations sessions recorded on the computer device can be displayed to the user. The content of a direct observation may contain notes taken during an observation, and may further contain one or more of rubric nodes assigned to the notes, scores assigned to rubric nodes, and artifacts such as photos, documents, audio, and videos captured during the session. The user may preview and modify some or all of the content prior to uploading the content. In some embodiments, the user may view the upload status of direct observations, and view a history of uploaded direct observations.

### Process Overview—Web Application

Next, with reference back to FIG. 3, the process of interacting with content by accessing the web application from a user's computer is described. First, during the process as illustrated in FIG. 3, in step 310 a remote user logs into the web application which is hosted by the remote server, e.g., the web application server. The web application server can be more generically described as a computer device, a networked computer device, a networked server system, for example. In one embodiment, the web application is accessible from the local computer 110 and/or one or more of the remote computers 130. In one embodiment, to access the web application, the computer must include some specific software or application necessary for running the web application, such as a web browser. In one embodiment, for example, one or more of the user computer 210 and remote computer 230 will have Flash installed to enable running of the web application. In one or more embodiments, the local computer 210 and remote computers 230 will be able to access the web application through any web browser installed at the computers. In another embodiment, specific software may be provided to and installed at the user computer 210 and/or remote computers 230 for running the web application. In one embodiment, upon accessing and initializing the web application the user will then be provided with a login screen to enter the web application and to view and manage one or more captured content available at the web application. It is noted that a similar web application may also be provided to allow for interaction with the computer device 6804 of FIG. 40.

After the user has logged into the system, the process of FIG. 3 will then continue to step 312 and allow the user to manage recorded content available in user's catalog or library, including editing metadata, and/or deleting one or more observations from the library. An observation in the library may be a video observation or a direct observation. In some embodiments, a video observation contains multimedia content items (e.g., video and audio content) captured of a performance of a task and any associated artifacts. In some embodiments, a video observation contains one or more videos and one or more audio files or content items captured of a performance of a task. Throughout the application, a video observation is sometimes described as multi-media captured observation or video captured observation. In some embodiments, a direct observation contains notes, comments, etc. taken during a live observation session and any artifacts described herein relating to an observed person performing a task, such as documents, lesson plans and so on. Throughout the application, a direct observation is sometimes described as live observation. In some embodiments for example, the user is able to select one or more observation content items from the user's library or catalogue once logged into the system and is able to edit the basic metadata that was previously entered and may add further description, etc. The user may additionally select one or more observation content items from the library for deletion. In one embodiment as shown in FIG. 3 at any point after the user has logged into the system, the user may access one or more observations in the users catalog and may share the video or direct observation contents with other users of the system. In one embodiment, after each of the steps 310-316, the user is able to continue to step 318 and/or 320 and share one or more observation content or a collection of contents with workspaces, user defined groups and/or individual users.

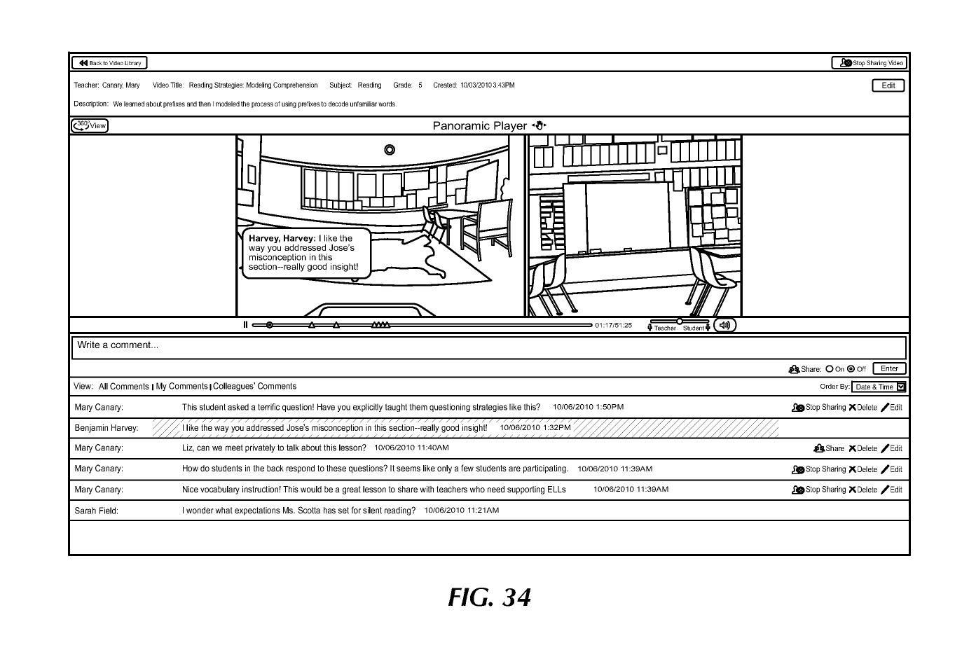

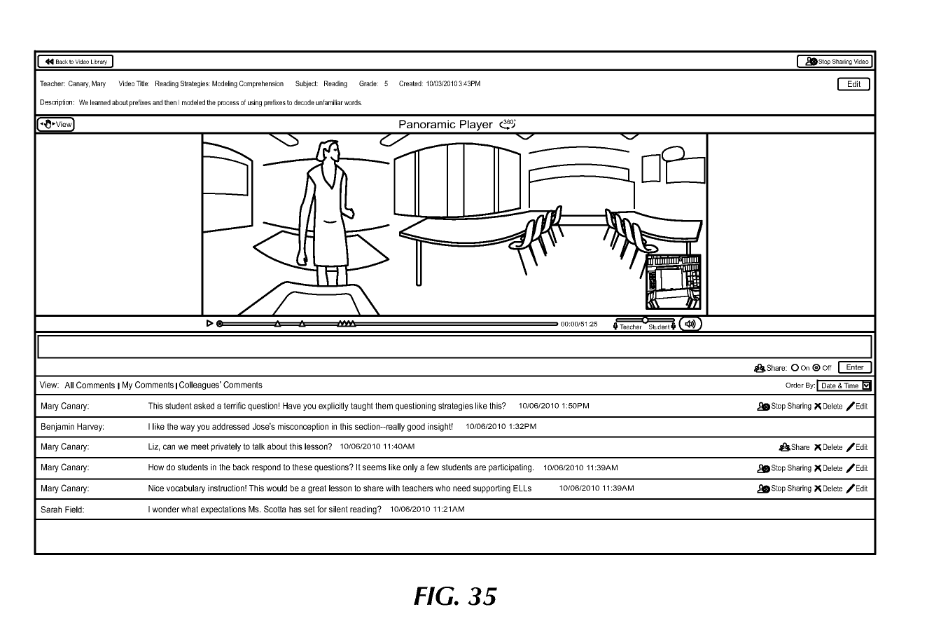

Next, in step 314, in addition to managing observation contents in the user's library or catalog, the user is able to view one or more video observations within the library and annotate the videos by entering one or more comments and tags to the video. FIGS. 34 and 35 provide exemplary display screen shots of one embodiment of the web application illustrating means by which the user is able to view and annotate one or more videos within the library and will be explained in further detail below. User may also enter and modify annotations and associations to one or more rubric nodes of a direct observation, such annotations and associations to rubric nodes or elements become part of the direct observation in some embodiments.

In one embodiment, after editing one or more observation content items, the user has the option to selectively share the observation content items with other users of the web application, e.g., example by setting (turning on or off, or enabling) a sharing setting. In one embodiment, the user is pre-associated with a specific group of users and may share with one or more such users. In another embodiment, the user may simply make the video public and the video will then be available to all users within the user's network or contacts.

In a further embodiment, the user is further able to create segments of one or more videos within the video library. In one embodiment, a segment is created by extracting a portion of a video within a video library. For example, in one embodiment the web application allows the user to select a portion of a video by selecting a start time and end time for a segment from the duration of a video, therefore extracting a portion of the video to create a segment. In one embodiment, these segments may be later used to create collections, learning materials, etc. to be shared with one or more other users.

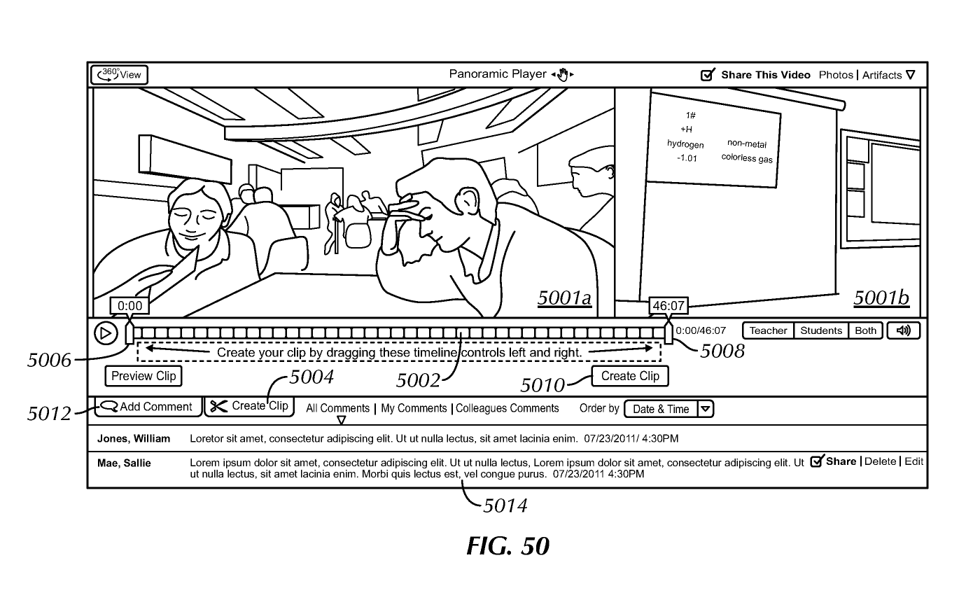

FIGS. 49 and 50 illustrate one embodiment of a process for creating a video segment and a screen capture thereof. The screen capture illustrates an interface having video display areas 5001a and 5001b, a seek bar 5002, a start clip indicator 5006, an end clip indicator 5008, a create clip tab 5004, a create clip button 5010, and a preview clip button 5012.

First, in step 4902, a video is displayed in display area 5001a on a display device to a user through a video viewer interface. In step 4904, when the user selects the “create clip” button 5004, the clip start time indicator 5006 and the clip end time indicator 5008 are displayed on the seek bar 5002. Additionally, the “create clip” button 5010 and the “preview clip” button 5012 are also displayed on the interface. In step 4906, the user positions the clip start time indicator 5006 and the clip end time indicator 5008 at desired positions. In some embodiments, after the placement of the clip start time indicator 5006 and the clip end time indicator 5008, the user may preview the clip by selecting the “preview clip” button 5012. In step 4908, when the user select the “create clip” button 5010 the positions of the clip start time indicator 5006 and the clip end time indicator 5008 are stored. In some embodiments, the newly created video clip appears in the user's video library as a video the user can rename, share, comment, and add to a collection. In step 4910, when the user, or another user who with access to the vide clip, selects the video clip to play, the video viewer interface retrieves the segment from the original video according to the stored position of the clip start time indicator 5006 and the clip end time indicator 5008 and displays the video segment.

In other embodiments, when the user selects the “create clip” button 5010, a new video file is created from the original video file according to the positions of the clip start time indicator 5006 and the clip end time indicator 5008. As such, when the video clip is subsequently selected for playback, the new video file is played.

In some embodiments, the video in display area 5001a is associated and synched to a second video in display area 5001b and/or one or more audio recordings. When the video clip created in step 4908 is played, the associated video in display area 5001b and the one or more audio recordings will also be played in the same synchronized manner as in the original video in display area 5001a. In other embodiments, when a clip is created, the user is given the option to include a subset of the associated video and audio recordings in the video clip.

In some embodiments, the original video in display area 5001a includes tags and comments 5014 on the performance of the person being recorded in the video capture. When the video clip is played, tags and comments that are entered during the portion of the original video that is selected to create the video clip is also displayed. In other embodiments, when a clip is created, the user is given the option to display all tags and comments associated with the original video, display no tags and comments, or display only a subset of tags and comments with the video clip.

In some embodiments, artifacts such as photographs, presentation slides, and text documents are associated with the original video in display area 5001a. When the video clip created from an original video with artifacts is played, all or part of the associated artifacts can also be made available to the viewer of the video clip.

Next, in step 316 the user may create a collection comprising one or more videos and/or segments, direct observation contents within the library, photos and other artifacts. In one embodiment, while the user is viewing videos the user can add photos and other artifacts such as lesson plans and rubrics to the video. In addition, in some embodiments, the user is further able to combine one or more videos, segments, direct observation notes, documents such as lesson plans, rubrics, etc., and photos, and other artifacts to create a collection. For example, in one embodiment, a Custom Publishing Tool is provided that will enable the user to create collections by searching through contents in the library, as well as browsing content locally stored at user's computer to create a collection. In one or more embodiments, the extent to which a user will be able to interact with content depends upon access rights of the user. In one embodiment, to create a collection, a list of content items is provided for display to a first user on a user interface of a computer device, the content items relating to an observation of the one or more observed persons performing a task to be evaluated, the content items stored on a memory device accessible by multiple users to a first user, wherein the content items comprise at least two of a video recording segment, an audio segment, a still image, observer comments and a text document, wherein the video recording segment, the audio segment and the still image are captured from the one or more observed persons performing the task, wherein the observer comments are from one or more observers of the one or more observed persons, and wherein a content of the text document corresponds to the performance of the task. Next, a selection of two or more content items from the list is received from the first user to create the collection comprising the two or more content items.

In some embodiments, the data that is available to the user in the Custom Publishing tool depends upon the user's access rights. For example, in one embodiment, a user having administrative rights will have access to all observation contents of all users in a workspace, user group, etc. while an individual user may only have access to the observations within his or her video library.

Next, in step 318 the user can share the collection with one or more workspaces. A workspace, in one or more embodiments, comprises a group of people having been pre-grouped into a workspace. For example, a workspace may comprise all teachers within a specific school, district, etc. Alternatively or additionally the process may continue to step 320 where the user is able to share collections with individual or user defined groups. In one embodiment, collection sharing is provided by providing a share field for display on the user interface to a first user to enter a sharing setting relating to created collection. The user selects, and the system receives the sharing setting from the first user, saves it, and determines whether to display the collection to a second user when the second user accesses the memory device based on the sharing setting.

In addition, when logged into the system, the user may access observations shared with the user. In some embodiments, to the user is able to interact with and evaluate these observation contents posted by colleagues, i.e. other users of the web application associated with the user in step 322. In one embodiment, during step 322, a user is able to review and comment on colleagues' videos when these videos have been shared with the user. In one embodiment, such videos may reside in the user's library and by accessing the library the user is able to access these videos and view and comment on the videos. In some embodiments, in addition to commenting on videos, the web application may further provide the user the ability to score or rate the shared videos. For example, in one embodiment, the user may be provided with a grading rubric for a video, a direct observation notes, or a collection and may provide a score based on the provided rubric. In some embodiments, the scoring rubrics provided to the user may be added to the video or the direct observation notes by an administrator or principal. For example, as described above, in one embodiment, the administrator or principal may create a collection by providing the user with a rubric for scoring as well as the video or direct observation notes and other artifacts and metadata as a collection which the user can view.

In one embodiment, the system facilitates the process of evaluating captured lessons by providing the user with the capability to provide comments as well as a score. In one embodiment, the scoring and evaluating uses customized rubrics and evaluation criteria to allow for obtaining different evidence that may be desirable in various context. In one embodiment, in addition to scoring algorithms and rubrics, the system may further provide the user with instructional artifacts to further the raters understanding of the lesson to further improve the evaluation process.

In one embodiment, before the evaluation process, one or more principals and administrators may access one or more videos that will be shared with various workspaces, user groups and/or individual users and will tag the videos for analysis. In one embodiment, tagging of the video for evaluation is enabled by allowing the administrator or principal to add one or more tags to the video providing one or more of a grading rubric, units of analysis, indicators, and instructional artifacts. In one embodiment, the tags provided point to specific temporal locations in the lesson and provide the user with one or more scoring criteria that may be considered by the user when evaluating the lesson. In one embodiment the material coded into the lesson comprises predefined tags available by accessing one or more libraries stored at the system at set-up or later added by an administrator of the system into the library. In one embodiment, all protocols and evaluating material may be customizable according to the context of the evaluation including the characteristics of the lesson or classroom environment being evaluated as well as the type of evidence that the evaluation is aiming to obtain.

In one or more embodiments, rubrics may comprise one or more of an instructional category of a protocol, one or more topics within an instructional category, one or more metrics for measuring instructional performance based on easily observable phenomena whose variations correlate closely with different levels of effectiveness, one or more impressionistic marks for determining quality or strength of evidence, a set of qualitative value ranges or ratings into which the available indicators are grouped to determine the quality of instruction, and/or one or more numeric values associated with the qualitative value ranges or criteria ratings.

In one or more embodiments, the videos having one or more rubrics and scoring protocols assigned thereto are created as a collection and shared with users as described above. Next, the user in step 322 accesses the one or more videos and is able to view and provide scoring of the videos based on the rubrics and tags provided with the collection, and may further view the instructional materials and any other documents provided with the grading rubric for review by the user.

In one embodiment, the web application further provides extra capabilities to the administrator of the system. For example, in one embodiment, a user of the web application may have special administrator access rights assigned to his login information such that upon logging into the web application the administrator is able to perform specific tasks within the web application. For example, in one embodiment, during steps 330 the administrator is able to access the web application to configure instruments that may be associated with one or more videos, collections, and/or direct observations to provide the users with additional means for review, analyzing and evaluating the captured content within the web application. One example of such instruments is the grading protocol and rubrics which are created and assigned to one or more videos to allow evaluation of videos or a direct observation. In one or more embodiments, the web application enables the administrator to configure customized rubrics according to different considerations such as the context of the observation as well as the overall purpose of the evaluation or observation. In one embodiment rubrics are a user defined subset of framework components that the video will be scored against. In some embodiments, frameworks can be industry standards (ex. Danielson Framework for Teaching) or custom frameworks, e.g. district specific frameworks. In one embodiment, one or more administrators may have access rights to different groups of videos and collections and/or may have access to the entire database of captured content and may assign the configured rubric to one or more of the videos, collection or entire system during step 332. In some embodiments, more than one instrument may be assigned to a video or direct observation.

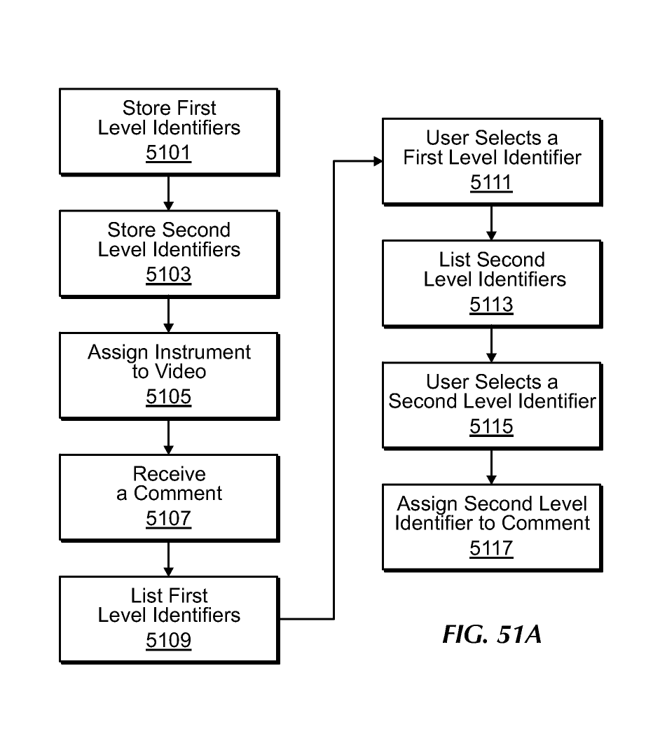

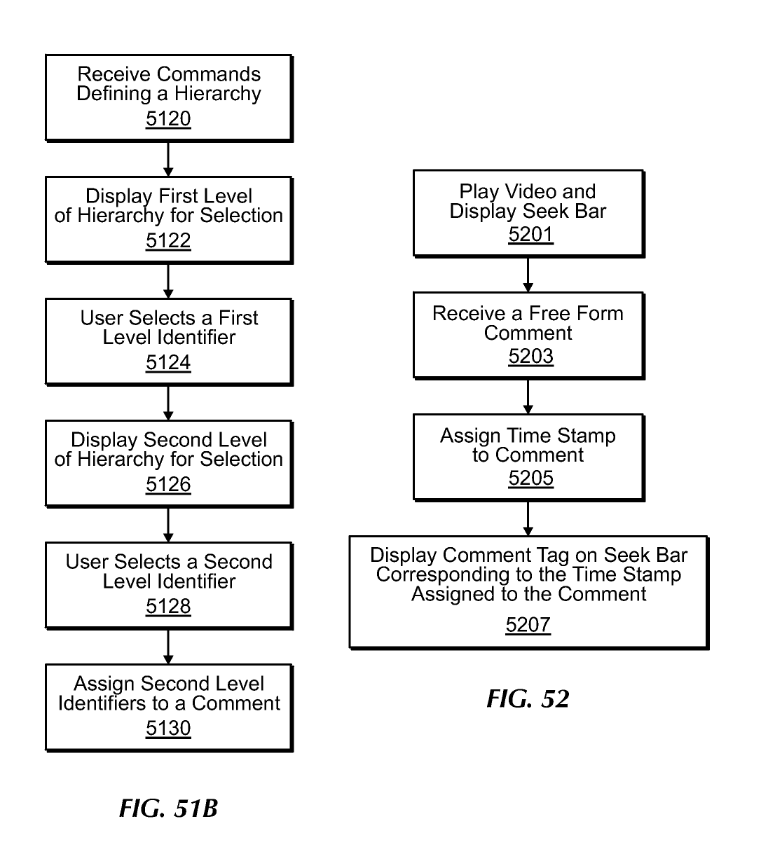

FIG. 51A illustrates one embodiment of a process for creating a customized instrument or rubric for performance evaluation. In step 5101, one or more first level identifiers are stored. In step 5103, after at least one first level identifier is stored, the interface allows the user to enter second level identifiers 5103 and to associate the second level identifiers to at least one first level identifier. For example, the first level identifiers may represent domains in the Danielson Framework for Teaching, and the second level identifiers may represent components. While FIGS. 51A and 51B illustrate two levels of hierarchy, the user may enter additional levels of hierarchy by associating an identifier with a stored identifier of a higher level. For example, a third level identifier can be entered and associated to a second level identifier. The third level identifier may be, for example, an element in the Danielson Framework for Teaching. It is understood that Danielson Framework is only described here as an example of a hierarchical instrument used for performance evaluation. Administrator may completely customize an instrument to suit their evaluation needs.

In some embodiments, a computer implemented method of customizing a performance evaluation rubric for evaluating performance a task by observed person/s includes providing a user interface for display on a computer device and for allowing entry of at least a portion of a custom performance rubric by a first user. Next, the system receives, via the user interface, first level identifiers belonging to a first hierarchical level of a custom performance rubric being implemented to evaluate the performance of the task by the one or more observed persons based at least on an observation of the performance of the task. These first level identifiers are stored. Then the system receives, via the user interface, one or more lower level identifiers belonging to one or more lower hierarchical levels of the custom performance rubric, wherein each lower level identifier is associated with at least one of the plurality of first level identifiers or at least one other lower level identifier. The first level identifiers and the lower identifiers of the custom performance rubric correspond to a set of desired performance characteristics specifically associated with performance of the task. And the one or more lower level identifiers are stored in order to create the custom rubric or performance evaluation rubric. It is understood that the observation may be one or both of a multimedia captured observation and a direction observation. In some embodiments, the custom performance rubric is a modified version of an industry standard performance rubric (such as the Danielson framework for teaching) for evaluating performance of the task.

In step 5105, after an instrument is defined, the instrument can then be assigned to a video or a direct observation for evaluating the performance of person performing a task. In some embodiments, the assigning of instrument to an observation may be restricted to administrators of a workgroup and/or the person who uploaded the video. In some embodiments, more than one instrument can be assigned to one observation.

In some embodiments, one or more instruments may be assigned to a direct observation prior to the observation session, and the evaluator will be able to use the assigned instrument during the observation to associate notes taken during the observation to elements of the instrument(s). In some embodiments, one or more instruments may be assigned to a direct observation after the observation session, and the evaluator can assign elements of the assign instrument(s) to the comments and/or artifacts recorded during the observation session after the conclusion of the observation session.

In step 5107, when a tag or a comment is entered for an observation with an assigned instrument, a list of first level identifiers is displayed on the interface for selection. In step 5109, a list of first level identifier is provided. In step 5111, a user can select a first level identifier from the list of first level identifiers. In step 5113, after a first level identifier is selected, second level identifiers that are associated with the selected first level identifier are displayed. In step 5115, user may then select a second level identifier. In step 5117, if the second level is in the end level of the hierarchy, the second level identifier would be assigned to the tag or the comment. While FIG. 51A illustrates a process involving a two level hierarchy, in other embodiments, if there are lower level identifiers associated with the selected identifier, the next level of identifiers is be displayed. This process may be repeated until an end level identifier is selected. An end level identifier may be, for example, a node or an element in an evaluation rubric. In some embodiments, a comment is associated to a portion of the custom performance rubric by first receiving the comment related to the observation of the performance of the task, then outputting the plurality of first level identifiers for display to a second user for selection. Next, a selected first level identifier is received from the second user, and a subset of the plurality of lower level identifiers that is associated with the selected first level identifier is output for display to the second user. Then, an indication to correspond the comment to a selected lower level identifier is received and the selected lower level identifier is assigned to the comment evaluating performance of the one or more observed persons.

In another embodiment, the user may submit a set of computer readable commands to define an instrument. For example, the user may upload extensible markup language (XML) codes using predefined markups, or upload codes written in another machine readable language. For example, in the process illustrated in FIG. 51A, a set of computer readable commands defining a hierarchy is first received in step 5120. After the commands are read and the hierarchy is stored in a memory device, users accessing the application can then assign elements of the hierarchy to a comment. Steps 5122 to 5130 are similar to steps 5109 to 5117 in FIG. 51A and a detailed description of steps 5122 to 5130 is therefore omitted. By way of example, and in general terms, in some embodiments, a computer-implemented method is provided for creation of a performance rubric for evaluating performance of one or more observed persons performing a task, including first providing a user interface for display on a computer device and for allowing entry of at least a portion of a custom performance rubric by a first user. Then, machine readable commands (such as XML codes) are received from the first user describing a custom performance rubric hierarchy comprising a pre-defined set of desired performance characteristics specifically associated with performance of the task based at least on an observation of the performance of the task, wherein command strings are used to define a plurality of first level identifiers belonging to a first level of the custom performance rubric hierarchy and a plurality of second level identifiers belonging to a second level of the custom performance rubric hierarchy, wherein each of the plurality of second identifiers is associated with at least one of the plurality of first level identifiers. Again, as with many of the embodiments herein, the observation may include one or both of a captured video observation and a direct observation of the one or more observed persons performing the task.

In one or more embodiments, the uploaded machine readable commands are immediately analyzed by the web application. An error message is produced if the uploaded machine readable commands do not follow a predefined format for creating a hierarchy. In one or more embodiments, after the machine readable commands are uploaded, a preview function is provided. In the preview function, the hierarchy defined in the commands is displayed in navigable and selectable form, similar to how the hierarchy will be displayed to a user selecting a rubric node to assign to a comment.

While FIGS. 51A and 51B are described in terms of creating an evaluation instrument for a video observation, the instruments created can also be applied to other types of observation. For example, a custom instrument can be assigned to notes taken during a direct observation or results of a walkthrough survey. When a custom instrument is assigned to a direct observation, an evaluator performing a direct observation can use the web application or an offline version of the application to make observation notes during the direct observation session, and assign rubric nodes to the notes either during or after the observation session.

Furthermore, in step 334 administrators are able to generate customized reports in the web application environment. For example, in one embodiment, the web application provides administrators with reports to analyze the overall activity within the system or for one or more user groups, workspaces or individual users. In one embodiment, the results of evaluations performed by users during step 322 may further be analyzed and reports may be created indicating the results of such evaluation for each user, user group, workspace, grade level, lesson or other criteria. The reports in one or more embodiments may be used to determine ways for improving the interaction of users with the system, improving teacher performance in the classrooms, and the evaluation process for evaluating teacher performance. In one embodiment, one or more reports may periodically be generated to indicate different results gathered in view of the user's actions in the web application environment. Administrators may additionally or alternatively create one time reports at any specific time.

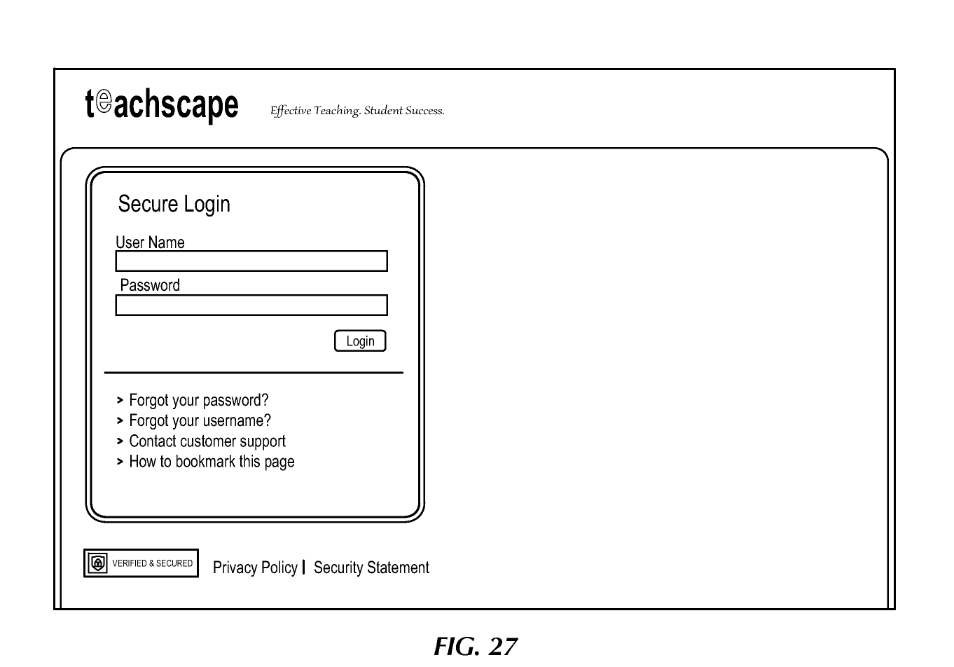

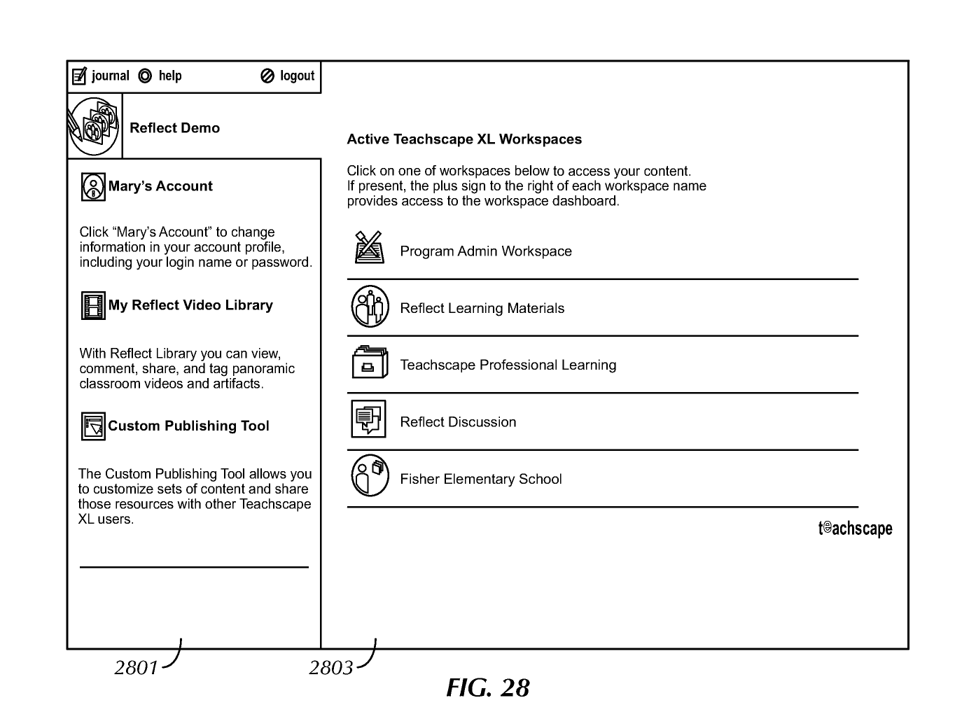

FIGS. 27-40 illustrate exemplary user interface display screens of the web application that are displayed to the user when performing one or more of the steps 310-334. FIG. 27 illustrates an exemplary login screen for the web application. During the login process, the remote user is asked to enter a user name and password, or similar information to log into the web application. Upon the user being logged into the web application, the user is presented with a screen, such as the screen shown in FIG. 28 and may choose among various options to interact with one or more videos, observation content, or collections including managing remote user's uploaded content such as reviewing and editing content uploaded by the user, sharing uploaded content with other users, viewing, analyzing and evaluating shared videos uploaded by other users that the remote user has access to, creating one or more content collections, creating one or more instruments and/or reports. In one embodiment, the options available to the user depend upon the access rights associated with the user's account.

FIG. 28 illustrates an exemplary home page screen that may be displayed once the user logs into the web application. As illustrated, upon login the user will have a list of actions provided on the side bar 2801 of the screen. For example, the user may select to edit his/her account profile, view, comment, share and tag videos and artifacts, and/or customize sets of content and share these customized resources with other users. In one embodiment, the user is further provided with a list of work spaces 2803 such as program admin workspace, Reflect learning material, Teachscape professional learning, King Elementary School (education institution specific workspace) and Reflect discussion. In one embodiment, a workspace refers to a group of users and/or a selection of materials that are made available to the users. In one embodiment, the learning material workspace contains materials for training purposes. In one or more embodiments, the options displayed on the welcome page of the web application depend upon the access rights of the user. These access rights may be assigned by system administrators or other entities and may effect what options and information is available to the user while interacting with the web application.

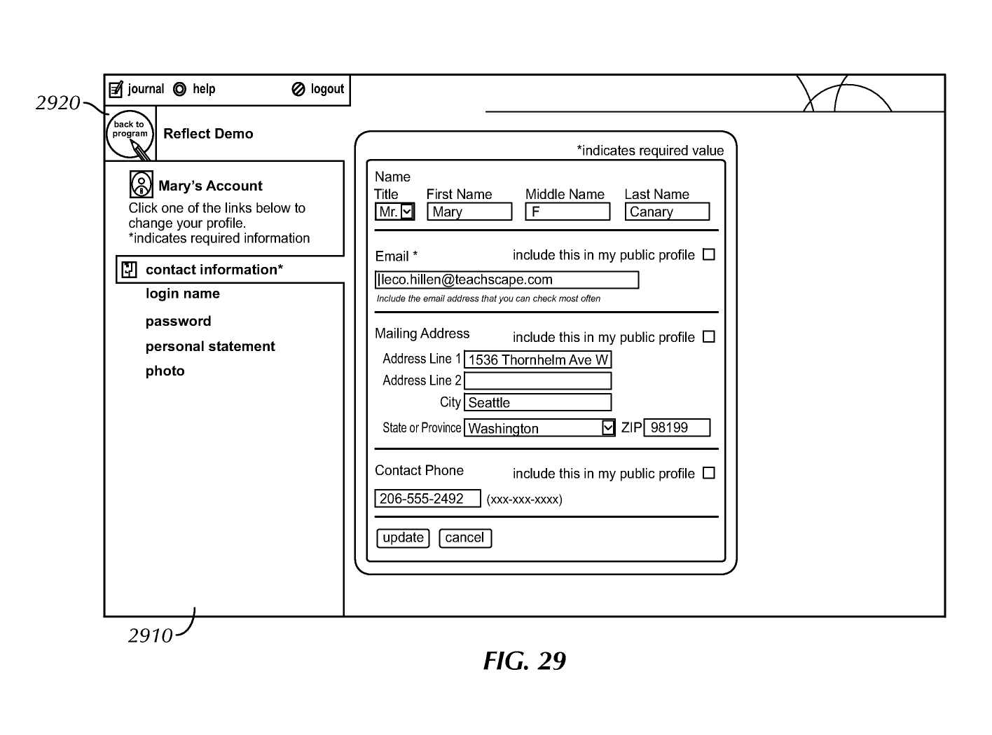

FIG. 29 illustrates an exemplary user interface display screen displayed at the user display device after the user selects the user account option from the home page. As shown, several links will appear on the side bar 2910 enabling the user to edit one or more of contact information, login name, password, personal statement, and photos.

After the user has satisfactorily completed editing his/her account information, the user is able to return to the home page by selecting the back to program option 2920 on top of the side bar of the homepage illustrated in the screen of FIG. 28 and may select another option.

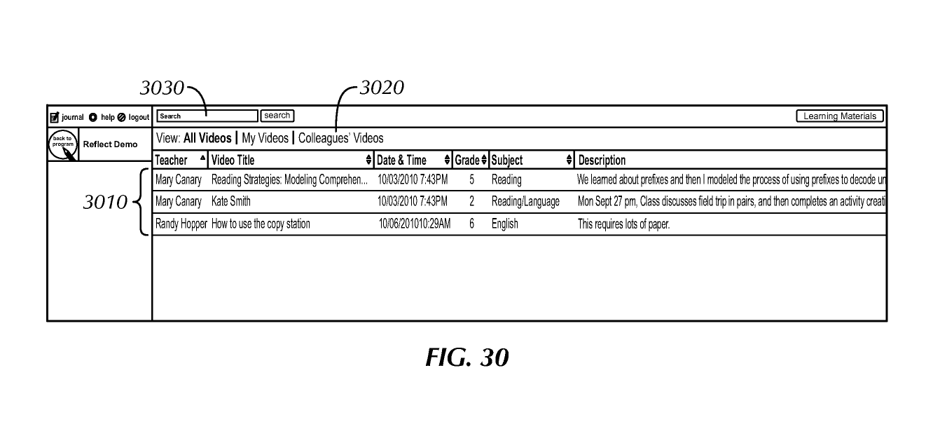

For example, in one embodiment, the user will select the My Reflect Video Library link which will direct the user to a screen having a list of all captured content available to the user. FIG. 30 illustrates an exemplary embodiment of a display screen that may be presented to the user upon selecting the My Reflect Video Library link. As illustrated a list of videos 3010 will be provided to the user. In one embodiment, the user is able to switch between viewing all videos including both the user's own captured videos, i.e. those uploaded by the user from his/her capture application as well as videos by other users which have been shared with the user, or may choose to view only the user's videos or videos by other users using the links 3020 provided on top of the list of videos 3010. In one embodiment, the list provides the user with one or more information regarding the videos such as the teacher, video title, date and time, grade, subject and description associated with the video. In another embodiment, the list may further include an indication of whether the video has been shared with other users of the web application. The user is further provided with a search window 3030 for searching through the displayed videos using different search criteria such as teacher name, video title, data and time of capture or upload, grade, subject, description, etc. In one or more embodiments, in addition, a learning materials link 3040 is provided to the user to provide the user with learning materials while the user is in the video library.

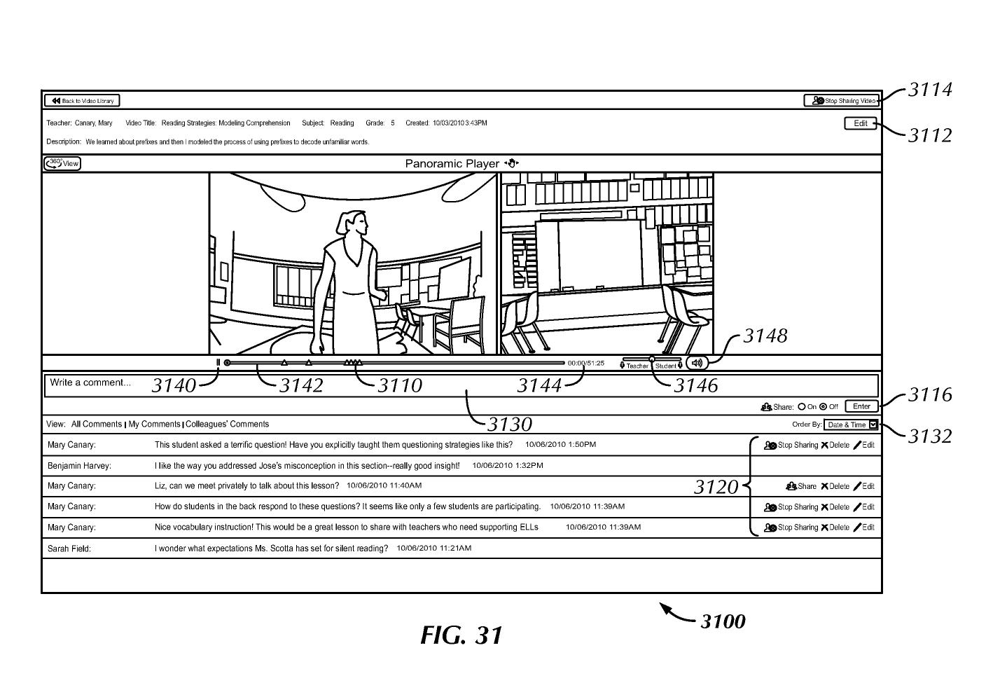

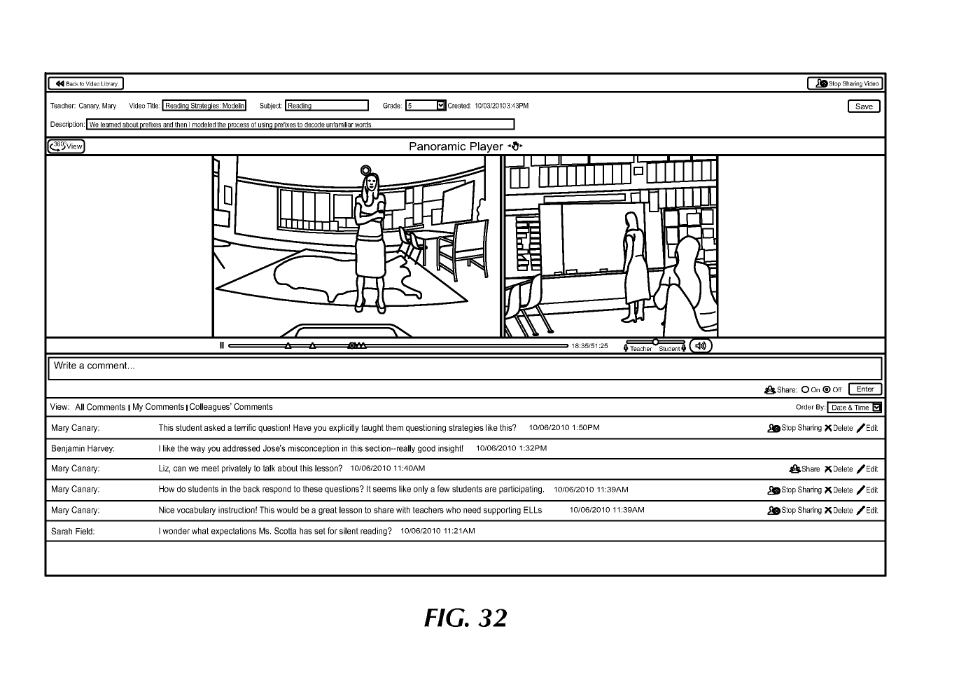

In one or more embodiments, by clicking on each of the content in the video library the user will be able to view the content in a separate window and will be able to enter comments and tags for the content being viewed. FIG. 31 illustrates an exemplary display screen that may be provided to the user once the user clicks on one of the videos in the video library owned by the user. As illustrated, the video is displayed to the user along with comments associated with the video. In one embodiment, as illustrated in FIG. 31, the display area 3100 will display the panoramic video as well as the board video. Basic information regarding the video such as the teacher name, video tile, subject, grade and time and date the content was created is also displayed to the user in the display screen. In one embodiment, a description of the video is also provided to the user. In one or more embodiments, the teacher is able to access the information fields and may be able to edit the basic information to make any corrections or modifications. For example, as displayed in FIG. 31, an edit button 3112 or selectable icon may be provided for the user. Upon selecting the edit button, the user is then enabled to edit some or all of the information associated with the selected video being displayed in display area 3100. In one embodiment, this may be possible only for the user's own videos and the user cannot modify any information regarding videos owned by other users of the web application that are shared with the user. FIG. 32 illustrates a display screen that is presented to the user when the user selects the edit button. Once the user has finished editing the information, the user will select the save button and be presented with the screen similar to FIG. 31 displaying the edited information.

In one embodiment the display area 3100 further comprises playback controls such as a play/pause button 3140, a seek bar 3142, a video timer 3144, an audio channel selector/adjustor 3146 (e.g., slide between teacher and student audio) and a volume button 3148.

The user is further provided with a means of annotating the video at specific times during the video with comments, such as free-form comments. For example, as displayed the screen of FIG. 31 includes a comment box 3130 where a user is able to enter comments. In one embodiment, a tag 3110 appears on the seek bar 3142 to specify the position within the video that the comment was entered. In some embodiments, the added comment further appears below the display area 3120. In one embodiment, the user enters a comments using a keyboard or other input means into the comment box 3130 and selects the enter button to submit the comment. In some embodiments, the user is able to specify on a comment by comment basis, for example, whether the entered comment will remain private or be shared with other users having access to the video. For example, in this embodiment, the comment box 3130 comprises a share on/off field 3116 for allowing the user to select whether the comment is shared with others or remains private and can only be viewed by the user.

FIG. 52 illustrates a method for annotating a video (e.g., a portion of captured observation) with free-form comments. First, in step 5201, a video is played in a viewer application and a seek bar is displayed along with the video to show the playback position of the video relative to the length of the video. In step 5203, a free-form comment is entered during the video playback. In step 5205, the application assigns a time stamp to the free form comment. In some embodiments, the free form comment may be text entered through an input device, a voice recording, an image file containing written notes or illustrations, or another video recording. A comment may also be a tag without any content, or a tag with a rubric node assignment.

In one or more embodiments, the time stamp corresponds to the time a commenter first began to compose the comment. For example, for a text comment, the time stamp corresponds to the time the first letter is typed into a comment field. In other embodiments, the time stamp corresponds to the time when the comment is submitted. For example, for a text comment, the time stamp corresponds to the time the commenter selects a button to submit the comment. In step 5207, a video with previously entered comments is played, and comment tags are shown on the seek bar at positions corresponding to the time stamp assigned to each comment.

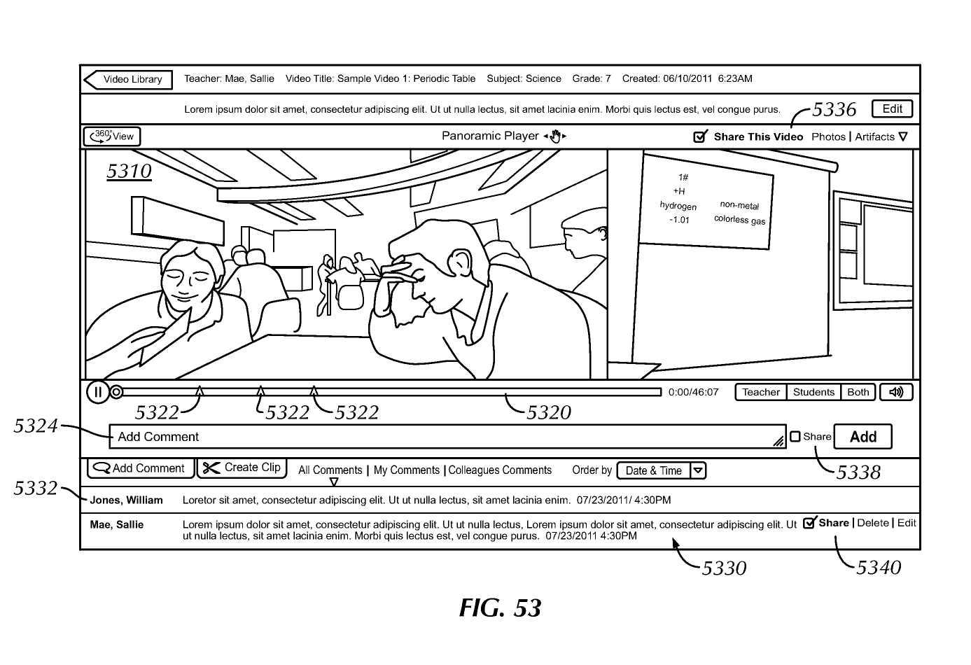

FIG. 53 is a screenshot of an embodiment of a video viewer interface display for displaying text comments with a video playback. The video viewer interface includes a video display portion 5310, a seek bar 5320, and a comment display area 5330. In some embodiments, a free form text comment may be entered in the add comment area 5324 by selecting the area 5324 and entering (e.g., typing) a free form comment. See also enter comment box 3130 of FIG. 31 which allows the entry of free-form comments. When the video is played in the video viewer interface, comments entered for that video are displayed in the comment display area 5330. Each comment may include the name of the commenter and the time the comment is entered. In some embodiments, a viewer may sort the comments according to, for example, date and time of the comment entries, or time stamp of the comments. In some embodiments, the viewer may filter the comments according to status of the commenter. For example, a viewer may elect to only display comments made by users with an evaluator status. In some embodiments, comments may be filter by selecting “all comments”, “my comments” and “Colleagues comments”. In the illustration of FIG. 53, all comments are displayed in the comment display area 5330.

Comments tags are displayed on the seek bar 5320 according to the time stamps of each of the comments displayed in the comment display area 5330. For example, if the first comment is entered by a user at 10 minutes and 20 seconds into the playback of the video, the comment tag 5322 associated with the first comment will appear at the 10:20 position on the seek bar 5320.

In some embodiments, when the comment 5332 is selected, the corresponding comment tag 5322 is highlighted to show the playback location associated with the comment. In other embodiments, when the comment 5332 is selected, the video will be played starting at the position of the corresponding comment tag 5322. In some embodiments, when a comment tag 5322 is selected, the corresponding comment 5332 is highlighted. In other embodiments, when the comment tag is selected, a pop-up will appear above the comment tag, in the video display portion 5310, to show the text of the comment.

In the above mentioned embodiments, selecting can mean clicking with a mouse, hovering with a mouse pointer, or a touch gesture on a touch screen device. It is further noted that while free form comments may be added to video content items of captured video observations, free form comments may be added to or associated with notes or records corresponding to direct observation content items.

In one or more embodiments, the user may be provided with a means to control whether a video or other content item is shared with other users. For example, FIG. 31 illustrates a screen of a video with sharing enabled. A button 3114 is available on the top left corner of the page that allows the user to disable and enable sharing. In other embodiments, when the video has not yet been shared, the button will be displayed allowing the user to share the video. The placement of the button may vary for different embodiments. FIG. 31 also includes a selectable share indicator 3116 that allows for on/off share setting. Additionally, in another embodiment, selectable share button 5336 is used to allow the user to share or not share particular videos while selectable share buttons 5338 and 5340 allow the user to share or not share particular comments.

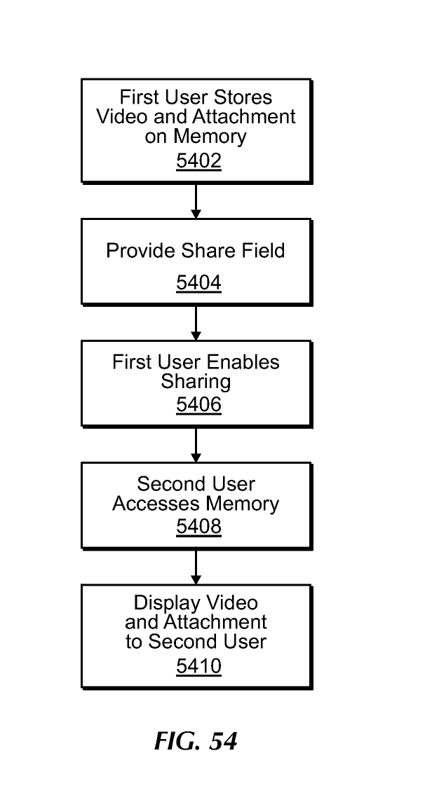

FIG. 54 illustrates an embodiment of a method for sharing a video. First, in step 5402, a user uploads a video and any attachments associated with the video to a memory device accessible by multiple users. An attachment may be, for example, a photograph, a text document, or a slideshow presentation file that is useful evaluators evaluating the performance recorded in the video. In step 5404, once the video is uploaded, a share field is provided for the user to select whether to enable sharing or not. In some embodiment, the user was previously assigned to at least one workgroup. For example, in an education environment, a workgroup may be a school or a district. When sharing is enabled in step 5406, the video is shared with all users belonging to the same workgroup. In step 5410, when a second user belonging to the same workgroup accesses the memory, the video would be made available to the second viewer for viewing.

In some embodiment, in step 5406, the user can enter names of individuals or groups in a share field to grant other users access to the video. In other embodiments, the user may select names from a list provided by the interface to grant permission. In some embodiments, different levels of permission can be given. For example, some users may be given permission to view the video only, while other users have access to comment on the video. Again, it is noted that free-form comments associated with a direct observation and/or content items associated with a direct observation may be similarly may be similarly shared or not based on the user setting of a sharing setting.

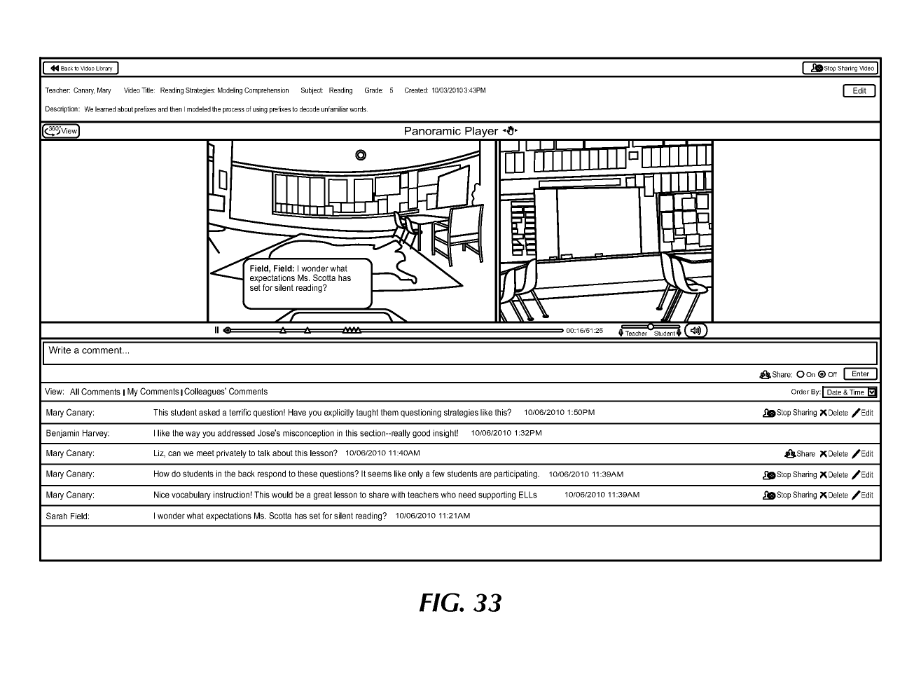

In one embodiment, the user is provided with one or more filtering options for the displayed comments. For example, in one embodiment, the user can filter the comments to show all comments, only the user's comments or only colleagues' comments. Furthermore, the user may be provided with means for sorting the comments based on different criteria such as date and time, video timeline and/or name. In one embodiment, a drop down window 3132 allows the user to select which criteria to use for sorting the comments. Furthermore, while viewing the comments in the list, the user is provided with an option to share or stop sharing the comment, to delete or to edit the comment as illustrated in FIG. 31. In one embodiment, the option to edit the comment or delete the comment is only available to the author of the comment. In one embodiment when the user selects the tags 3110 on the seek bar or highlights a comment in the comment list 3120, a pop-up will appear in the video showing the text of the comment as well as the author. FIGS. 33 and 34 illustrate exemplary display screen shots with comment pop-up according to one embodiment.

In one embodiment, while viewing the video, the user is further able to switch between a side by side view of the two camera views, e.g., panoramic and board camera, or may choose a 360 view where the user will be able to view the panoramic video and the board camera content will be displayed in a small window on the side of the screen. FIGS. 31-34 illustrate the display area showing the videos. FIG. 35 illustrates a 360 view with the panoramic video 3510 taking up the entire display area and the board video 3520 being displayed in a small window in picture in picture format in the lower right portion of the large window. In one embodiment, to provide the picture-in-picture view the board video is rendered over the perspective view of the panoramic video. In one embodiment, when generating the side-by-side view, the total rendering space available is calculated and the calculated space is roughly divided in two while maintaining the aspect ratio of each of the video content. Next, each video image is rendered in the space taking up roughly half of the displayed image. Generally, generating one or more of the side-by-side or picture-in-picture views is performed according to one or more rendering techniques known in the art.

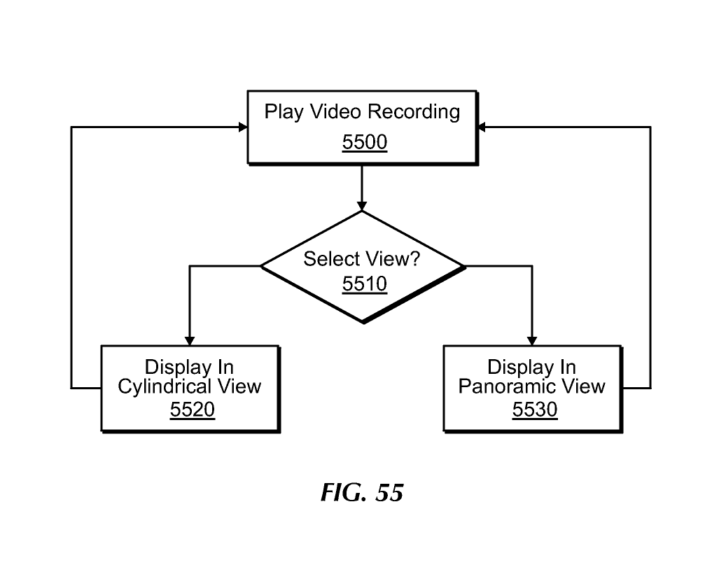

FIG. 55 illustrates one embodiments of a process which allows a user to switch between two different camera views. First, in step 5500 a viewer application plays the video in a default view. The default view may be either a cylindrical view or a panoramic view (or other default view). In the cylindrical view, only a limited range of angles of the panoramic video is shown at one time. Panning controls are provided in the cylindrical view to allow a user to pan the video and view all angles captured in the panoramic video. In a panoramic view, all angles captured in the panoramic video are shown at the same time. In step 5510, a selection is provided to the user to switch between the cylindrical view and the panoramic view. If panoramic view is selected, the view is switch to panoramic view mode in step 5530, and the video continues to play in step 5500. If cylindrical view is selected, the view is witched to cylindrical view mode in step 5520, and the video continues to play in step 5500.

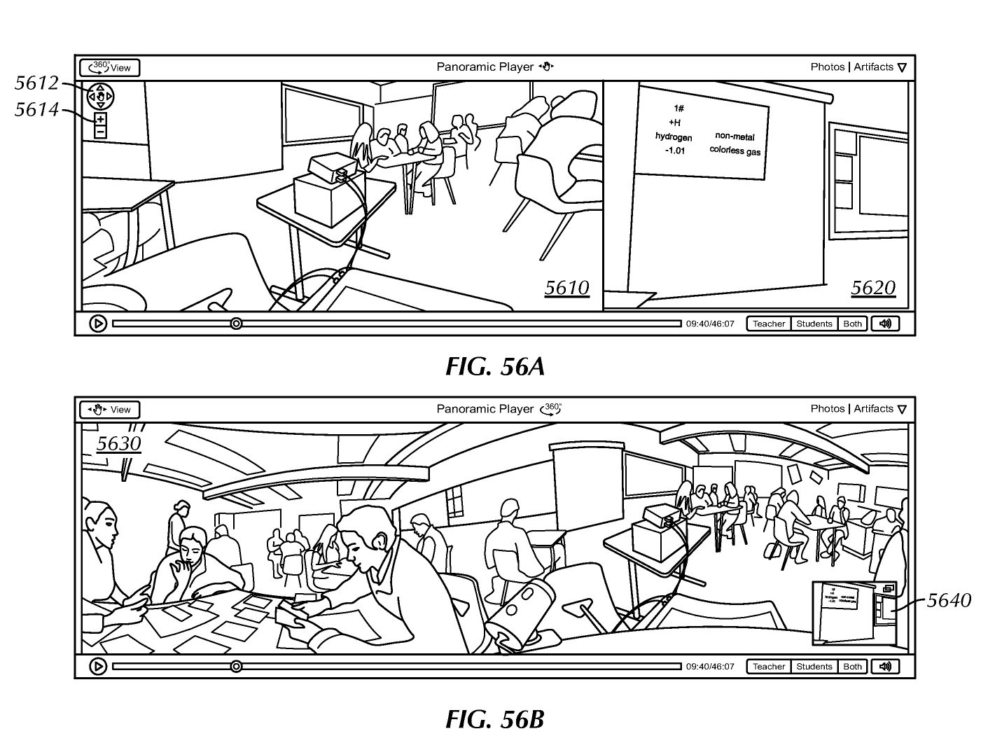

FIGS. 56A and 56B are examples of videos displayed in cylindrical view and panoramic view, respectively. In FIG. 56A, the panoramic video 5610 is displayed side by side with a board view 5620. As shown in FIG. 56A, in a cylindrical view, only a limited range of the panoramic video is shown on the screen. Panning controls 5612 allow the user to change the angles displayed on the screen to mimic the experience of being situated in the environment and able to look around the surrounding. In this embodiment, zooming controls 5614 are further provided to allow a user to zoom in and out on the panoramic video. In the panoramic view shown in FIG. 56B, all angles of the panoramic video 5610 are visible at the same time. The board video 5640 is displayed in a picture-in-pictures manner in one corner of the panoramic video 5630.

In other embodiments, the board video may be shown in either picture-in-picture mode or size-by-size mode with either panoramic view or cylindrical view. In some embodiments, additional zooming controls similar to zooming controls 5614 are also provided for the zooming of the board video and the panoramic video in the panoramic view. In other embodiments, panning control 5612 is replaced by a controlling method in which the user can click and drag on the video display to change the displayed angle.

### Submitting and Sharing Comments for a Video

FIG. 36 illustrates one embodiment of the video view display screen that may be presented to the user upon selecting a colleague's captured video for viewing and evaluation. Most viewing capabilities of the screen of FIG. 36 are similar to those described with respect to FIGS. 31-35 above. However, as illustrated, when viewing a colleague video, the user is only provided with viewing and evaluating capabilities. For example, when viewing colleague's videos the user is not able to edit content and/or metadata/information associated with the content. As illustrated, the user is able to view and comment on the video. In one embodiment, the user is further able to set a privacy level for the content by making a selection. In one embodiment, for example, the user may wish to share his comment with the owner of the video, while in other embodiments he may make his comment public and available to all users having access to the video.

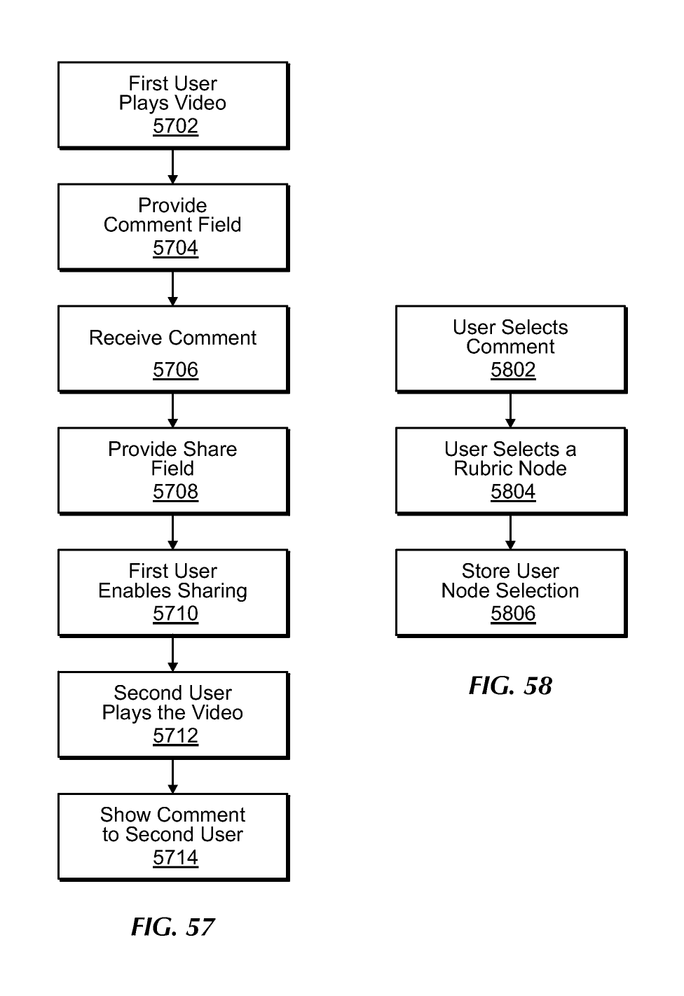

FIG. 57 illustrates one embodiment of a method for sharing a video comment. First, in step 5702, a video is displayed through the web application. In step 5704, the video viewer interface provides a comment field for the first user to enter a free form comment. In step 5706, a free form comment is entered and stored. In step 5708, the video viewer interface provides a share field 5708 for the first user to give one or more person permission to view the video or not. In step 5710, the first user enables sharing. In some embodiments, when sharing is enable, everyone with permission to view the video can see the comment, otherwise, only the first user and the owner of the video can see the comment. In some embodiments, the first user belongs to a workgroup, and when sharing is enabled, all users in that worker have permission to view the comment. In others embodiments, the first user may enter or select, for example, an individual's name, an individual's user ID, a pre-defined group's name, or a group ID in the share field to enable sharing. In step 5712, when a second user access the same video, the interface looks up the whether the second user is given permission to view any of the comments on the video. In step 5712, the interface displays the comments that the second user has permission to view with the video.

In some embodiments, comments and notes entered for a live observation may also be shared. A share field may be provided for comments taken in response to a live observation, and uploaded to a content server accessible by multiple users. A user can enter sharing settings similar to what is described above with references to FIG. 57. For example, in general terms in some embodiments, a method and system are provided a comment field is provided on a display device for a first user to enter free-form comments related to an observation of one or more observed persons performing a task to be evaluated. Then, a free-form comment entered by the first user is received in the comment field which relates to the observation, and the comment is stored on a computer readable medium accessible by multiple users. Also, a share field is provided to the user for the user to set a sharing setting. A determination of whether or not to display the free-form comment to a second user when the second user accesses stored data relating to the observation is made based on the sharing setting. Like other embodiments herein, the observation may include one or both of a multimedia captured observation and a direct observation.

Furthermore, in general terms in accordance with some embodiments, a method and system is provided for use in remotely evaluating performance of a task by one or more observed persons to allow for sharing of captured video observations. The method includes receiving a video recording of the one or more persons performing the task to be evaluated by one or more remote persons, and storing the video recording on a memory device accessible by multiple users. Then, at least one artifact is appended to the video recording, the at least one artifact comprising one or more of a time-stamped comment, a text document, and a photograph. A share field is provided for display to a first user for entering a sharing setting, and an entered sharing setting is received from the first user and stored. Next, a determination of whether or not to make available the video recording and the at least one artifact to a second user when the second user accesses the memory device is made based on the entered sharing setting.

In another embodiment, the viewer may have access to specific grading criteria or rubric assigned to the video as tags and may be able to score the user based on the rubric.

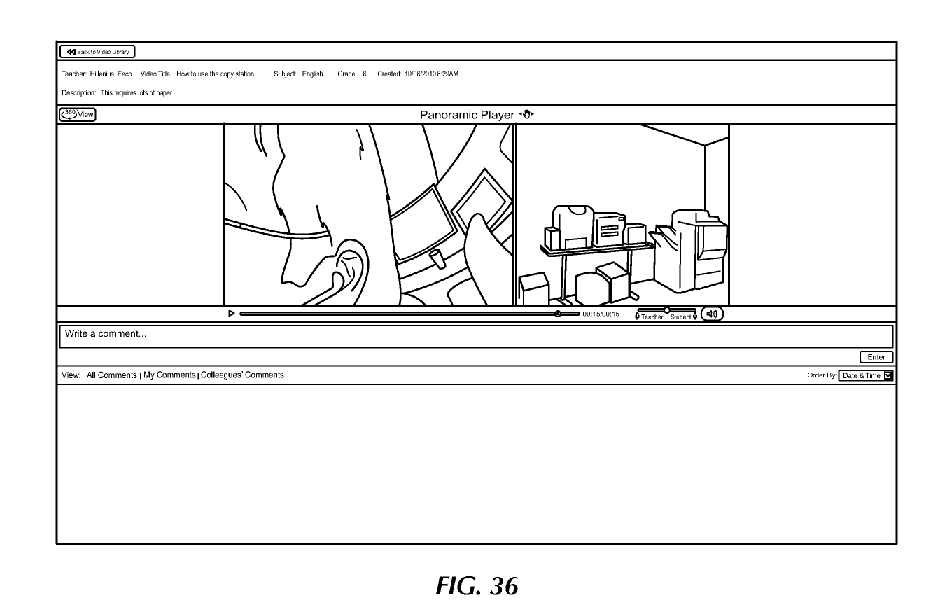

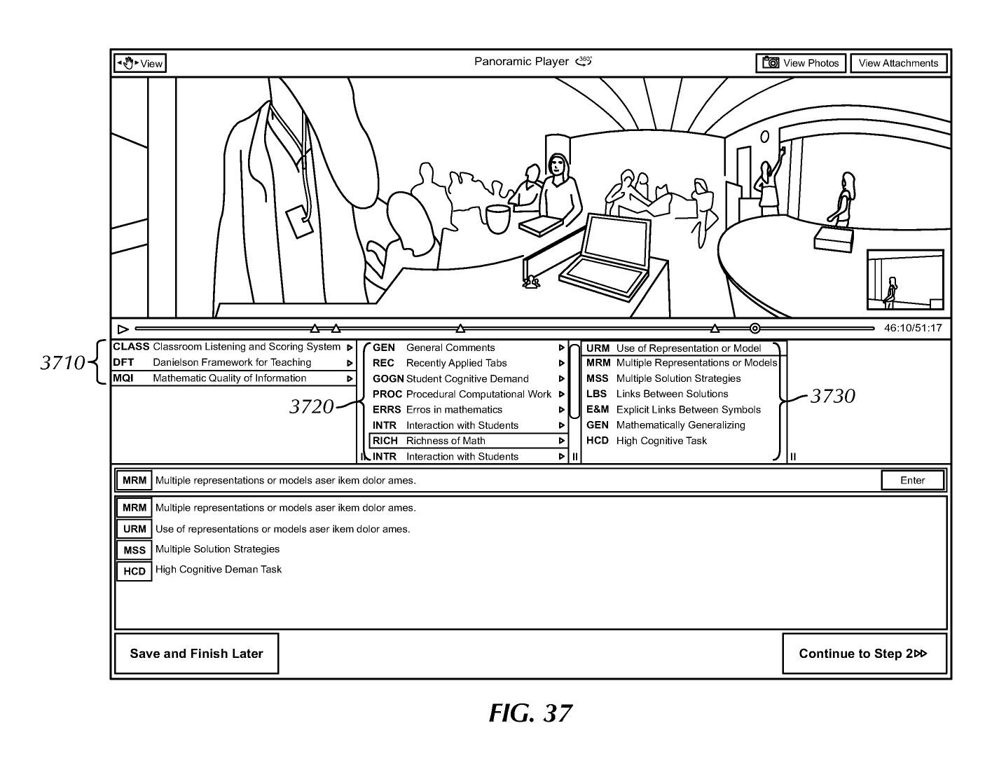

FIG. 37 illustrates an exemplary screen for tagging one or more content for analysis/scoring by a user. In one embodiment, a user, e.g. teacher or principal, is able to access a video and begin evaluating the video. In one embodiment, the user accesses the video/collection and while viewing the content comments on specific portions of the content as described above. In some embodiments, similar to other embodiments described above, the user may be provided with a comment window for providing free form comments regarding the content or the scoring process.

In one embodiment, the content is associated with an observation set having a specific scoring rubric associated therewith. In such embodiments, as shown the user may associate one or more comments with specific categories or elements within the rubric. In one embodiment, the user may make these associations either at the time of initial commenting while viewing the content, or may later make such associations when the viewing of content is done. In one embodiment, the content is then tagged with one or more comments having specific time stamps and optionally associated with one or more specific categories associated with a grading rubric or framework. In one embodiment, the predefined criteria available to the user depend upon the specific rubric or framework associated with the content at the time of initiating the observation set. In one embodiment, the specific rubric or framework assigned depends upon the specific goals being achieved or the specific behavior being evaluated. In one embodiment, for example, administrators within specific school districts may select one or more rubrics or frameworks that are made available to users for associating with an observation set or content. In one embodiment, each rubric or framework comprises predefined categories or elements which can be associated with comments during the viewing and evaluation process as displayed in FIG. 37. In some embodiments, the pre-defined categories may include a pre-defined set of desired performance characteristics or elements associated with performance of a task to be evaluated. In another embodiment, administrators are further able to create customized evaluation protocols and rubrics and such rubrics will include one or more predefined components or categories and stored within the system and made available for later use by one or more users having access to the customized rubrics. In one embodiment, as illustrated in FIG. 37 a user accesses one or more components of a rubric assigned/associated with the specific content and associates one or more comments made during the evaluation process with the specific components of the rubric. As shown in FIG. 37, the user can association an comment or annotation to an element by selecting a rubric from a list of rubrics 3710, selecting a category from a list of categories, 3720, and select an element from a list of elements 3730.

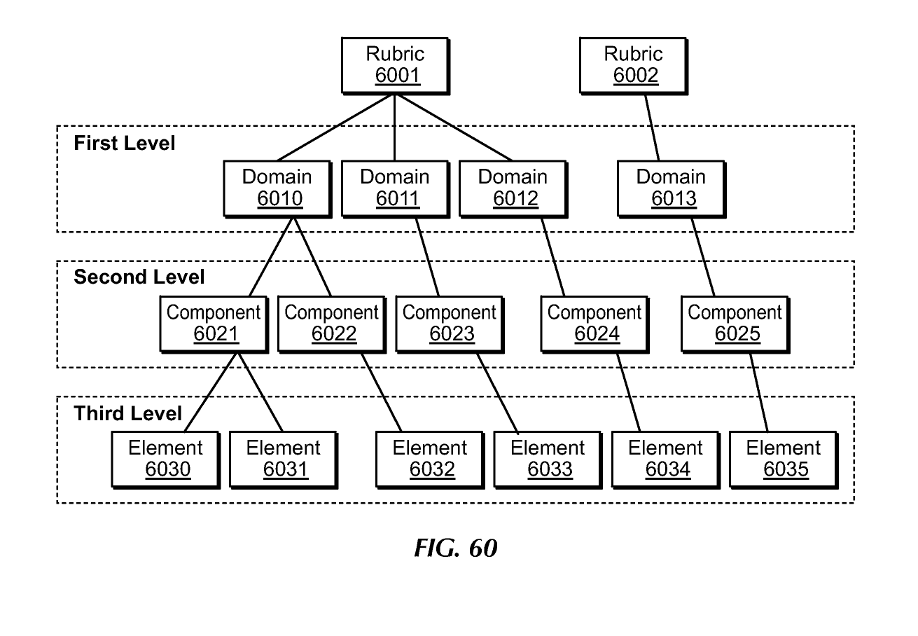

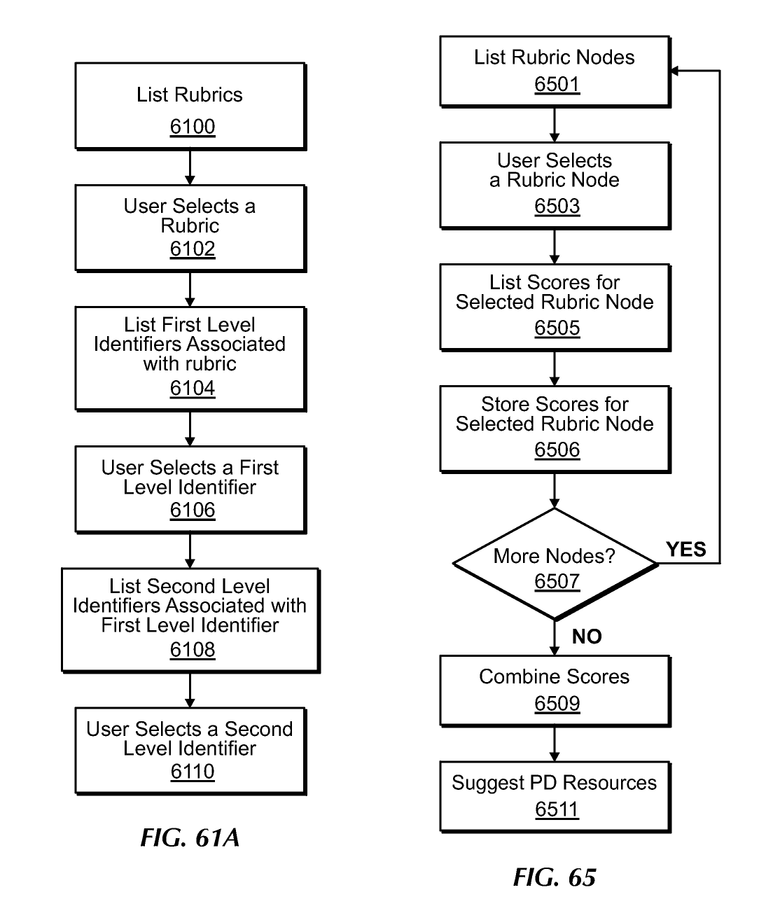

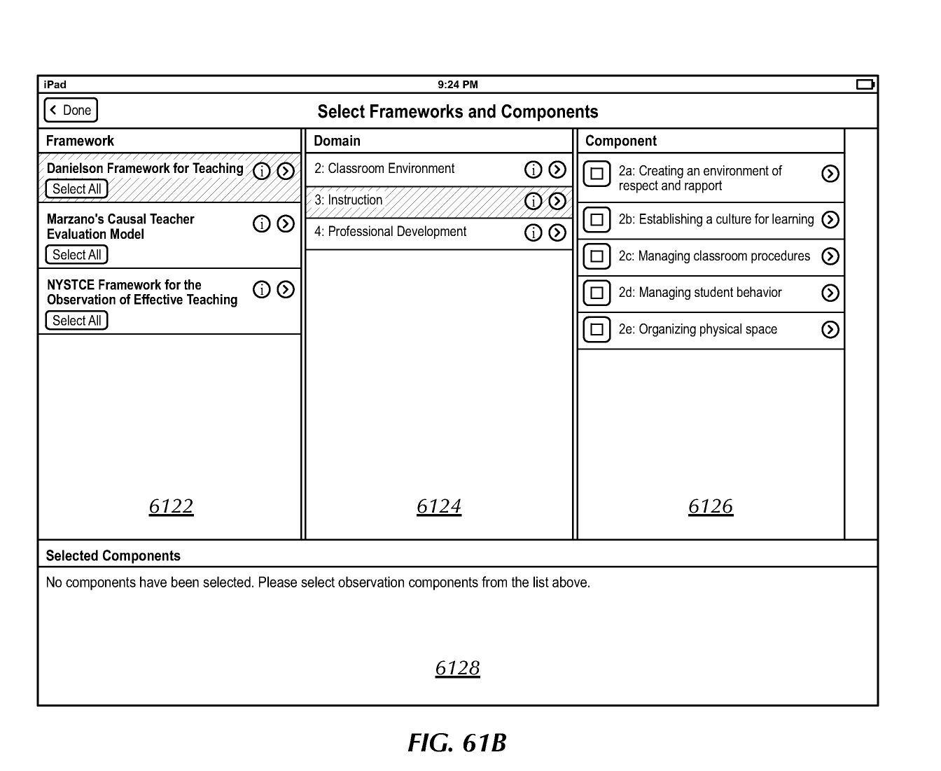

FIG. 58 is a flow chart illustrating a process for assigning a rubric element or node to an annotation or comment. In step 5802, a comment to be associated with a rubric node is first selected. The comment may be a comment made to a captured video or during a direct observation. This step could be performed immediately after the comment is entered or at a later time. In step 5804, a list of rubric nodes is provided to the user for selection. The rubric node may be presented in a dynamic navigable hierarchy as will be described with reference to FIGS. 60, 61A and 61B hereinafter. In 5806, the rubric node selection is stored, and the assignment can subsequently be used in the scoring stage of the evaluation.

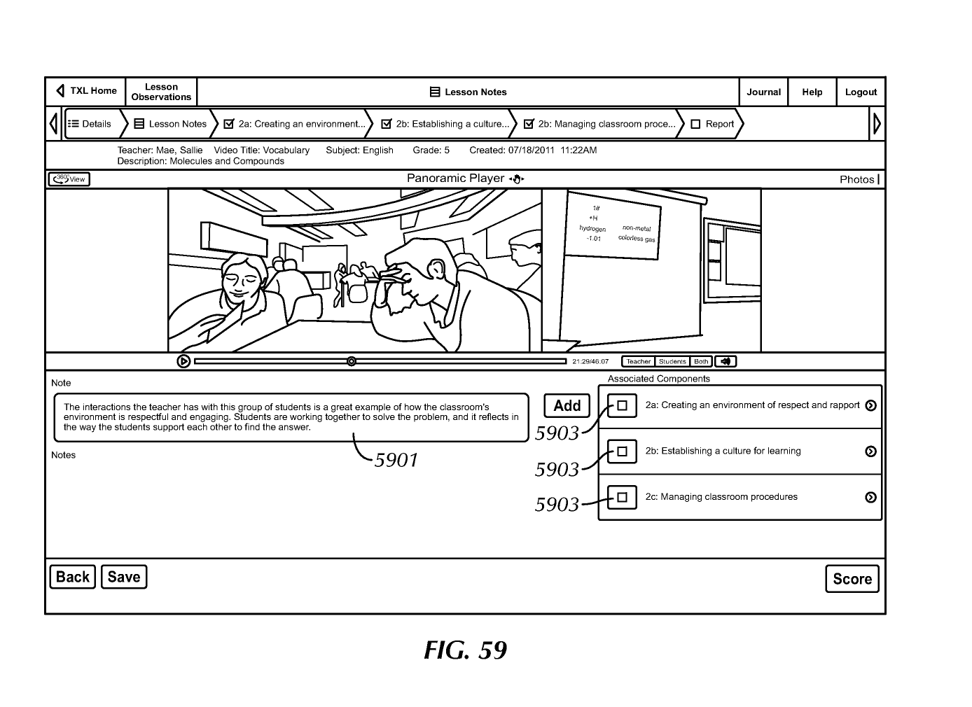

FIG. 59 illustrates an exemplary interface display screen of a video observation comment assigned to rubric nodes. In FIG. 59, a comment 5901 is assigned or associated to three rubric components 5902. These components can later be selected to receive a score based on the comment and the observation. A note or comment recorded during a direct observation may similarly be assigned to more than one rubric components.

Evaluation elements or nodes with in an evaluation framework used for evaluating a captured video and/or a live observation are often categorized and organized in the form of a hierarchy. FIG. 60 illustrates sample rubrics with hierarchical node organization. In FIG. 60, each rubric 6001 and 6002 has a first level of categorization, which may be called domains 6010-6013 of the rubric. Within each first level category, there are second level subcategories, which may be called components 6021-6025 of the category. Each component may contain one or more evaluation nodes called elements 6030-6035. In other embodiments, the rubric may have more or fewer levels of hierarchy. For example, a rubric may contain nodes without any categorization while another rubric may have three or more levels of hierarchy to navigate through before reaching the level containing rubric nodes. Not all rubrics and hierarchy branches within a rubric need to have the same number of hierarchy levels.

In one or more embodiments, dynamic navigation of rubrics is provided to assist users in selecting one or more rubric nodes to assign or associate to a comment or a tag of a captured video, or a note taken during a direct observation. FIG. 61A is a flowchart showing one embodiment of the dynamic navigation process. First, all rubrics assigned to an observation are listed 6100. In step 6100, rubrics assigned to the selected observation are listed. In step 6102, a user selects one of the rubrics. In step 6104, a list of first level identifiers associated with the selected rubric is displayed. At this time, the user may also select another rubric to display another set of first level identifiers. In step 6106, first level identifier is selected from the list. In step 6108, a list of second level identifiers associated with the first level identifier is displayed. At this time, the use may select another rubric or another first level identifier, and the process would go back to steps 6102 and 6106 respectively. In step 6110, the user selects a second level identifier. If the selected second level identifier represents a rubric node, the rubric node can be assigned to a comment. If the selected second level identifier is not an end level identifier (e.g. rubric node), the interface will display additional hierarchy levels associated with the second level identifier, additional identifier will be selectable on each additional level. When an end level rubric node is selected through this process, the user is given the option to assign the selected rubric node to the comment.

In one or more embodiments, when lower level identifiers are listed, one or more higher level identifiers that were previously listed remain visible and selectable on the display. For example, when the list of second level identifiers is provided in step 6108, list of rubrics and first level identifiers are also displayed and are selectable. As such, the user may select a different rubric or a different first level identifier while a list of second level identifier is displayed to display a different list of first or second level identifiers.

In some embodiments, the number of lists of higher level identifiers shown on the interface display is limited. For example, some embodiments may allow only three levels of hierarchy to be shown at the same time. As such, when a second level identifier is selected and associated third level identifiers are listed, only first, second, and third levels are displayed, and the list of rubrics is not shown. In some embodiments, a page-scroller is provided to show additional listed levels. In other embodiments, all prior listed levels are shown, and the width of each level's display frame is adjusted to fit all listed levels into one screen.

FIG. 61B is an embodiment of an interface display screen of a dynamic rubric navigation tool as applied to frameworks for teaching. In this exemplary screen, a list of frameworks 6122, a list of domains 6124, a list of components 6126, and a selected components field 6128 are displayed on the interface. Compared to the hierarchy structure shown in FIG. 60, each framework may be a type of evaluation rubric, each domain may be represented by a first level identifier, and each component may be represented by a second level identifier. In FIG. 61B, “Danielson Framework for Teaching” is selected from the list of frameworks 6122, “instruction” is selected from the list of domains 6124 associated with the Danielson Framework for Teaching, and the list of components 6126 associated with the “instruction” domain is displayed. While the list of components 6126 is displayed, the user may select another framework, for example, “Marzano's Causal Teacher Evaluation Model,” to display domains associated with that framework, or select another domain, for example “classroom environment” to display components associated with “classroom environment” domain.

When the user selects a component from the list of component 6126, the component is added to the selected components field 6128. Components from different frameworks and different domains can be added to the selected components field 6208 for the same comment. When one or more components have been added to the selected components list 6128, the user can select a “done” button to assign the components in the “selected components” field to a comment.

In general terms and according to some embodiments, a method and system are provided to allow for dynamic rubric navigation. In some embodiments, the method includes outputting a plurality of rubrics for display on a user interface of a computer device, each rubric comprising a plurality of first level identifiers. Each of the plurality first level identifiers comprises a plurality of second level identifiers and each of the plurality of rubrics comprises a plurality of nodes and each node corresponds to a pre-defined desired performance characteristic associated with performance of the task, where the task to be performed by the one or more observed persons is based at least on an observation of the performance of the task. Then, the system allows, via the user interface, selection of a selected rubric and a selected first level identifier associated with the selected rubric. The selected rubric and the selected first level identifier are received and stored. Also, selectable indicators for a subset of the plurality of second level identifiers associated to the selected first level identifier are output for display on the user interface, while also outputting selectable indicators for other ones of the plurality of rubrics and outputting selectable indicators for other ones of the plurality of first level identifiers for display on the user interface. And, the user is allowed to select any one of the selectable indicators to display second level identifiers associated with the selected indicator. Like other embodiments, the observation may include one or both of a captured video observation and a direct observation of the one or more observed persons performing the task.

In one embodiment, after the user has completed the comment/tagging step the user is then able to continue to the second step within the evaluation process to score the content based on the rubric using one or more of the comments made. For example, as shown in FIG. 37 once the user has entered one or more comments regarding the content and associated some or all of these comments with specific elements or components of the associated rubric the user may select the continue to step 2 button at the bottom of screen to continue to the scoring step of the evaluation process. In the illustrated embodiment of FIG. 37, user entered comments are associated with the time during playback that the comment was added, e.g., the triangles illustrated in the playback timeline of FIG. 37 correspond to certain comments. For example, a user may click on a particular triangle to view the video/audio content at that time with the comment/s added at that time.

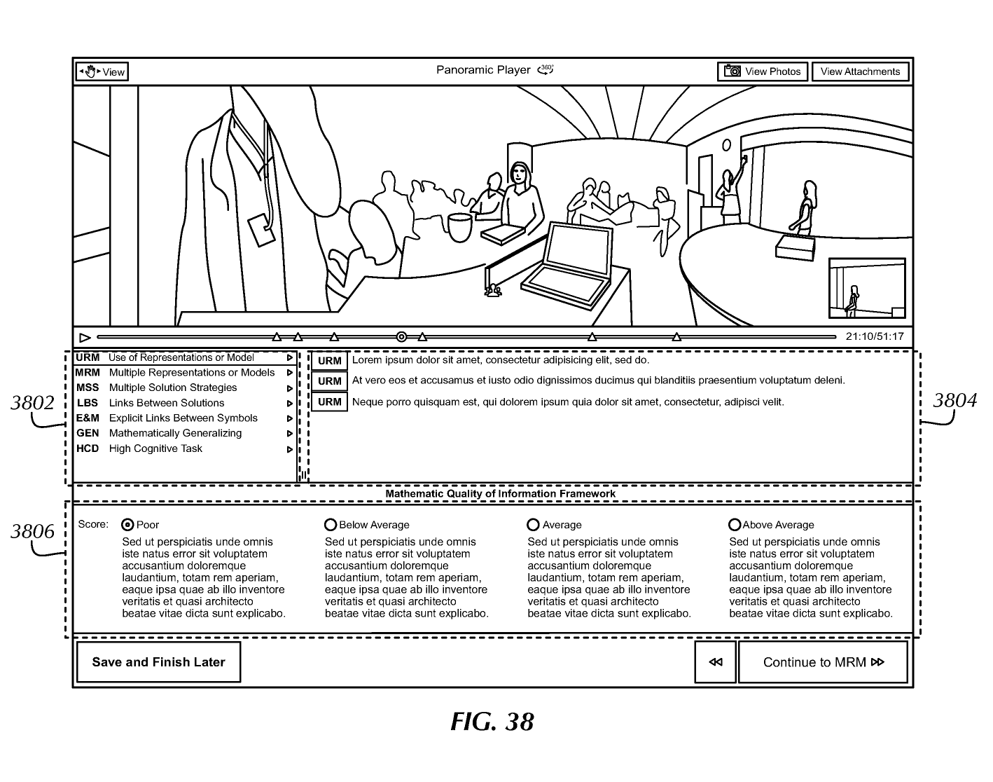

FIG. 38 illustrates a display screen that is presented to the user when the user selects to continue to the scoring step of the evaluation. As shown the user is provided with one or more comment/tags as assigned during the coding process described with respect to FIG. 37. In addition a grading/scoring framework having one or more predefined score values is presented to the user and the user is able to select one of the pre-assigned score values when evaluating the lesson based on the predefined comment/criteria embedded into the video during the coding process. In one embodiment, as shown a brief description of each grading value is further provided to the scorer/user to help the user is selecting the right score for the lesson. In one or more embodiments, the grader will score the video based on the comments and specific predefined criteria and categories assigned to different portions of the video by tags. In one embodiment, at several times during the video different grading framework may appear to the user and the user will choose a value from the predefined set of scores. In one embodiment, as a summary, portion 3802 illustrates a predefined set of criteria that the evaluation is based on, and portion 3804 illustrates all comments added by the user/reviewer during viewing the observation. The information in portions 3802 and 3804 may be helpful for the user when assigning a pre-defined score, such as shown in portion 3806.

While FIGS. 37-38 illustrate associating comments to a video observation with specific elements or components and scoring the comments, a similar interface, without the video player display, may be used for coding and scoring notes taken (e.g., on the computer device 6804) during a direct observation. When a note or comment is entered during a direct observation, elements of a rubric may be displayed for user selection and association. At the scoring stage, all selected rubric element may be displayed in a filed similar to portion 3802, comments associated with an element selected in a field portion 3802 may be displayed in portion 3804, and pre-defined scores for the element selected in portion 3802 may be displayed in portion 3806.

### Video Capture Evaluation Process

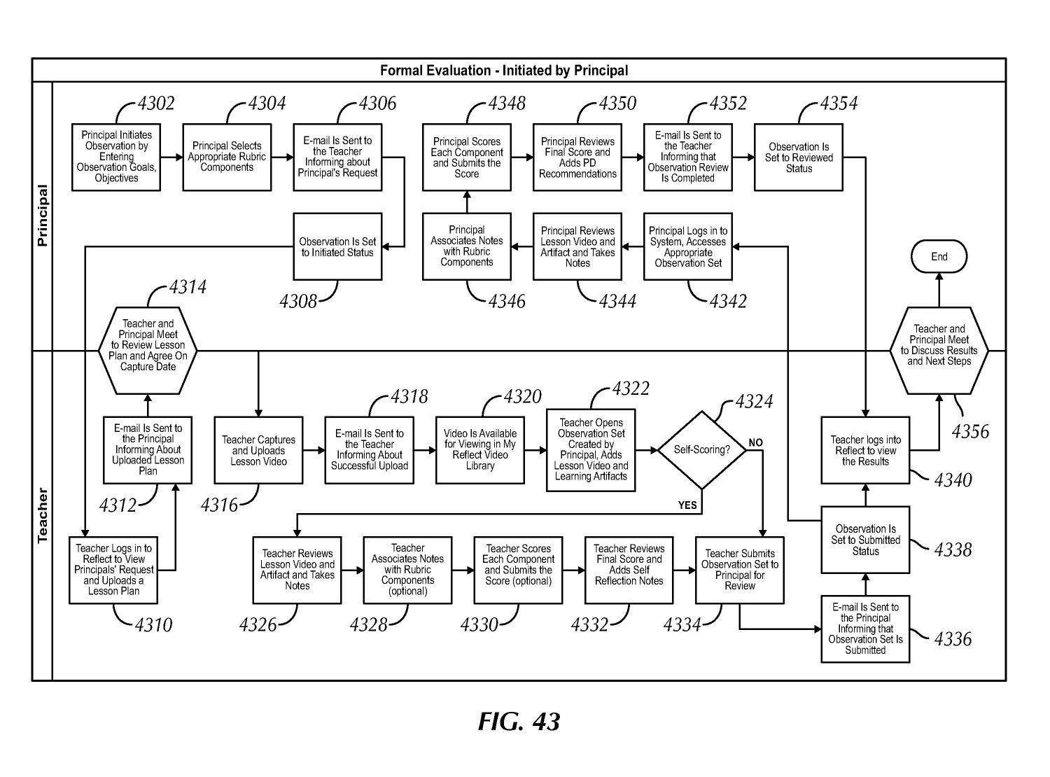

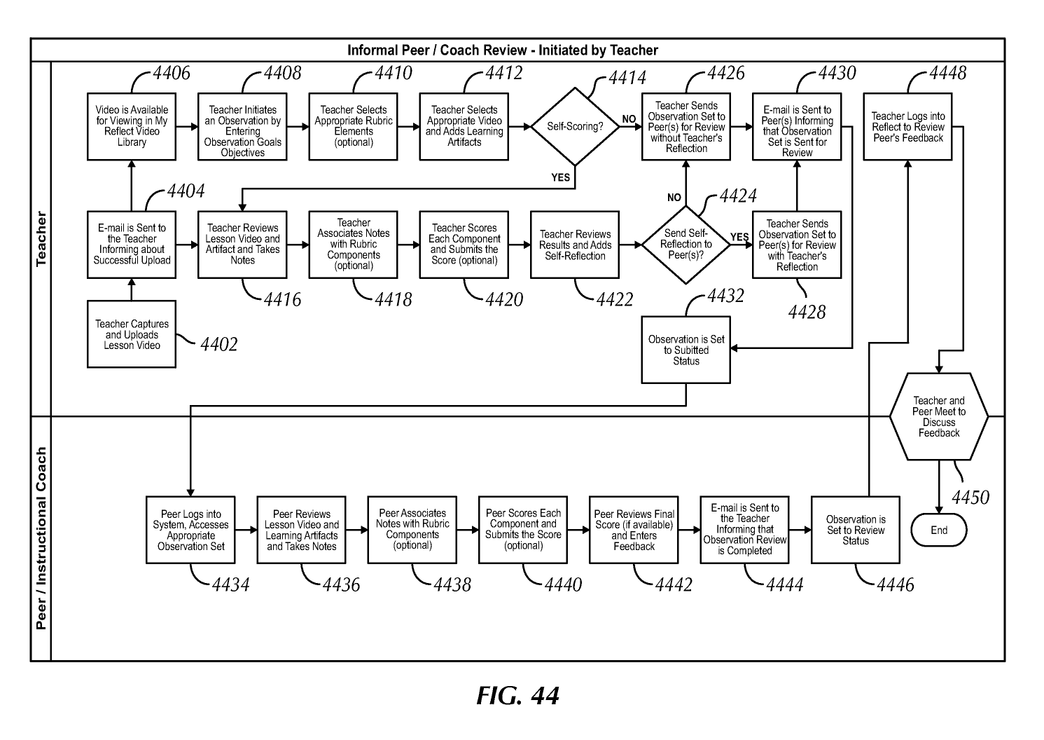

In some embodiments the evaluation process may be started by an observer, such as a teacher and/or principal or other reviewer. In one embodiment, the process is initiated by initiating an observation set and assigning a specific rubric among a set of rubrics made available through the system to the user. FIGS. 43 and 44 illustrate the evaluation process when either a teacher or principal initiates the review process. It should be understood that in some embodiments, other users may initiate the review process and that a similar process will be provided for initiating review by other users.

FIG. 43 illustrates a flow diagram of the evaluation process for a formal evaluation. In the exemplary embodiment the formal evaluation is depicted as initiated by a principal, however it should be understood that any user having a supervisory position or reviewing capacity may initiate the formal request. Further, the exemplary embodiment refers to a review of a teacher's performance, however it should be understood that any professional or individual or event that is intended to be evaluated.

As illustrated, the process is initiated in step 4302 where the principal initiates an observation by entering observation goals and objectives. In one embodiment, observation goals and objectives refer to behaviors or concepts that the principal wishes to evaluate. Next, in step 4304 the principal selects an appropriate rubric or rubric components for the observation and associates the observation with the rubric. In one embodiment, the rubrics and/or components within the rubric are selected based on the observation goals and objectives,

Next, in some embodiments, the process continues to step 4306 and a notification is sent to the teacher to inform the teacher that a request for evaluation is created by the principal. In one embodiment, for example, as shown in FIG. 43 an email notification may be sent to the teacher. Next, in step 4308 the observation is set to observation status.

Next, in some embodiments, during step 4310 the teacher logs into the system to view the principal's request. For example, upon receiving the notification sent in step 4306, the teacher logs into the system. After logging into the system/web application, during step 4310 the teacher then uploads a lesson plan for the lesson that will be captured for the requested evaluation observation. In step 4312, a notification is sent to the principal notifying the principal that a lesson plan has been uploaded. In one embodiment, for example, an email notification is sent during step 4312. Next, in some embodiments, the teacher and principal meet during step 4314 of the process to review the lesson plan and agree on a date for the capture. In one embodiment, the agreed upon lesson plan is associated with the observation set. In one embodiment, step 4314 may be performed as a face to face meeting, while in another embodiment the system may allow for a meeting to be set remotely and the principal and teacher may both log into the system or a separate independent meeting system to conduct the meeting in step 4314.

Next, in step 4316 the teacher captures and uploads lesson video according to several embodiments described herein. In one embodiment, once the capture and upload is completed the teacher is notified of the successful upload in step 4318 and in step 4320 the video is made available for viewing in the web application, for example in the teacher's video library. Next, in step 4322 the teacher enters the web application and accesses the uploaded content and the observation set created by the principal in step 4302. Next, the web application in step 4324 provides the teacher with an option to self score the lesson.

If the teacher chooses to self score the observation including captured video and/or audio content, the process then continues to step 4326 where the teacher reviews the lesson video and artifacts and takes notes, i.e. makes comments in the video. Next, in step 4328 the teacher associates one or more of the comments/notes made in step 4326 with components of the rubric associated with the observation set in step 4306. In one embodiment, step 4328 may be completed for one or more of the comments made in step 4326, For one or more comments, step 4328 may be performed while the teacher is reviewing the lesson video and making notes/comments where the comment is immediately associated with a component of the rubric while with respect to one or more comments step 4328 may be performed after the teacher has completed review of the lesson video where the teacher is then able to review each comment and associate the comment with the appropriate one or more categories of the rubric. FIG. 37 illustrates one example of the user performing steps 4326 and/or 4328. Next, the process continues to step 4330 where the teacher is able to score each component of the rubric associated with the observation set and submit the score. FIG. 38 illustrates an example of the scoring feature performed during step 4330. In one embodiment, during step 4330 the teacher is provided with specific values for evaluating the lesson with respect to one or more of the components of the rubric assigned to the observation set. In one embodiment, once the teacher has completed step 4330, in step 4332 the teacher is able to review the final score, e.g. an overall score calculated based on all scores assigned to each component, and add one or more additional comments, referred to herein as self reflection notes, to the observation set.

Next, the process continues to step 4334 and the teacher submits the observation set to the principal for review. Similarly, if in step 4324 the teacher chooses not the self score the lesson video the process continues to step 4334 where the observation set is submitted to the principal for review. After the observation set has been submitted for principal review, a notification may be sent to the principal in step 4336 to notify the principal that the observation set has been submitted. For example, as shown an email notification may be sent to the principal in step 4336. The observation is then set to submitted status in step 4338 and the process continues to step 4340.

In step 4340, the principal logs into the system/web application and accesses the observation set containing the lesson video submitted. The process then continues to step 4342 where the principal reviews the lesson video and artifacts and takes notes, i.e. makes comments in the video. Next, in step 4344, the principal associates one or more of the comments/notes made in step 4342 with components of the rubric associated with the observation set in step 4306. In one embodiment, step 4344 may be completed for one or more of the comments made in step 4342, For one or more comments, step 4344 may be performed while the principal is reviewing the lesson video and making notes/comments where the comment is immediately associated with a component of the rubric while with respect to one or more comments step 4344 may be performed after the principal has completed review of the lesson video where the principal is then able to review each comment and associate the comment with the appropriate one or more categories of the rubric. FIG. 37 illustrates one example of the user performing steps 4342 and/or 4344. Next, the process continues to step 4346 where the principal is able to score each component of the rubric associated with the observation set and submit the score. FIG. 38 illustrates an example of the scoring feature performed during step 4346. In one embodiment, during step 4346 the principal is provided with specific values for evaluating the lesson video with respect to one or more of the components of the rubric assigned to the observation set. In one embodiment, once the principal has completed step 4346, in step 4348 the principal is able to review the final score, e.g. an overall score calculated based on all scores assigned to each component, and add one or more additional comments, e.g., professional development recommendations, to the observation set.

Next, in step 4350 a notification, e.g., email, is sent to the teacher informing the teacher that review is complete. Next, in step 4352 the observation status is set to reviewed status and the process continues to step 4354 where the teacher is able to access the results of the review. For example, in one embodiment, the teacher may log into the web application to view the results in step 4354. After the review is completed, in step 4356 the teacher and principal may set up a meeting to discuss the results of the review and any future steps based on the results and the process ends after the meeting in step 4356 is completed. In one embodiment, step 4356 may be performed as a face to face meeting, while in another embodiment the system may allow for a meeting to be set remotely and the principal and teacher may both log into the system or a separate independent meeting system to conduct the meeting in step 4356.

FIG. 44 illustrates a flow diagram of an informal evaluation process initiated by a teacher, for example for the purpose of receiving feedback from a principal, coach and/or peers. The exemplary embodiment refers to a review of a teacher's performance, however it should be understood that any professional may be evaluated.

As illustrated, the process begins in step 4402 when a teacher captures and uploads lesson video according to several embodiments described herein. Next, in step 4404 a notification, e.g. email, is sent to teacher informing the teacher of the successful upload. Next, in step 4306 the video is made available for viewing in the web application, for example in the teacher's video library.

The process then continues to step 4408 where the teacher initiates an observation by entering observation goals and objectives. In one embodiment, observation goals and objectives refer to behaviors or concepts that the peer wishes to evaluate. Next, in step 4410 the peer selects an appropriate rubric or rubric components for the observation and associates the observation with the rubric and/or selected components of the rubric. As illustrated, in some embodiment, step 4304 is optional and may not be performed in all instances of the informal evaluation process. In one embodiment, the rubrics and/or components within the rubric are selected based on the observation goals and objectives, Next, in step 4412 the teacher associates one or more learning artifacts, such as lesson plans, notes, photographs, etc. to the lesson video captured in step 4402. In one embodiment, the teacher for example accesses the video library in the web application to select the captured video and is able to add one or more artifacts to the video according to several embodiments of the present invention.

Next, the web application in step 4414 provides the teacher with an option to self score the captured lesson. If the teacher chooses to self score the capture video content, the process then continues to step 4416 where the teacher reviews the lesson video and artifacts and takes notes, i.e. makes comments in the video. Next, in step 4418 the teacher associates one or more of the comments/notes made in step 4416 with components of the rubric associated with the observation set in step 4410. In one embodiment, step 4418 may be completed for one or more of the comments made in step 4416, For one or more comments, step 4418 may be performed while the teacher is reviewing the lesson video and making notes/comments where the comment is immediately associated with a component of the rubric while with respect to one or more comments step 4418 may be performed after the teacher has completed review of the lesson video where the teacher is then able to review each comment and associate the comment with the appropriate one or more categories of the rubric. FIG. 37 illustrates one example of the user performing steps 4416 and/or 4418. Next, the process continues to step 4420 where the teacher is able to score each component of the rubric associated with the observation set and submit the score. FIG. 38 illustrates an example of the scoring feature performed during step 4420.

In one embodiment, during step 4420 the teacher is provided with specific values for evaluating the lesson with respect to one or more of the components of the rubric assigned to the observation set. In one embodiment, once the teacher has completed step 4420, in step 4422 the teacher is able to review the final score, e.g. an overall score calculated based on all scores assigned to each component, and add one or more additional comments, referred to herein as self reflection notes, to the video.

After the teacher has finished self scoring the captured content, in step 4424, the teacher is provided with an option to share the self-reflection as part of the observation set with the peers. If the teacher chooses to share the observation set with the reflection with one or more peers for review, then the process continues to step 4426 and the teacher submits the observation set including the self-reflection to one or more peers/coaches for review. Alternatively if the user does not wish to share the self reflection as part of the observation the process continues to step 4428 where the observation is submitted for peer review without the self reflection. Similarly, if in step 4414 the teacher does not wish to self score the lesson video, the process moves to step 4428 and the observation set is submitted for peer review without self reflection material.

After the observation set has been submitted for peer review, a notification may be sent to the peers in step 4430 to notify the peers that the observation set has been submitted for review. For example, as shown an email notification may be sent to the peer in step 4430. The observation is then set to submitted status in step 4432 and the process continues to step 4434.

In step 4434, each of the peers logs into the system/web application and accesses the observation set containing the lesson video submitted. The process then continues to step 4436 where the peer reviews the lesson video and artifacts and takes notes, i.e. makes comments in the video. Next, in step 4438 the peer may associate one or more of the comments/notes made in step 4436 with components of the rubric associated with the observation set in step 4410. In one embodiment, step 4438 may be completed for one or more of the comments made in step 4436, For one or more comments, step 4438 may be performed while the peer is reviewing the lesson video and making notes/comments where the comment is immediately associated with a component of the rubric while with respect to one or more comments step 4438 may be performed after the peer has completed review of the lesson video where the peer is then able to review each comment and associate the comment with the appropriate one or more categories of the rubric. FIG. 37 illustrates one example of the user performing steps 4436 and/or 4438. Next, the process continues to step 4440 where the peer is able to score each component of the rubric associated with the observation set and submit the score. FIG. 38 illustrates an example of the scoring feature performed during step 4440. In one embodiment, during step 4440 the peer is provided with specific values for evaluating the lesson video with respect to one or more of the components of the rubric assigned to the observation set. In one embodiment, once the peer has completed step 4440, in step 4442 the peer is able to review the final score, e.g. an overall score calculated based on all scores assigned to each component, and add one or more additional comments and feedback, e.g., professional development recommendations, to the video. In one embodiment, one or more of the steps 4438 and 4440 may be optional and not performed in all instances of the informal review process. In such embodiments, a final score may not be available in step 4442.

Next, in step 4444 a notification, e.g., email, is sent to the teacher informing the teacher that review is complete. Next, in step 4446 the observation status is set to reviewed status and the process continues to step 4448 where the teacher is able to access the results of the review. For example, in one embodiment, the teacher may log into the web application to view the results in step 4448. After the review is completed, in step 4450 the teacher and peer may set up a meeting to discuss the results of the review and any future steps base on the results. In one embodiment, step 4450 may be performed as a face to face meeting, while in another embodiment the system may allow for a meeting to be set remotely and the peer and teacher may both log into the system or a separate independent meeting system to conduct the meeting in step 4450.

The system described herein allows for remote scoring and evaluation of the material, as a teacher in a classroom is able to capture content and upload the content into the system and remote unbiased teachers/users are then able to review, analyze and evaluate the content while having a complete experience of the classroom by way of the panoramic content. In one embodiment, further, a more complete experience is made possible since one or more users may have an opportunity to edit the content post capture before it is evaluated, such that errors can be removed and do not affect the evaluation process.

Once the user has completed the process of editing/commenting on his videos within the video library and shared one or more of the videos with colleagues and/or viewed one or more colleague videos and provided comments and evaluations regarding the videos, the user can then return to the home page and select another option or log out of the web application.

### Direct Observation Process

In some embodiments, a performance evaluation based on video observation may be combined with other types of evaluations. For example, direct observations and/or walkthrough surveys may be conducted in addition to the video observation. Direct observations or live observations are a type of observation that is conducted while the one or more observed person is performing the evaluated task. For example, in an education environment, direct observations may typically conducted in a classroom during a class session. In some embodiments, a direct observation may also be conducted remotely through a live video stream. Walkthrough surveys are questionnaires that an observer uses to observe the work setting to gather general information about the environment.

### Direct Observation (Reflect Live)

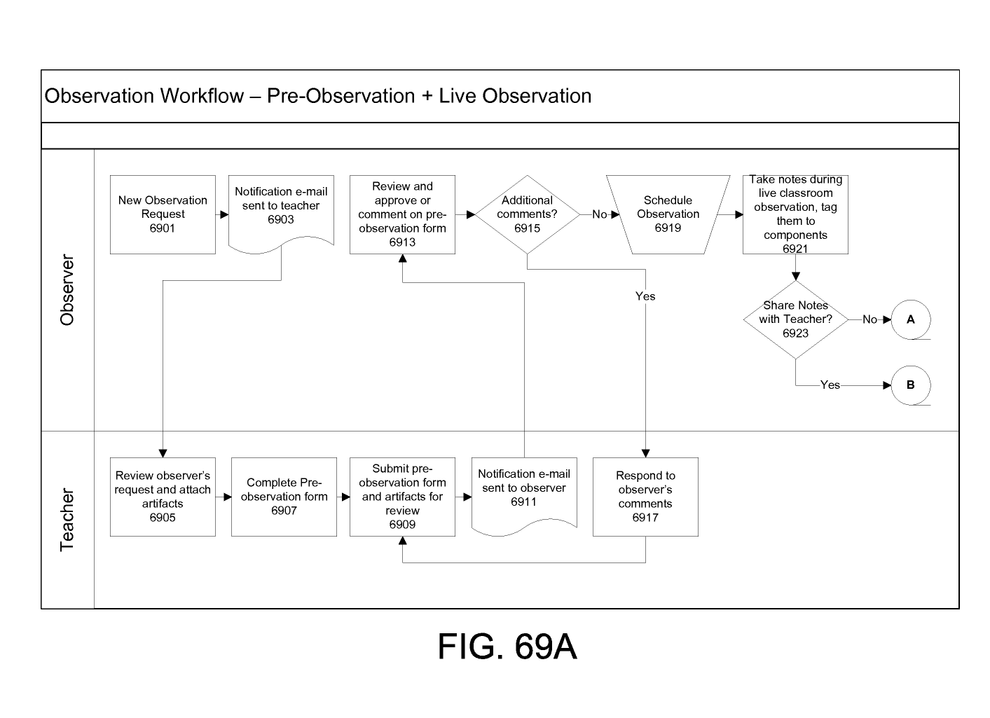

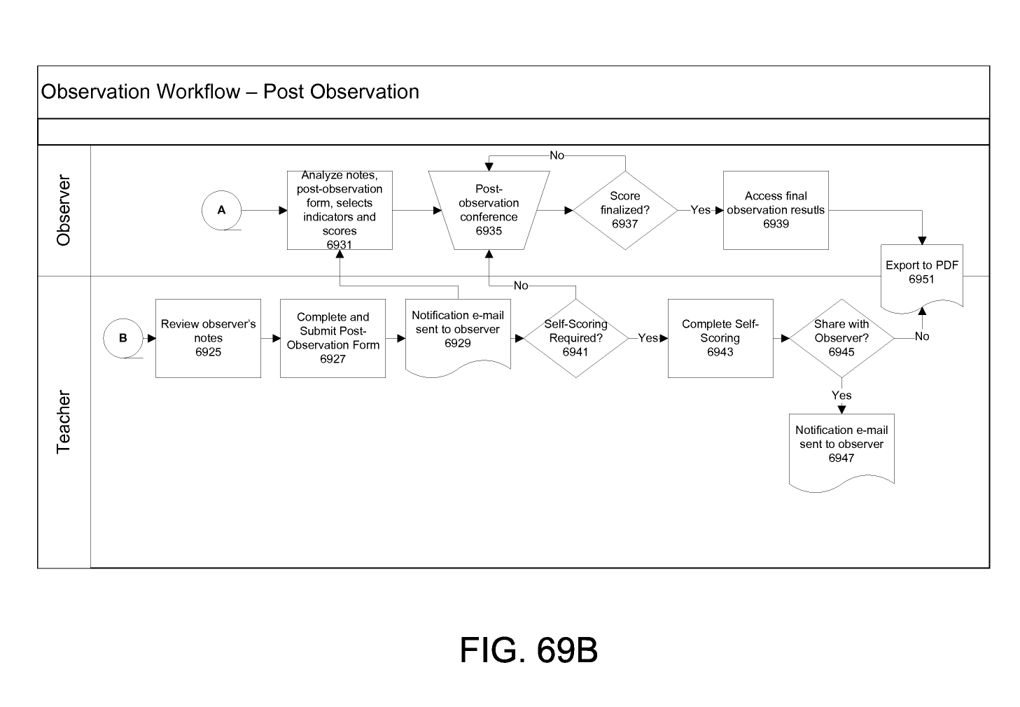

FIGS. 69A and 69B illustrate flow diagrams of the exemplary evaluation process for a direct observation as applied in an education environment. In step 6901, an observer requests a new observation. An observer may be the person who is going to conduct the direct observation. In step 6903, the web application sends a notification to the teacher. In some embodiments, the notification can be sent through an in-application messaging system, email, or text message. In step 6905, the teacher reviews observer's request and attaches the requested artifact or artifacts. An artifact is generally an item that is auxiliary to a performance of the task and can be used to assist in the evaluation of the performance of the task. The requested artifact may be, for example, lesson plan, student assignment from a previous lesson, handout that will be distributed in class, etc. In step 6907, the teacher completes a pre-observation form. In step 6909, the teacher submits pre-observation form and artifacts for review. In step 6911, a notification is sent to an observer. In step 6913, the observer review and approve or comment on pre-observation form and artifacts. In 6915, the observer can either request a response on the observer's comments on the pre-observation form and artifacts from the teacher or schedule a time and date for the observation. In step 6917, the teacher response to observer's comments, and resubmits pre-observations and/or artifacts (step 6909). In step 6919, the evaluator schedules the observation. The scheduling of observation may involve further communication between the observer and teacher. In step 6921, the observer conducts the observation in the classroom during a lesson. In step 6923, the observer can choose to either share the notes taken during observation with the teacher or begin post-observation evaluation. If the observer shares the observation notes with the teacher, in step 6925, the teach reviews the observer's notes. In step 6927, the teacher complete and submit a post-observation form. In step 6929, a notification is sent to the observer. In step 6931, the observer analyzes notes and scores the lesson based on rubric components. If, in step 6923, the observers chose to not share the observation notes with the teacher, the observer can begin step 6931 immediately after the classroom observation. If, in step 6923, the observer shares the observation notes with the teacher, the observer may receive a post observation form from the teacher which may be reviewed in step 6931. In step 6935 the observer conducts a post-observation conference with the teacher. In step 6937, the observer can either finalize the score, or conduct another post-observation conference. In step 6939, the observer accesses final observation results. In step 6941, in addition to submitting the post-observation form, the teacher may be required to perform self evaluation through self scoring. In step 6943, the teacher completes self scoring. In step 6945, the result of the teacher's self-scoring can either be shared with the observer or not. If the self-scoring results are share with the observer, in step 6947 a notification is sent to the observer. In step 6951, observer's observation results and, if self-scoring is required in step 6941, the teacher's self scoring results are reported as an evaluation report. In some embodiments, the evaluation report may be presented as a pdf file.

During the live observation session in step 6919, the observer may takes notes using the observation application 6806 as described in FIG. 40. The observer can also associates the notes to component of rubrics through an interface provided by the observation application 6806. The associating of an observation note to a component or node of a rubric can utilize an interface as shown in FIG. 61B for selecting one or more components. In some embodiments, a custom rubric and be assigned to the observation and used to score the observation. In some embodiments, the tagging of notes to component rubrics can be performed after the conclusion of the observation session, through the observation application 6806 and/or the web application 122. During the observation, the observer can add additional artifacts to the observation, for example, the observer can also capture video and/or audio segments of the lesson, take photographs, and attach documents such as student work to the observation using the computer device 6804 through the observation application 6806. In some embodiments, the notes and the observations can be immediately uploaded to the content server 140. In some embodiments, the notes and observations can be uploaded at a subsequent time.

While an extensive evaluation process involving direct observation is described in FIGS. 69A and 69B, in practice, steps of FIGS. 69A and 69B may be omitted. In some instances, a direct observation described in step 6921 may be performed without at least some of the pre-observation steps, and/or with only limited post-observation steps. For example, the observer may show up unannounced to observe a performance of a task, and/or the post-observation evaluation may be conducted without the participation of the teacher.

While steps in FIGS. 69A and 69B are described to be either performed by the observer or the teacher, some of the steps can be performed by an administrator who is organizing the observation. For example, the administrator may request a new observation (step 6901), and a notification is send to both the observer and the teacher in step 6905. The administrator can also perform the scheduling of the observation in step 6919.

It is understood that FIGS. 69A and 69B are examples of a direct observation as applied to an education environment. A similar process may be applied to many other environments where an observation based evaluation may be desired.

The web application and the observation application 6806 may further provide tools to facilitate each step described in FIGS. 69A and 69B, and group all the steps into a workflow described below which that can be viewed and managed by both the teacher and the observer.

A workflow dashboard is provided to facilitate an evaluation process. As described previously, an evaluation process, whether involving a video observation or a direct observation, may involve active participation from the evaluator, the person being evaluated, and in some cases, an administrator. The evaluator and the person being evaluated may also have multiple evaluation processes progressing at the same time. The workflow dashboard is provided as an application for viewing and managing incoming notifications and pending tasks from one or more evaluation process.

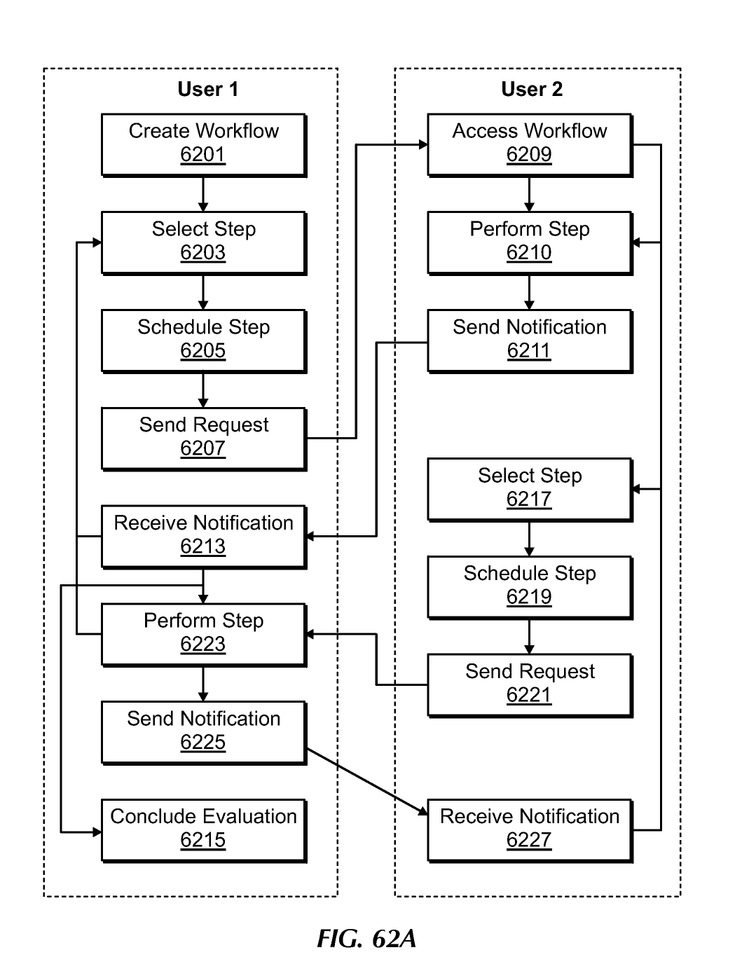

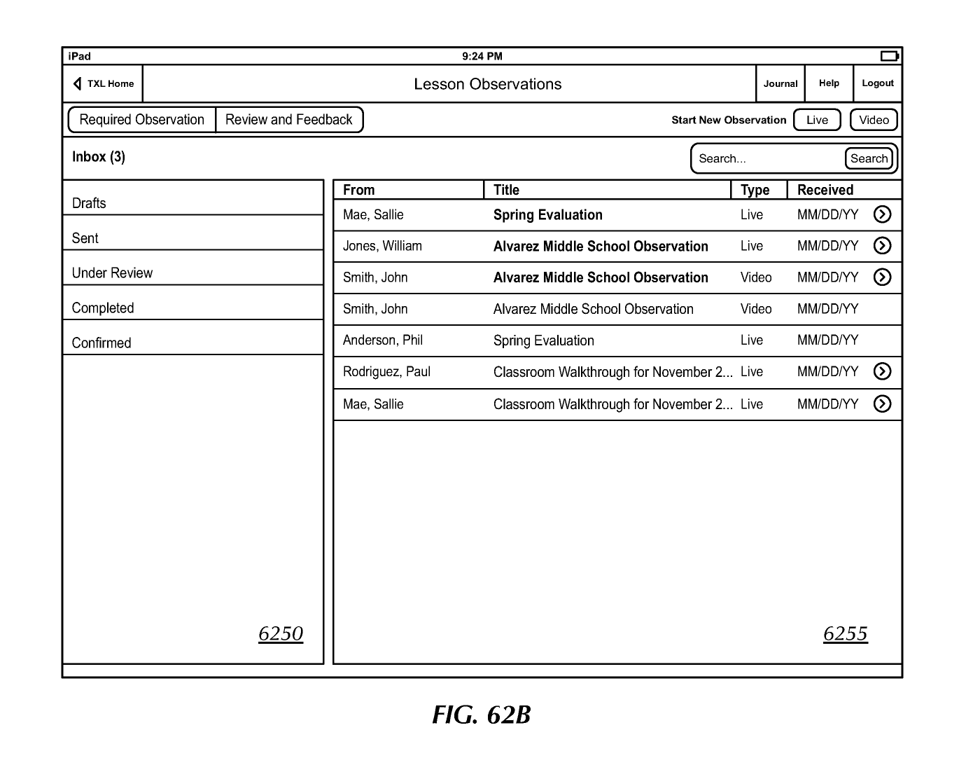

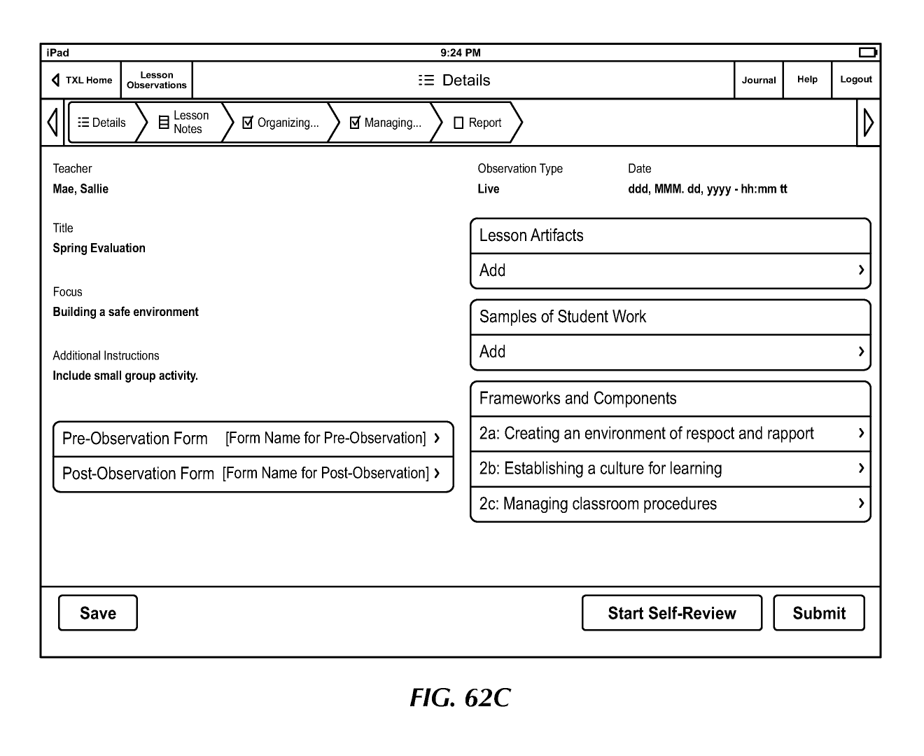

FIG. 62A illustrates an exemplary process of a workflow dashboard for facilitating a multi-step evaluation process. In step 6201, a first user creates a workflow. The first user may be an evaluator of an evaluator initiated evaluation, a person being evaluated, for an administrator. In step 6203, the first user selects one or more steps requiring a response from a second user. A requested response may be, for example, submitting a schedule of availability, submitting an artifact, submitting a pre-observation form, uploading of a video, reviewing of a video, scoring of a video, responding to comments to a video, completing a post-observation form, etc. In step 6203, the first user may select a date when the selected step is schedule to be completed. In some embodiments, step 6203 may be omitted. In step 6207, a request is sent to the second user. The request may include requests for the completion of one or more steps. In some embodiments, access to files and web application functionalities necessary to complete the selected step is provided to the second user along with the request. For example, if the completion of a pre-observation form is requested, the second user may be given access to view and enter text into a web-based form. In step 6209, the second user is able to access the workflow created by the first user. In step 6210, the second user performs the step requested. In step 6211, upon the completion of the step, a notification is sent to the first user. The notification may be for example, an in-application message, an email, or a text message. In step 6213, the first user receives the notification and is given access to any content the second user has provided in response to the request. In step 6213, the first user can either choose to initiate another step (go back to step 6203) or conclude the evaluation (step 6215). For some steps, the second user's performance of a request in step 6210 could trigger a request for the first user to perform an action. For example, when the second user uploads a video in response to a request from the first user, the uploading of the video can triggers request for the first user to comment on the video. As such, the notification receive at step 6213 is also a request to perform an action or task.

When the second user gains access to the workflow in step 6209, the second user may also make requests to the first user. The second user can use the workflow dashboard to select a step (step 6217), schedule the step (step 6219), and send the request to the first user (step 6221). In some embodiments step 6219 is omitted. In step 6223, the first user performs the action either requested by the second user or triggered by second user's performance of a previous step. In step 6225, a notification is sent to the second user. When the notification is received in step 6227, the second user may be triggered to perform another step. Or, in step 6217 the second user can select and schedule another step.

In some embodiments, the sending of request and notification are automated by the workflow dashboard application. In some embodiments, steps are selected from a list of pre-defined steps, each predefined step may have the application tools necessary to perform the step already assigned to the predefined step. For example, when a request to upload a video is sent, the notification provides a link to an upload page where a user can select a local file to upload and preview the uploaded video before submitting it to the workflow. In another example, when a request to complete a pre-observation form is sent, a Tillable pre-observation form may be provided by the application along with the request. In other embodiments, only the creator of the workflow has the ability to select and schedule step. The creator may be the evaluator or an administrator. In some embodiments, users can use the workflow dashboard to send messages without associating the message with any step. In some embodiments, multiple observations may be associated with one workflow.

FIG. 62B illustrates an exemplary interface display screen of a workflow dashboard. In this example, task notifications from multiple evaluation processes are displayed at once. The display screen includes a category area 6250 and a message area 6255. The message area 6255 displays notifications and requests received or sent. The notifications or requests may be displayed with their attributes, for example, their workflow name, type, and date in the message area 6255. The messages may also be sorted according to these attributes. Furthermore, the messages can be displayed according to their categorization by selecting one of the categories in the category area 6250. For example, received messages are displayed in the inbox, and send messages are displayed in the sent box. The messages can also be categorized by the status of the evaluation, for example, evaluation that are under review, completed, or confirmed can be displayed when the respective category is selected in the category area 6250.

FIG. 62C illustrates an exemplary display screen of a live observation associated with a workflow. In the observation display screen, information of the observation session is displayed. Listed information may include, for example, name of the teacher, title of the evaluation, focus of the evaluation, etc. Various functionalities of the web application applicable to the observation are also provided. For example, on this screen, the user can submit pre-observation and post-observation forms, add lesson artifacts, add samples of student work, review framework and components assigned to the video, and start a self-review. In other embodiments, some or all of these functionalities can be turned on and off by the evaluator, the administrator and/or depending on the progression of the evaluation process. For example, post-observation form submission may not be available until the observation session has been completed.

The screen display shown in FIG. 62C can be provided as a workflow notification. The person receiving the notification may be requested to fill in some or all fields of the screen to complete a step in the observation process.

While FIG. 62C illustrates a live observation associated with a workflow, in some embodiment, a similar interface is provided for video observations and walkthrough surveys. In a workflow screen for other types of observations, functionalities of the web application applicable to that observation would be displayed.

In some embodiments, the workflow dashboard described with reference to FIGS. 62A-62C can further provide functionalities to combine different types of observations. For example, referring back to FIG. 62B, requests and notifications received through the workflow dashboard shown in the message area 6255 includes messages for video observations and direct (live) observations. Participants of a direct observation or a walkthrough survey can also use a process similar to the process illustrated in FIG. 62A to communicate requests and notifications. For example, for a direct observation, the evaluator may request the person being evaluated to submit pre-observations forms prior to the direct observations session through the workflow dashboard. The completed form is then stored and made available to both participants. The observation application 6806 may also be provided for the evaluator to enter notes during or after the completion of the direct observation. All or part of the direct observation notes may be stored and shared with other participants through the workflow dashboard. Additionally, direct observations notes may also be coded with rubric nodes through a process similar to what is illustrated in FIG. 58 and scored through a process similar to what is described with reference to FIG. 38. Similar to the workflow functionalities provided to video observations, when a step is selected for a direct observation, application tools and/or forms necessary to perform the task may also be provided to the participants

Similarly, applicable functionalities can be provided to video observations and walkthrough surveys through the web application. For example, a walkthrough survey form may be provided as an on-line or off-line interface for the evaluator to enter notes during or after the completion of walkthrough survey. Tools may also be provided to assign or record scores from a walkthrough survey.

In some embodiments, workflow dashboard can be implemented on the observation application 6806 or the web application 122. In some embodiments, information entered through either the observation application 6806 or the web application 122 is shared with the other application. For example, the artifacts submitted through the web application in step 6906 can be downloaded and viewed through the observation application 6806. In another example, observation notes and scores entered through the observation application 6806 can be uploaded and viewed, modified, and processed through the web application 122.

In some embodiments, multiple observations can be assigned to one workflow. For example, direct observation, video observation, and walkthrough survey of the same performance of a task can be associated to the same workflow. In another example, two or more separate task performances may be assigned to the same workflow for a more comprehensive evaluation. All requests and notifications from the same workflow can be displayed and managed together in the workflow dashboard. Data and files associated with observations assigned to the same workflow may also be shared between the observations. For example, for a teaching evaluation, an uploaded lesson plan can be shared by a direct observation and a video observation of the same class session which are assigned to the same workflow. As such, multiple evaluators may have access to the lesson plan without the teacher having to provide it separately to each evaluator. In another example, information such as name, date, and location entered for one observation type may be automatically filled in for another observation type associated with the same workflow.

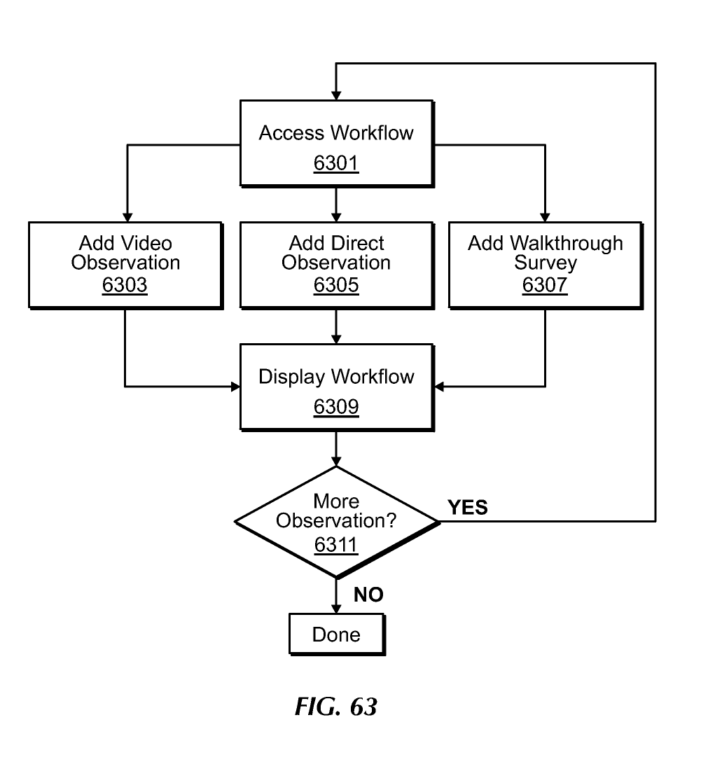

FIG. 63 illustrates one embodiment of a process for assigning an observation to a workflow. In step 6301, a user accesses a workflow. The workflow display may include options to create a new observation and/or to add an existing observation to the workflow. In this embodiment, the user can add a video observation 6303, a direct observation 6305, or a walkthrough survey 6307 to the workflow. In step 6309, the added observation is displayed in the workflow. After each observation is added, the user has the option to add more observations to the workflow by selection of another observation. In other embodiments, the user may customize an observation type by selecting steps to be included in the observation. In some embodiment, the ability to add and delete observations from a workflow is limited to the creator of the workflow or persons given permission by the creator of the workflow. In step 6311, the user is given to option to add another observation to the workflow and if not, the process ends such that the selected observations are added to the workflow.

In some embodiments and in general terms, a method and system are provided for facilitating performance evaluation of a task by one or more observed persons through the use of workflows. In one form, the method creating an observation workflow associated with the performance evaluation of the task by the one or more observed persons and stored on a memory device. Then, a first observation is associated to the workflow, the first observation comprising any one of a direct observation of the performance of the task, a multimedia captured observation of the performance of the task, and a walkthrough survey of the performance of the task. A list of selectable steps is provided through a user interface of a first computer device, to a first user, wherein each step is a step to be performed to complete the first observation. Then, a step selection is received from the first user selecting one or more steps from the list of selectable steps, and a second user is associated to the workflow. And a first notification of the one or more steps is sent to the second user through the user interface.

In other embodiments, a system and method for facilitating evaluation using a workflow includes providing a user interface accessible by one or more users at one or more computer devices, and allowing, via the user interface, a video observation to be assigned to a workflow, the video observation comprising a video recording of the task being performed by the one or more observed persons. Also, a direct observation is allowed via the user interface, a direct observation to be assigned to the workflow, the direct observation comprises data collected during a real-time observation of the performance of the task by the one or more observed persons. And a walkthrough survey is allowed via the user interface to be assigned to the workflow, the walkthrough survey comprises general information gathered at a setting in which the one or more observed persons perform the task. An association of at least two of an assigned video observation, an assigned direct observation, and an assigned walkthrough survey to the workflow is stored.

In further embodiments, a computer-implemented method for facilitating performance evaluation of a task by one or more observed persons comprises providing a user interface accessible by one or more users at one or more computer devices, and associating, via the user interface, a plurality of observations of the one or more observed persons performing the task to an evaluation of the task, wherein each of the plurality of observations is a different type of observation. Also, a plurality of different performance rubrics are associated to the evaluation of the task; and an evaluation of the performance of the task based on the plurality of observations and the plurality of rubrics is received.

As described above, scores can be produced by video observation, direct observations and walkthrough surveys. The web application may combine scores from different types of observation stored on the content server. In some embodiments, scores are given in each observation based on how well the observed performance meets the desired characteristics described in an evaluation rubric. The scores from different observation types can then be weighted and combined together based on the evaluation rubric for a more comprehensive performance evaluation. In some embodiments, scores assigned to the same rubric node from each observation type are combined and a set of weighted rubric node scores is produced using a predetermined or a customizable weighting formula. An evaluator or an administrator may customize the weighting formula based on different weight assigned to each of the observation types.

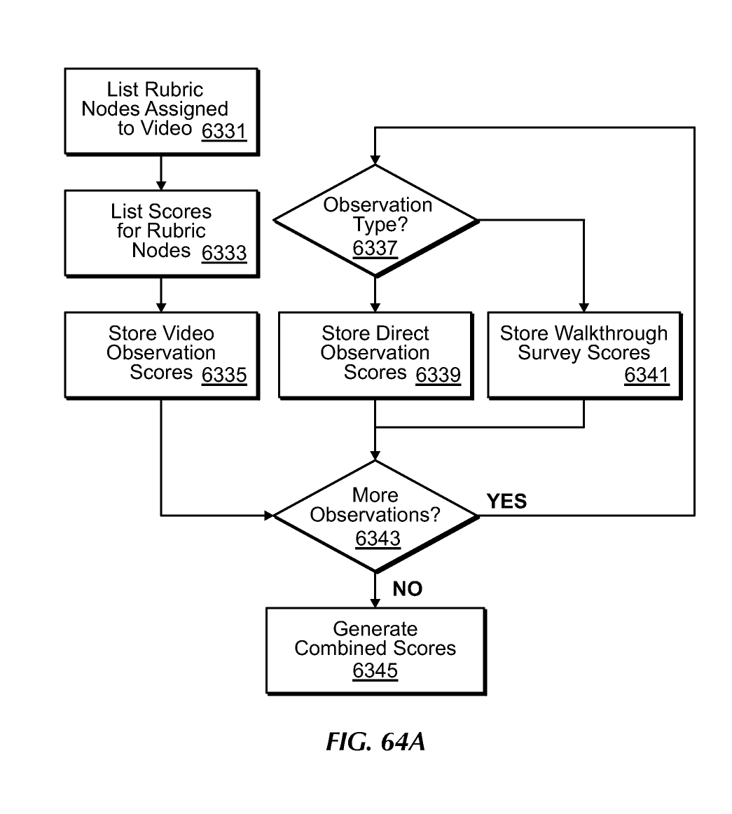

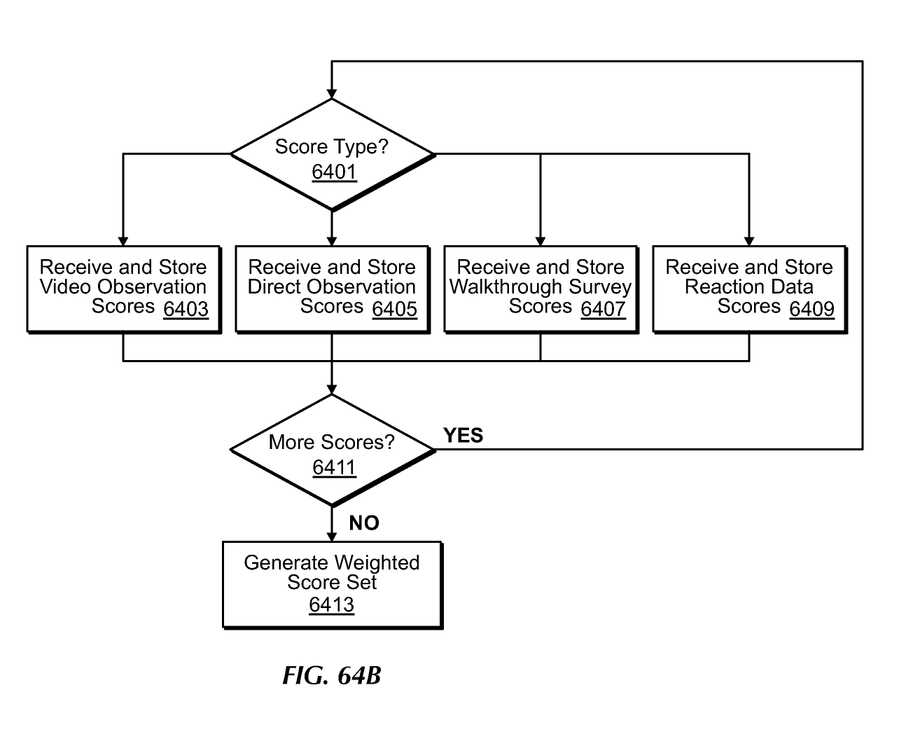

FIG. 64A illustrates one example process for combining video observation scores with direct observation scores and/or walkthrough survey scores. In step 6331, a scorer is given a list of rubric nodes assigned to a video capture of an observation session. In step 6333, a list of possible scores is provided for each rubric node. In step 6335, the score assigned to each node is stored. In step 6343, a user may add other observations to the scoring. In step 6337, the user selects an observation type. In some embodiments, scores for the same rubric node can be weighted differently depending what type of observation produced the score. As such, the observation type of the score affects the determination of the weighted score. In step 6339 and 6341, direct observation scores or walkthrough survey scores are stored. In step 6343, the user may select to add more scores. The additional score may be entered by the user, or retrieve from a content server. While only direct observation scores and walkthrough survey scores are illustrate in FIG. 64A, in other embodiments, other types of observations including another video observation or a live video observation score may also be added to the weighted score. In step 6345, a weighted score is generated. In some embodiments, scores for the same rubric nodes from different observations are combined, and scores that are combined are given different weight based on the observation type that produced the score. For example, for a teaching evaluation, a rubric node describing student interaction with one another is given a score of 5 in a video observation and a score of 3 in a direct observation, the weighting formula may weight the direct observation score more heavily and produce a weighted score of 3.5. In another example, two or more scorers may score a set of same rubric nodes in a video observation. The weighting formula may weigh the scores from each evaluator differently. For example, the weighting rules may be customized based on experience and expertise of the evaluator. In other embodiments, scores can be combined based on categorization of the rubric node to produce a combined score for each category in a rubric.

In general terms and according to some embodiments, a system and method are provided for facilitating an evaluation of performance of one or more observed persons performing a task. The method includes receiving, through a computer user interface, at least two of multimedia captured observation scores, direct observation scores, and walkthrough survey scores corresponding to one or more observed persons performing a task to be evaluated, wherein the multimedia captured observation scores comprise scores assigned resulting from playback of a stored multimedia observation of the performance of the task, wherein the direct observation scores comprise scores assigned based on a real-time observation of the performance of the one or more observed persons performing the task, and the walkthrough survey scores comprise scores based on general information gathered at a setting in which the one or more observed persons performed the task. And, the method generates a combined score set by combining, using computer implemented logics, the at least two of the multimedia captured observation scores, the direct observation scores, and the walkthrough survey scores.

FIG. 64B illustrate an embodiment of a computer implemented process for combining and weighting of at least two of video observation scores, direct observation scores, walkthrough survey scores, and reaction data scores. Reaction data scores are based on data gathered from persons reacting to the performance of the person being evaluated. In some embodiments, the persons reacting are included in the observed persons, while in other embodiments, one or more of the persons reacting may be in attendance or witnessing the observed task, but not part of the video and/or audio captured observation. The data may be gathered by for example, surveying, observing, and/or testing persons present during the performance of the task. For example, if the person being evaluated is a teacher, the reaction data score may be student data such as longitudinal test data, student grades, specific skills gaps, or student value added date in the form of survey results. In step 6401, a user selects a score type to enter. In steps 6403, 6405, 6407, and 6409, the user enters video observation scores, direct observation scores, walkthrough survey scores, or student data. In some embodiments, some or all of the scores are already stored on a content server, and are imported for combining. The video observation scores, direct observation scores, walkthrough survey scores, and reaction data scores can be scored by one or more scorers and can be based on one or more observations sessions. In step 6411, the user can select more scores to combine or generate weighted scores based on scores already selected. In step 6413, a weighted score set is generated. The weighting of the scores can be customized based on, for example, observation type, scorer, or observation session. Additionally, in some embodiments, scores of individual rubric nodes can be weighted and combined to generate a summary score for a rubric category or for the entire evaluation framework.

In some embodiments, the combining of scores further incorporates combining artifact scores to generate the combined score set. An artifact score is a score assigned to an artifact related to the performance of a task. In an education setting for example, the artifact may be a lesson plan, an assignment, a visual, etc. An artifact can be associated with one or more rubric nodes and one or more scores can be given to the artifact based on how well the artifact meet the desired characteristic(s) described in the one or more rubric nodes. The artifact score can be given to a stand-alone artifact or an artifact associated with an observation such as a video or direct observation. In some embodiments, the artifact score for an artifact associated with an observation is incorporated into the scores of that observation. In some embodiments, artifact scores are stored as a separate set of scores and can be combined with at least one of video observation scores, direct observation scores, walkthrough survey scores, and reaction data to generate a combined score. The artifact scores can also be weighted with other types of scores to produced weighted scores.

In general terms and according to some embodiments, a system and method are provided for facilitating an evaluation of performance of one or more observed persons performing a task. The method comprises receiving, via a user interface of one or more computer devices, at least one of: (a) video observation scores comprising scores assigned during a video observation of the performance of the task; (b) direct observation scores comprising scores assigned during a real-time observation of the performance of the task; (c) captured artifact scores comprising scores assigned to one or more artifacts associated with the performance of the task; and (d) walkthrough survey scores comprising scores based on general information gathered at a setting in which the one or more observed persons performed the task. Also, reaction data scores are received via the user interface, the reaction data scores comprising scores based on data gathered from one or more persons reacting to the performance of the task. And, the method generates a combined score set by combining, using computer implemented logics, the reaction data scores and the at least one of the video observation scores, the direct observation scores, the captured artifact scores and the walkthrough survey scores.

In some embodiments, a purpose of performing evaluations is to help the development of the person or persons evaluated. The scores obtained through observation enable the capturing of quantitative information about an individual performance. By analyzing information gathered through the evaluation process, the web application can develop an individual growth plan based on how well the performance meets a desired set of skills or framework. In some embodiments, the individual growth plan includes suggestions of PD resources such as Teachscape's repository of professional development resources, other online resources, print publications, and local professional learning opportunities. The PD recommendation may also be partially based on materials that others with similar needs have found useful. In some embodiments, when evaluation scores are produced by one or more observation, the web application provides professional development (PD) resource suggestions to the evaluated person based on the one or more evaluation scores. The score may be a combined score based on one or more observations.

FIG. 65 illustrates one embodiment of a process for suggesting PD resources. In step 6501-6506, scores are assigned to a list of rubric nodes associated with an observation. The observation may be a video observation, a direct observation, or a walkthrough survey. In step 6509, scores are combined. In some embodiments, scores can be combined based on categories within the one observation. In other embodiments, scores from multiple scorers are combined. In still other embodiments, scores from steps 6501 to 6507 are combined with scores from one or more other observation types and/or observation sessions such as a direct observation or a live video observation. In still other embodiments, scores received from steps 6501 to 6506 are combined with reaction data as described with reference to FIG. 64. In some embodiments, step 6509 is omitted, and the suggestion of PD resource is based on scores stored in step 6506. In some embodiments, combined scores may be weighted. In step 6511, PD resources are suggested at least partially based on scores generated in step 6509. For example, if a low score is given to a rubric node, the application would suggest PD resources for improving the desired attributes described in the rubric node. In other embodiments, a PD resource can also be suggested based on how well others have rated the PD resource, and PD resources others have fund useful is suggested.

In general terms and according to some embodiments, a system and method are provided for use in evaluating performance of a task by one or more observed persons. The method comprises outputting for display through a user interface on a display device, a plurality of rubric nodes to the first user for selection, wherein each rubric node corresponds to a desired characteristic for the performance of the task performed by the one or more observed persons; receiving, through an input device, a selected rubric node of the plurality of rubric nodes from the first user; outputting for display on the display device, a plurality of scores for the selected rubric nodes to the first user for selection, wherein each of the plurality of scores corresponds to a level at which the task performed satisfies the desired characteristics; receiving, through the input device, a score selected for the selected rubric node from the user, wherein the score is selected based on an observation of the performance of the task; and providing a professional development resource suggestion related to the performance of the task based at least on the score.

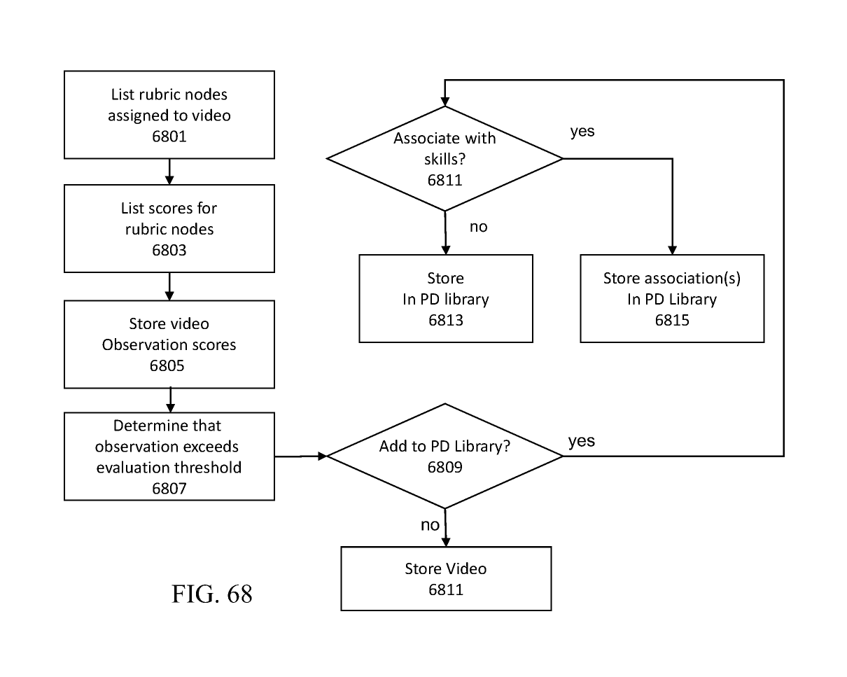

In some embodiments, captured and scored video observations previously stored on the content server can added to a PD library that is accessed to suggest a PD resource to the one or more observed person. FIG. 68 describes a process for adding a video capture to the PD library. Steps 6801 to 6807 describe the scoring of a video observation. In step 6801, a list of rubric nodes assigned to the video is displayed. In step 6802, scores associated for each rubric node is displayed. In step 6805, scores are assigned and stored for the video observation. In step 6807, the scores assigned to the video observation are compared to a pre-determined evaluation threshold to determine whether the video exceeds the threshold. In some embodiments, a threshold may be set for each rubric node, for a combined score for each category of the rubric, for a combined score for each rubric, for a combined score across all rubrics, or for a combination of some of the above. For example, a video may be determined to exceed the evaluation threshold if at least one rubric node receives a score above the threshold. Or, a video observation may be determined to exceed the evaluation threshold if the video's combined score across all rubrics exceeds a threshold and the video observation has at least one rubric node that received a score that exceeds a higher threshold. In step 6809, a determination to include or not include the video observation in the PD library is made. The determination in step 6809 can be made by a user. The user may be the observed person captured in the video observation who may or may not wish to publish a video capture of his or her performance in the PD library. The user may also be an administrator of the PD library who reviews the video before including the video observation into the library. In some embodiment, the step 6809 can also be determined automatically by the application based on, for example, the number of videos in the PD library that describe the same skill or skills, or other setting previously determined by the owner of the video and/or the administrator of the PD library. If in step 6809, is it determined that the video is not to be added to the library, the video will be stored in step 6811. If in step 6809, is it determined that the video should included in the library, then in step 6811, a determination is made to associate the video with a skill or skills. Some or all of the rubric nodes used to score the video are associated with one or more specific skills. In some embodiments, the determination in step 6811 can be made by a person reviewing the videos who determines the skills to be associated with the video based on the content of the video and/or scores the video received. The determination can also be made automatically by the application based on the scores assigned to rubric nodes associated with particular skills. The determination can also be based on a combination of determination made by a person and determination automated by the application. For example, for video observations only associated one skill, the application may store the video into the PD library in step 6813, and for video observations associated with more than one skill, a person can be prompted to determine which skills the video should be associated with in the PD library, and the association is then stored in the PD library in step 6815. In some embodiments, some videos may also be stored in the PD library without being associated with any skill.

A videos added to the PD library through the process illustrated in FIG. 68 can then be accessed by a user browsing the PD library for resources, along side other PD resources. A video added to the PD library through the process illustrated in FIG. 68 can also be suggested to an observed person based on their evaluation scores, along side other PD resources.

In some embodiments, a video added to the PD library is accessible by all user of the web application. In some embodiments, a video added to the PD library is accessible by only the users in the workgroup the owner of the video belongs to. In some embodiments, comments and artifacts associated with a video are also shown when the video is accessed through the PD library. In other embodiments, the owner of the video or an administrator can choose to include some or all of the comments and artifacts associated with the video in the PD library.

In general terms and according to some embodiments, a system and method are provided for use in developing a professional development library relating to the evaluation of the performance of a task by one or more observed persons. The method comprises: receiving, at a processor of a computer device, one or more scores associated with a multimedia captured observation of the one or more observed persons performing the task; determining by the processor and based at least in part on the one or more scores, whether the multimedia captured observation exceeds an evaluation score threshold indicating that the multimedia captured observation represents a high quality performance of at least a portion of the task; determining, in the event the multimedia captured observation exceeds the evaluation score threshold, whether the multimedia captured observation will be added to the professional development library; and storing the multimedia captured observation to the professional development library such it can be remotely accessed by one or more users.

### Custom Publishing Tool

Next, in some embodiments, the user may select to access the custom publishing tool from the homepage to create one or more customized collections of content. In one embodiment, only certain users are provided with the custom publishing tool based on their access rights. That is, in one or more embodiments, only certain users are able to create customized content comprising one or more videos within the video catalog or as stored at the content delivery server. In one embodiment, for example, only users having administrator or educational leader access rights associated with their accounts may access the custom publishing tool. In one embodiment, the custom publishing tool enables the user to access one or more videos, collections, segments, photos, documents such as lesson plans, rubrics, etc., to create a customized collection that may be shared with one or more users of the system or workspaces to provide those users with training or learning materials for educational purposes. For example, in one embodiment, an administrator may provide a group of teachers with a best teaching practices document having one or more documents, photos, and panoramic videos, still videos, rubrics, etc. In one embodiment, while in the custom publishing tool the user may access one or more of content available in the user's catalog, all content available at one or more remote servers as well as content locally stored at the user's computer.

In one embodiment, the custom publishing tool allows the user to drag items from the library to create a customized collection of materials. Furthermore, in one or more embodiments, the user is able to upload materials either locally or remotely stored and use such materials as part of the collection. FIG. 39 illustrates an exemplary display screen that will be displayed to the user once the user selects to enter the custom publishing tool. As shown, the user will have access to one or more containers in the custom content section and will further have access to the workspaces associated with the user. In one embodiment, using the add button 3910 on top of the page the user is able to add folders, create pages or upload locally stored content into the system. In one embodiment, folders area added to the custom content list and will create a new container for a collection. As shown, one or more containers may comprise subfolders. Furthermore, the user in some embodiments is provided with a search button 3920 to search through the user's catalog of content. In some embodiments, search options will appear once the user has selected to search within the content stored in one or more databases the web application has access to. In one embodiment, the uploaded content from the user's computer as well as the content retrieved from one or more databases will appear in the list of resources. The user is then able to drag one or more content from the list to one or more containers in the custom content containers and create a collection. The user may then drag one or more of the containers into one or more workspaces in order to share the custom collections with different users.

Referring now to FIG. 4, a diagram is shown of different functional application components of the web application in accordance with some embodiments. As illustrated, in one or more embodiments, the web application comprises a content delivery application component 410, a viewer application component 420, a comment and share application component 430, an evaluation application component 440, a content creation application component 450, and an administrator application component 460. In one embodiment, one or more other additional application components may further be provided at the web application. In other embodiments, one or more of the above application components may be provided at the user's computer and the user may be able to perform certain functions with respect to content at the user computer while not connected to the web application. In one or more such embodiments, the user will then connect to the web application at a later time and the application will seek and update the content at the web application and content delivery server based on the actions performed at the user computer. It is understood that by using the term application component, the component may be a functional module or part of the larger web application or alternatively, may be a separate application that functions together with one or more of the functional components or the larger application.

The content delivery application component 410 is implemented to retrieve content stored at the content delivery server and provide such content to the user. That is, as described above, and in further detail below, in one or more embodiments, uploaded content from user computers is delivered to and stored at the content delivery server according to several embodiments. In one or more such embodiments the content delivery application component, upon a request by the user to view the content, will request and retrieve the content and provide the content to the user. In one or more embodiments, the content delivery application component 410 may process the content received from the content delivery server such that the content can be presented to the user.

The viewer application component 420 is configured to cause the content retrieved by the content delivery application component to be displayed to the user. In one embodiment, as illustrated in one or more of the FIGS. 31-40 displaying the content to the user comprises displaying a set of content such as one or more videos, one or more audios, one or more photos, as well as other documents such as grading rubrics, lesson plans, etc., as well as a set of metadata comprising one or more of stream locations, comments, tags, authorizations, content information, etc. In one embodiment, the viewer application component is able to access the one or more content and the one or more metadata and cause a screen to be displayed to the user similar to those described with respect to FIGS. 31-40 displaying the set of content and metadata that makes up a collection or observation.

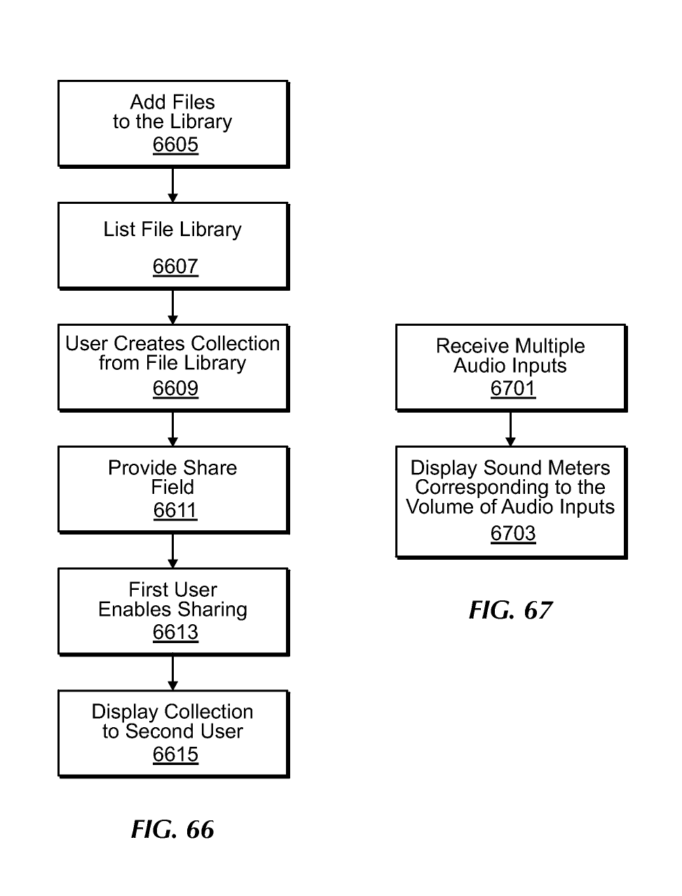

FIG. 66 illustrates an embodiment of a process for sharing a collection created using an embodiment of the custom publishing tool described above. In step 6605, a user adds files to a file library. A file can be added to the file library by uploading the file from a local memory device. A file can also be added by selecting the file from files that is already stored on the content delivery server. In some embodiments, file library consist of all the files on the content delivery server the user has access to. In step 6607, the file library is displayed. As previously described, the file library may be displayed with files organized in containers. In step 6609, the user creates a collection by selecting files from the library. In some embodiments, the user may modify a file in the file library prior to adding the file to the collection. For example, the user can create a video segment from a full length video observation file and include only the video segment in the collection. In another example, the user can annotate a video observation file with time stamped tags and add the annotated video observation file to the collection. In step 6611 a share field is provided to the user. In step 6614 the user enables sharing using the share field. In some embodiments, the user belongs to a workgroup, and when sharing is enables, the collection is shared with every user in the workgroup. In other embodiments, the user may enter names of groups or individuals to grant other users access to the collections. In some embodiments, the level of access can be varied. For example, some users may be collaborators and are given access to modify the collection, while other users are only given access to view the collection. In step 6615, when a second user with access permission accesses the web application, the collection is made available to the second user. In some embodiments, what the second user is able to do with the collection is determined by the permission set in step 6613.

### Viewer Application

FIG. 5 illustrates an exemplary embodiment of the process for displaying the content to the remote user at the web application. As illustrated, the video player/display area 510 displays both a panoramic video 510 and still video 520 and one or more audio sources, e.g., teacher audio and classroom audio associated with the video. As shown in this embodiment, the one or more video feeds and audio are retrieved from the content delivery network/server. In one embodiment, when the content is uploaded to the content delivery server the video and audio are combined, while in other embodiments, each of the video/audio is separately stored and processed for playback and combined at the web application by the viewer application 420. In one embodiment, as illustrated a panoramic stream, and a board stream, as well as a teacher audio and classroom audio are retrieved from the content delivery server. In one embodiment, the one or more video and audio is retrieved and stored locally before being processed and played back at the web application. In another embodiment, the content is played back as it is being retrieved from the content delivery server. In one embodiment, as described above, the content delivery application will enable the retrieval, storing and/or buffering of the video/audio for playback by the viewer application.

In one embodiment, as illustrated in FIG. 5, once the content is received at the viewer application component, the panoramic stream and the board stream are synchronized. In one embodiment, one or more of the panoramic and board videos, as well as the audios are received at the web application in a streaming manner. In one embodiment, the process of synchronization comprises monitoring the playback time for each of the videos such that the videos are played back in a substantially synchronized manner. The process of synchronization comprises retrieving a lag time generated at the capture application at the time of recording the content. In one embodiment, the lag time comprises a time between the start of recording of each of the panoramic video and board video. In one embodiment, the lag time is stored with one or both of the panoramic video and board video at the content delivery network. In one embodiment, the lag time is calculated with reference to a master video, e.g. the panoramic video, and stored along with the panoramic video as metadata. In another embodiment, the board video may be the master video and the lag time is calculated with respect to the board video.

After retrieving the lag time, the viewer application component is then able to calculate the time at which each video should begin to play. In one embodiment, for example, the lag time is used to start the player for each of the videos at a same or proximately same time. In other embodiments, the duration of each video is taken into account and the videos are only played for the duration of the shorter length video. In one embodiment, the video duration is further stored as part of the content metadata along with the content at the content delivery network and will be retrieved with each of the board stream and panoramic stream at the time of retrieving the content. In one embodiment, for example, content metadata including the lag time and/or duration is stored as the header information for the panoramic stream and board stream and will be received before receiving the content as the content is being streamed to the player/web application. In additional embodiments the audio will also be synchronized along with the video for playback. In one embodiment, the audio may be embedded into the video content and will be received as part of the video and synchronized as the video is being synchronized.

Once the videos begin to play, the viewer application component will attempt to play the streams in a synchronized manner. In one embodiment, the viewer application component will continuously monitor the play time of each of the audio and video to determine if the panoramic stream and the board stream, as well as the associated audio, are playing at the same time during each time interval. For example, in one embodiment, the viewer application performs a test every frame to determine that both videos are within 0.5 or 1 seconds of one another to determine whether the two streams are playing back at the same location/time within the content, if the two players are not playing at the same location, the viewer application will then either pause one of the streams until the other stream is at the same location or will skip playing one or more frames of the stream that is behind to synchronize the location of both videos. In one embodiment, the synchronization process will further take into account frame rates as well as bandwidth and streaming speed of each of the streams for synchronizing the streams. Further, in one embodiment the viewer application will monitor whether both content are streaming, and if it is determined that one of the content is buffering then the application will pause playback until enough of the other video is streamed. In one embodiment, the monitoring of play time and buffering may be performed with respect to the master video. For example, one of the panoramic and board stream will be the master video and during the monitoring process the viewer application will perform any necessary steps, such as pausing the video, skipping frames, etc. to cause the other video/audio to play in synchronization with the master video. The synchronization process is described herein with respect to two streams, however it should be understood that the same synchronization process may be used for multiple videos.

In one embodiment, the teacher audio and classroom audio are further synchronized in the same manner as described above either independent of the videos, or synchronized as part of the videos while the videos are being synchronized.

In one embodiment, the viewer application 420 further enables audio channel selection between the audios.

That is, as shown in FIG. 5, the user is provided with a slide adjuster for adjusting the ratio of each audio that is presented in the audio combined final played back to the user. In the illustrated FIG. 5, the audio is being played back with equal weight given to the teacher audio and classroom audio. However, by having two separate channels of audio, the user is able to adjust the weight of each audio so that the user can adjust the experience of viewing the audio. In one embodiment, based on the selection of the user, using the toggle, the viewer application, upon receiving the audio will assign different weight to each audio before playing back the audio to the user, thus creating the desired auditory effect for the user. In one embodiment, the audio is recorded on two separate channels, left and right channel, and the audio may be filtered by altering or turning off one or both the channels.

In some embodiments, the viewer application component further enables switching between different views of the video streams. As shown in FIG. 5 and further described with respect to FIGS. 31-35, a user is able to select between a side by side view and a 360 picture-in-picture view of the videos. In one embodiment, switching between the views may comprise redrawing the display areas displaying the content to alter their respective overlay characteristics. In one embodiment, the viewer application comprises the capability of receiving the streams and processing the streams such that they can be played back in the desired view selected by the user. In one embodiment, the panoramic stream and board stream are stored in a single format in the content delivery device and the viewer application is configured to process the content for playback in the desired format selected by the user. In other embodiments, the streams may be stored in different formats for the desired viewing options at the content delivery server, and/or the content delivery server will contain specialized software to process the content before the content is sent to the web application such that the web application is able to request the content in the format desired by the user and no processing is necessary at the web application.

In one embodiment, the content delivery server further stores the basic information/metadata entered at the capture application and uploaded along with the content to the content delivery server. In one embodiment, such metadata will further be retrieved by the player and displayed to the user as described for example with respect to FIGS. 31-38. In one embodiment, for example, the basic information associated with the content such as teacher name, subject, grade etc. will be stored as header information with the content and will be displayed to the user at the player of the web application.

As illustrated in FIG. 5 in addition to being in communication with the content delivery server, the web application/viewer application component 420 is also communicationally coupled to a metadata database storing one or more metadata such as stream locations, comments/tags, documents, locations of photos, workflow items such as whether a capture is viewed yet, sharing information, information on where captures are referenced from in the content, indexing information for searching support, ownership information, usage data, rating and relevancy data for search/recommendation engine support, framework support etc.

In one embodiment, while retrieving and playing back the content, the viewer application component is further configured to request the metadata associated with the content being played back and displaying the metadata at the player. For example, as described above, marker tags for comments will be placed along the seek bar below the videos to indicate the location of the comments within the video. In one embodiment, the metadata database stores the comment time stamps along with the comments/tags and will retrieve these time stamps from each comment/tag to determine where the tag marker should be placed along the player. In addition, comments and tags are further displayed in the comment list. In one embodiment, the metadata database may further comprise additional content such as photos and documents associated with the videos and will provide access to such content at the web player.

### Web Application

Referring back to FIG. 4, the comment and share application component 430 enables the user to view one or more user videos, i.e., videos captured by the user or to which the user has administrative access rights, and to manage, annotate and share the content. As described above when in the web application, the user is able to access content, edit the content and/or metadata associated with the content, provide comments with respect to the content and share the content with one or more users. The comment/share application component allows the user to edit, delete or add one or more of the metadata associated with the content such as basic information, comment/tags, additional artifacts such as photos, documents, rubrics, lesson plans etc., and further allows the user to share the content with other users of the web application, as described in FIG. 3.

In one embodiment, the comment/share application component 430 allows the user to provide comments regarding the content being viewed by the user. In one embodiment, when the user enters a comment into the comment field provided to the user, the comment/share application will store a time stamp representing the time at which the user began the comment and tags the content with the comment at the determined time. In other embodiments, the time stamp may comprise the time at which the user finishes entering the comment. The comment is then stored along with the time stamp at the metadata database communicatively coupled to the web application. In one embodiment, the user may further associate one or more comments with predefine categories or elements available for example from a drop down menu, in such embodiments, similarly, the comment is stored with a time stamp representing the time in the video the content was tagged to the metadata database for further retrieval. In one embodiment, tagging is achieved by capturing the time in one or both videos, for example, in one instance the master video, and linking the time stamp to persistent objects that encapsulate the relevant data. In one embodiment, the persistent objects are permanently stored, for example through a framework called Hibernate, which abstracts the relational database tier to provide an object oriented programming model.

Furthermore, the comment/share application component 430 provides the user with the ability to edit one or more metadata associated with the content and stored at the content delivery server and/or the metadata database. In one embodiment, for example, the content is associated with one or more information, documents, photos, etc. and the user is able to view and edit one or more of the content and save the edited metadata. The edited metadata may be then stored onto one or more of the content delivery server and/or the metadata database or other remote or local databases for later retrieval and the edited metadata will be displayed to the user.

In some embodiments, the comment/share application component 430 enables the user to share the content with other individuals, user groups or workspaces. In one embodiment, for example, the user is able to select one or more users and share the content with those users. In other embodiments, the user may be pre-assigned to a group and will automatically share the content with the predefined group of users. Similarly, the comment/share application component 430 allows the user to stop sharing the content currently being shared with other users. In one embodiment, the sharing status of the content is stored as metadata in the metadata database and will be changed according the preferences of the user.

The evaluation application component 440 allows the user to access colleagues' content or observations, e.g., observations or collections authored by other users, and evaluate the content and provide comments or scores regarding the content. In one embodiment, the evaluation of content is limited to allowing the user to provide comments regarding the videos available to the user for evaluation. In another embodiment, the evaluation application component 440 comprises a coding/scoring application for tagging content with a specific grading protocol and/or rubric and providing the user with a framework for evaluating the content. The evaluation of content is described in further detail with respect to FIG. 3 and FIGS. 37 and 38.

The content creation application component 450 allows one or more users to create a customized collection of content using one or more of the videos, audios, photos, documents and artifacts stored at the content delivery server, metadata database or locally stored at the user's computer. In some embodiments, a user may create a collection comprising one or more videos and/or segments within the video library as well as photos and other artifacts. In some embodiments, the user is further able to combine one or more videos, segments, documents such as lesson plans, rubrics, etc., and photos, and other artifacts to create a collection. For example, in one embodiment, a Custom Publishing Tool is provided that will enable the user to create collections by searching through videos in the video library, as well as browsing content locally stored at user's computer to create a collection. In one embodiments, the content creation application component enables a user to create a collection of content comprising one or more multi-media content collections, segments, documents, artifacts etc., for education or observation purposes.

In one embodiment, for example, the content creation application component 450 allows a user to access one or more content collections available at the content delivery server and one or more content stored at one or more local or remote databases as well as content and documents stored at the user's local computer and combine the content to arrive at a custom collection that will be then shared with different users, user groups or work spaces for the purpose of improving teaching techniques.

The administrator application component 460 provides means for system administrators to perform one or more administrative functions at the web application. In one embodiment, the administrator application component 460 comprises an instruments application component 462 and a reports application component 464.

The instruments application component 462 provides extra capabilities to the administrator of the system. For example, in one embodiment, a user of the web application may have special administrator access rights assigned to his login information such that upon logging into the web application the administrator is able to perform specific tasks within the web application. For example, in one embodiment, the administrator is able to configure instruments that may be associated with one or more videos and/or collections to provide the users with additional means for review, analyzing and evaluating the captured content within the web application. In another embodiment, instruments may be assigned on a global level to all content for a set of users or workspaces. One example of such instruments is the grading protocol and rubrics which are created and assigned to one or more videos to allow evaluation of videos. In one or more embodiments, the web application enables the administrator to configure customized rubrics according to different considerations such as the context of the videos, as well as the overall purpose of the instrument being configured. In one embodiment, one or more administrators may have access rights to different groups of videos and collections and/or may have access to the entire database of captured content and may assign the configured instruments to one or more of the videos, collections or the entire system.

The reports application component 464 is configured to allow administrators to create customized reports in the web application environment. For example, in one embodiment, the web application provides administrators with reports to analyze the overall activity within the system or for one or more user groups, workspaces or individual users. In one embodiment, the results of evaluations performed by users may further be analyzed and reports may be created indicating the results of such evaluation for each user, user group, workspace, grade level, lesson or other criteria. The reports in one or more embodiments may be used to determine ways for improving the interaction of users with the system, improving teacher performance in the classrooms, and the evaluation process for evaluating teacher performance. In one embodiment, one or more reports may periodically be generated to indicate different results gathered in view of the user's actions in the web application environment. Administrators may additionally or alternatively create one time reports at any specific time.

### Capture Application

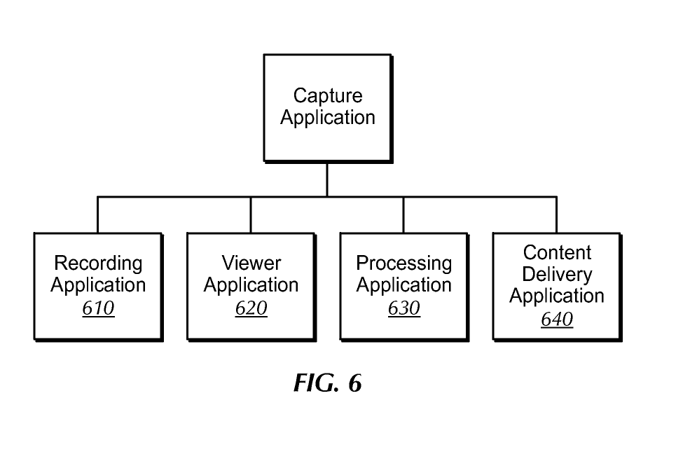

Next, referring to FIG. 6, a diagram of the functional components of the capture application is illustrated according to one or more embodiments. In one embodiment, as illustrated, the capture application comprises a recording application component 410, a viewer application component 420, a processing application component 430, and a content delivery application component 440.

The recording application component 410 is configured to initiate recording of the content and is in communication with one or more capture hardware including cameras and microphones. In one embodiment, for example, the recording application component is configured to initiate capture hardware including two cameras, a panoramic camera and still camera, and two microphones, teacher microphone and student microphone and is further configured to store the recorded captured content in a memory or storage medium for later retrieval and processing by other applications of the content capture application. In one embodiment, when initializing the recording, the recording application component 610 is further configured to gather one or more information regarding the content being captured, including for example basic information entered by the user, a start time and end time and/or duration for each video and/or audio recording at each of the cameras and/or microphones, as well as other information such as frame rate, resolution, etc. of the capture hardware and may further store such information with the content for later retrieval and processing. In one embodiment, the recording application component is further configured to receive and store one or more photos associated with the content.

The viewer application component 620 is configured to retrieve the content having been captured and process the content to provide the user with a preview of the content being captured. In one embodiment, the captured content is minimally processed at this time and therefore may be presented to the user at a lower frame rate, resolution, or may comprise selected portions of the recorded content. In one embodiment, the viewer application component 620 is configured to display the content as it is being captured and in real time while in other embodiments, the content will be retrieved from storage and displayed to the user with a delay.

The processing application component 630 is configured to retrieve content from the storage medium and process the content such that the content can then be uploaded to the content delivery server for remote access by users of the web application. In one embodiment, the processing application component 630 comprises one or more sets of specialized software for decompressing, de-warping and combining the captured content into a content collection/observation for upload to the content delivery server over the network. In one embodiment, for example, the content is processed and videos/audios are combined to create a single deliverable that is then sent over the network. In one embodiment, the processing server further retrieves metadata, such as video/audio recording information, basic information entered by the user, and additional photos added by the user during the capture process, and combines the content and the metadata in a predefined format such the content can later be retrieved and displayed to a user at the web application. In one embodiment, for example the video and audio are compressed into MPEG format or H.264 format, Photos are formatted in JPEG format and a separate XML file that holds the metadata is provided, including, in one embodiment, the list of all the files that make the collection. In one embodiment, the data is encapsulated in JSON (Java Script Object Notation) objects depending one the usage of a particular service. In one embodiment, the metadata and content are all separately stored and various formats may be used depending on the use and preference.

The content delivery application component 640 is in communication with the content delivery server and is configured to upload the captured and processed content collection/observation to the content delivery server over the network according to a communication protocol. For example, in one embodiment, content is communicated over the network according to the FTP/sFTP communication protocol. In another embodiment content is communicated in HTTP format. In one embodiment the request and reply objects are format in JSON format.

FIGS. 7A and 7B illustrate an exemplary system diagram of the capture application according to several embodiments of the present invention. In one embodiment, the process of FIGS. 7A and 7B refer to the process for providing the user with a pre-capture/live preview while the content is being captured.

As illustrated in FIG. 7A, the capture application is communicatively coupled to a first camera 710, and a second camera 720 through connection means 712 and 722 respectively. In one embodiment, the connection means comprise USB/UVC cables capable of streaming video. It is understood that connection means 712 and 722 may be one physical connector, such as one wire line connection. In one embodiment, the first camera 710 comprises a Logitech C910 camera. In one embodiment, the first camera 710 is a camera capable of capturing panoramic video. For example, as described in one or more embodiments, the camera may comprise a camera or camcorder being attached to an inverted conical mirror such that it is configured to capture a panoramic view of the environment. In one embodiment, the first camera 710 is similar to the camera of FIG. 41. In one embodiment, the second camera 720 is a video camera that has a capability to take still pictures, such as for example, a LifeCam. In one embodiment, the camera 720 is placed or oriented such that it will capture the board in the classroom environment and thus may be referred to as the board camera. In one embodiment, the camera 720 may be placed proximate to the panoramic camera. For example, in one embodiment a mounting assembly is provided for mounting both the panoramic camera and still camera.

In one or more embodiments, one or both cameras 710 and 720 further comprise microphones for capturing audio. In other embodiments, one or more independent microphones may be provided for capturing audio within the monitored environment. For example, in one embodiment, two microphones/audio capture devices are provided, the first camera may be placed proximate to one or both the cameras 710 and 720 to capture the audio from the entire monitored environment, e.g. classroom, while another microphone is attached to a specific person or location within the classroom for capturing a more specific sound within the monitored environment. For example, in one embodiment, a microphone may be attached to a speaker within the monitored environment, e.g. teacher microphone, for capturing the speaker audio. In one embodiment, the audio feed from these microphones is further provided to the capture application. In one embodiment, the one or more microphones may further be in communication with the captured application through USB connectors or other means such as wireless connection.

As shown, the video feed from the cameras 710 and 720 and additionally the audio from the microphones is communicated over the connection means to the computer where the capture application resides. In one embodiment, the computer is a processor-based computer that executes the specialized software for implementing the capture application. In one embodiment, once the video/audio is received from the cameras and/or microphones it is then recorded to a file system storage medium for later retrieval. In one embodiment, the storage medium resides locally at the computer while in other embodiments, the storage medium may comprise a remote storage medium. In one embodiment, the storage medium may comprise local memory or a removable storage medium available at the computer running the capture application.

Next, the capture application retrieves the stored content for display before or during the capture process or stores the content for providing a preview as discussed for example with respect to FIGS. 14 and 15 in the upload queue. In one embodiment, the display of content as shown in FIGS. 11-12 is for the purpose of allowing the user to adjust the setting of the captured content, e.g. brightness, focus, and zoom, previous to initiating capture/recording, or to ensure that the right areas or content is being captured during the capture process.

In one embodiment, the retrieved stored content is first decompressed for processing. In one embodiment, each of the first camera and second camera are configured to compress the content as it is being capture before streaming the content over the connection means to the capture application. In one embodiment, for example, each frame is compressed to an M-JPEG format. In one embodiment, compression is performed to address the issue of limited bandwidth of the system, e.g. local file system, or other transmittal limitations of the system to make the transmitting the streams over the communication means more efficient. In an alternative embodiment, the compression may not be necessary if the system has enough capability to transmit the stream in its original format. In an alternative embodiment, the compression may be performed directly on the video capture hardware, as on a smartphone like the iPhone, or with special purpose hardware coupled to the capture hardware, e.g. cameras, and/or the local computer.

In one embodiment, the content is stored at the file system storage as raw data and the user is able to view raw video on the capture laptop. In other embodiments, the stored video content is compressed and therefore decompression is required before the content can be displayed to the user for preview purposes. In one embodiment, further, the panoramic content from the camera 710 is warped content. That is, in one embodiment, the panoramic content is captured using an elliptical mirror similar to that of FIG. 41. In one or more such embodiments, the warped content is unwarped using warping software during the process. In one embodiment, for example, after the panoramic video content is decompressed, it is then sent to an unwarping application within the capture application for unwarping. After the content has been processed, it is then forwarded to a graphic interface for rendering such that the content can be displayed to the user. In one embodiment, the video content is displayed for preview purposes without audio. In another embodiment, audio may further be played back to the user by retrieving the audio from storage and playing back the audio along with the displayed video content.

FIG. 7B illustrates an alternative embodiment of the capture process. Several steps of the process are similar to the process as described with respect to FIG. 7B and therefore will not be repeated herein and only the distinctions will be discussed. As shown, in this embodiment, content is forwarded from the camera 710 using a TCP/IP connection. In one embodiment, the content is sent for example over a wireless network and received at the capture application. In one embodiment, the RTSP component at the capture application is configured to receive and process the content before the content is recorded at the file system storage medium. Furthermore, in the alternative embodiment of FIG. 7B, the unwarping application and recording and processing application are combined into a single processing component before being passed to the interface for rendering and creating a preview canvas.

FIG. 8 illustrates an exemplary system flow diagram of the capture application process for capturing and uploading content according to several embodiments of the present invention. In FIG. 8, it is assumed that compressed board video, compressed panoramic video, teacher and classroom audio are already stored in a file system 802 (such as one or more memories of the local computer or coupled to the local computer). In some embodiments, one or more of this stored content is stored in an uncompressed form.

In some embodiments, the stored content is received directly from the respective source of the content, for example, the stored content is received directly from the content sources illustrated and variously described in FIGS. 7A and 7B. In one embodiment, similar to that shown in FIGS. 7A and 7B, the capture application is communicatively coupled to a first camera, and a second camera through wired or wireless connection means. In one embodiment, the connection means comprise USB/UVC/Firewire/Ethernet cables capable of streaming video. In another embodiment, one or more of the streams may be received wirelessly for example through TCP/IP connection. It is understood that the connection means be one physical connector, such as one wire line connection. In one embodiment, the first camera may for example comprise a Logitech C910 camera. In one embodiment, as indicated in FIG. 8, the first camera is a panoramic camera capable of capturing panoramic video. For example, as described in one or more embodiments, the camera may comprise a camera or camcorder being attached to an inverted conical mirror such that it is configured to capture a panoramic view of the environment.

In one embodiment, the first camera is similar to the camera of FIG. 41. In one embodiment, the second camera is a video camera that is capable, in one or more embodiments, to capture both video and still images, such as for example, a LifeCam. In one embodiment, the second camera is placed or oriented such that it will capture the board, e.g. white board, black board, smart board or other fixed display used by the teacher, in the classroom environment and thus may be referred to as the board camera. In one embodiment, the second camera may be placed proximate to the panoramic camera. For example, in one embodiment a mounting assembly is provided for mounting both the panoramic camera and still camera. In one embodiment, each of the first camera and second camera are configured to compress the content as it is being captured before streaming the content over the connection means to the capture application. In one embodiment, for example, each frame is compressed to an M-JPEG format. In one embodiment, compression is performed to address the issue of limited bandwidth of the storage system, e.g. limited bandwidth of the file system, or other transmittal limitations of the system to make the transmitting the streams over the communication means more efficient. In an alternative embodiment, the compression may not be necessary if the system has enough capability to transmit the stream in its original format.

In one or more embodiments, one or both cameras further comprise microphones for capturing audio. In other embodiments, one or more independent microphones may be provided for capturing audio within the monitored environment. For example, in one embodiment, as indicated in FIG. 8, two microphones/audio capture devices are provided, the first microphone may be placed proximate to one or both the cameras to capture the audio from the entire monitored environment, e.g. student audio, while another microphone is attached to a specific person or location within the classroom for capturing a more specific sound within the monitored environment. For example, in one embodiment, a microphone may be attached to a speaker within the monitored environment, e.g. teacher microphone, for capturing the speaker audio. In one embodiment, the audio feed from these microphones is further provided to the capture application. In one embodiment, the one or more microphones may further be in communication with the captured application through USB connectors or other means such as wireless connection.

During the capture process, the video feed from the panoramic camera and board camera and additionally the audio from the microphones, i.e., student audio and teacher audio are communicated over the connection means to the computer where the capture application resides. In one embodiment, the computer is a processor-based computer that executes the specialized software for implementing the capture application. In one embodiment, once the video/audio is received from the cameras and/or microphones it is then recorded to a file system storage medium for later retrieval. In one embodiment, the storage medium resides locally at the computer while in other embodiments, the storage medium may comprise a remote storage medium. In one embodiment, the storage medium may comprise local memory or a removable storage medium available at the computer running the capture application.

Whether the video/audio content is received directly from the source or from the file system 802, as illustrated in FIG. 8, the processing of content for uploading begins where the capture application retrieves the stored content for processing and uploading (e.g., from the file system 802 or directly from the audio/video source/s). In one embodiment, the stored video content is in its raw format and may not require any decompression. In other embodiments, where the video data is received and stored in a compressed format, e.g. M-JPEG format, each of the retrieved stored panoramic and board video content is first decompressed for processing in steps 804 and 806 respectively. In one embodiment, after the video data is decompressed, in step 808, the panoramic video content from the panoramic camera is unwarped using custom/specialized software. In one embodiment, for example, after the panoramic video content is decompressed, it is then sent to an unwarping application within the capture application for unwarping. Next in step 810 the uncompressed board video content is compressed, for example according to MPEG (motion picture experts group) or H.264 standards, and prepared for uploading to the content delivery server over the network. Similarly, in step 812, the unwarped uncompressed panoramic content is compressed, for example according to MPEG or H.264 standards, and prepared for uploading to the content delivery server over the network. In one embodiment, the compression performed in steps 810 and 812 is performed to address the limits in bandwidth and to make the transmittal of the video content over the network more efficient.

In one embodiment, the two channels of audio are further compressed for being sent over the network during steps 814 and 816. In one embodiment, before upload, the panoramic video and the two sources of audio may be combined into a single set of content. For example, in one embodiment, the compressed panoramic content, teacher audio and classroom audio are multiplexed, e.g. according to MPEG standards, during step 818. In one embodiment, during step 818 the panoramic content and the two audio contents are synchronized. In one embodiment, the synchronization is done by providing the panoramic content to the multiplexer at the original frame rate that the panoramic content was captured and providing the audio content live, e.g. as it was originally captured. In one embodiment, the panoramic camera is configured to record/capture at a predefined frame rate which is then used during the synchronization process during step 818. While this exemplary embodiment is described with the multi-media content being encoded/compressed according to a specific, industry wide, standard such as MPEG or H.264, it should be understood by one of ordinary skill in the art that the content may be encoded using any encoding method. For example, in one embodiment, a custom encoding method may be used for encoding the video. In one embodiment, this is possible because the player/viewer application in the web application environment may be configured to receive and decode/decompress the content according to any standard used for encoding the content.

At this point of the process both the compressed board video content and multiplex panoramic and audio combination content are ready for upload over the network to the content delivery server. In one embodiment, prior to upload the content is saved to file system 802 (e.g., a storage medium) and accessed upon request from a user for upload to the content delivery server over the network.

### ADDITIONAL EMBODIMENTS

While in several embodiments, the capturing application may reside in a processor-based computer coupled to external capture hardware referring back to FIGS. 1 and 2, in some embodiments, the system may additionally or alternatively comprise mobile capture hardware 115 and 215 which are implemented without being connected to a separate computer and instead comprise mobile devices having the capability to directly communicate over the network and transmit video and audio content to the content delivery server to be provided to users of the web application 120/220.

For example, in one embodiment, it may be desirable to capture a classroom environment where the teacher is mobile and moving around the classroom. In such embodiments, the use of cameras that are limited in mobility, i.e. fixed to a specific position within the classroom may not provide the viewer with an effective view of the classroom environment. In such embodiments, it may be desirable to provide one or more mobile capturing devices having capturing and communication capabilities for capturing the teacher as the teacher moves around the classroom and to send the content directly to the content delivery server over the network. In one embodiment, for example, a first mobile device having video and audio capture capability, and a second mobile capturing device having audio capturing capability is provided. The mobile video capture device, in one embodiment is an Apple® iPhone®, while the audio capture device may be a voice recorder or Apple® iPod® or another iPhone. In one embodiment, the audio capture device comprises a microphone that is fixed to or on the teacher's person and therefore captures the teacher's voice as the teacher moves about the classroom environment. In one embodiment, the two mobile capture devices are in communication with one another and can send information regarding the capture to one another. For example, in one embodiment, the two mobile capture devices are connected to one another through Bluetooth connection. In some embodiments, one or both capture devices comprise specialized software that provides same or similar functionality as the capture application as described above. In one embodiment, for example, the capture device may comprise an iPhone having a capture app. In one embodiment, the capture app residing on the iPhone may be similar to the capture application described above with respect to several embodiments. In one embodiment, however, the capture app may be different from the capture application described above. For example, in one embodiment the processing steps of the capture application may differ because the mobile device may capture different types of content. In another embodiment, the compression of the video/audio content may be done in real-time before being stored locally at the mobile capture device.

In one embodiment, the capture application resides in the video capture device, e.g. iPhone. Right at the beginning of the capture, the two devices synchronize over Bluetooth to allow synchronization of the two audio channels/tracks. In one embodiment, the teacher device/audio capture device is the slave, and the video capture device is the master. In one embodiment, synchronization is achieved by exchanging time stamps to synchronize the system clocks of the two mobile capture devices and computing an offset between the clocks. In one embodiment, once this data is captured, recording is then initiated by Master. In one embodiment, each device uploads the captured content independently upon being connected to the network, e.g. through WIFI connection. In one or more embodiments, the uploaded content contains the system clock timestamp for the start instant, as well as the computed offset between the two clocks.

In one embodiment, the video capture device is carried by some means such that it can follow the teacher and capture the teacher as the teacher moves around the classroom. In one embodiment, for example a person holds the mobile device, e.g. iPhone, and follows the teacher to capture the teacher video. In one embodiment, the video capture device further comprises audio capability and captures the classroom audio.

In one embodiment, when capture is initiated the two capture devices communicate to send one another a time stamp representing the time at which recording started at each device, such that a lag time is calculated for later synchronizing of the captured content. In one embodiment, other information, such as frame rate, identification information, etc., may also be communicated between the two mobile capture devices. After the capture process is complete then the captured content from each device is uploaded over the network to the content delivery server. In one embodiment, prior to the upload the content is processed, e.g. compressed. In another embodiment, the captured content may be compressed in real time before being stored locally onto the mobile capture device and no processing and/or compression is performed by the capture application prior to upload. In one embodiment, the content uploaded comprises at least an identification indicator such that once received at the web application the two contents can be associated and synchronized. In one embodiment the lag time is further appended to the content and uploaded over the network for later use. The web application is then capable of accessing the content from the mobile capturing devices and using the information associated with the content will perform the necessary processing to display the content to users.

In one or more embodiments, the mobile capture hardware may be used at an additional means of capturing content and may be displayed to the user along with content from one or more of the content captured by the panoramic or board camera or the microphones connected to the computer 110/210. In some embodiments, the video and or audio content of the mobile device or devices may act as a replacement for one of the video content or audio content captured by capture hardware 114 or 214, 216, 217 and 218, e.g. the board video. In another embodiment, the video and/or from the mobile device may be the only video provided for a certain classroom or lesson. In some embodiments, one or more of the capture hardware connected to the network through computer 110/120 may also be mobile capture devices similar to the mobile capture hardware 114. For example, in one embodiment, the mobile device may not have enough communication capability to meet the requirements of the system and therefore may be wirelessly connected to a computer having the captured application stored therein, or alternatively the content of the mobile device may be uploaded to the computer before being sent over the network.

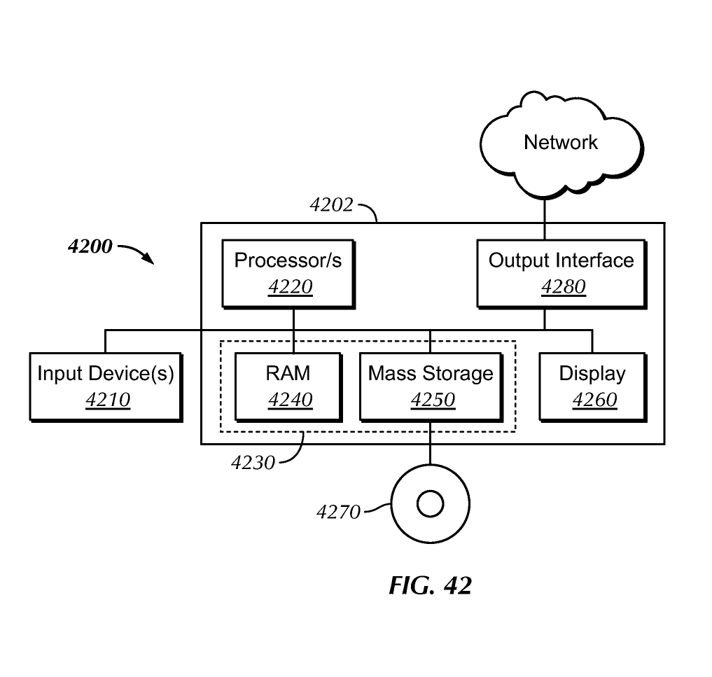

The methods and processes described herein may be utilized, implemented and/or run on many different types of systems. Referring to FIG. 42, there is illustrated a processor-based system 4200 that may be used for any such implementations. One or more components of the system 4200 may be used for implementing any system or device mentioned above, such as for example any of the above-mentioned capture, processing, managing, evaluating, uploading and/or sharing of the content in one or more of the capture application and the web application as well as the user's computer or remote computers.

By way of example, the system 4200 may comprise a computer device 4202 having one or more processors 4220 (such as a Central Processing Unit (CPU)) and at least one memory 4230 (for example, including a Random Access Memory (RAM) 4240 and a mass storage 4250, such as a disk drive, read only memory (ROM), etc.) coupled to the processor 4220. The memory 4230 stores executable program instructions that are selectively retrieved and executed by the processor 4220 to perform one or more functions, such those functions common to computer devices and/or any of the functions described herein. Additionally, the computer device 4202 includes a user display 4260 such as a display screen or monitor. The computer device 4202 may further comprise one or more input devices 4210, such as any user input device such a keyboard, mouse, touch screen keypad or keyboard. The input devices may further comprise one or more capture hardware such as cameras, microphones, etc. Generally, the input devices 4210 and user display 4260 may be considered a user interface that provides an input and display interface between the computer device and the human user. The processor/s 4220 may be used to execute or assist in executing the steps of the methods and techniques described herein.

The mass storage unit 4250 of the memory 4230 may include or comprise any type of computer readable storage or recording medium or media. The computer readable storage or recording medium or media may be fixed in the mass storage unit 4250, or the mass storage unit 4250 may optionally include an external memory device 4270, such as a digital video disk (DVD), Blu-ray disc, compact disk (CD), USB storage device, floppy disk, RAID disk drive or other media. By way of example, the mass storage unit 4250 may comprise a disk drive, a hard disk drive, flash memory device, USB storage device, Blu-ray disc drive, DVD drive, CD drive, floppy disk drive, RAID disk drive, etc. The mass storage unit 4250 or external memory device 4270 may be used for storing executable program instructions or code that when executed by the one or more processors 4220, implements the methods and techniques described herein such as the capture application, the web application, specialized software at the user computer, and web browser software on user computers, etc. Any of the applications and/or components described herein may be expressed as a set of executable program instructions that when executed by the one or more processors 4220, can performed one or more of the functions described in the various embodiments herein. It is understood that such executable program instructions may take the form of machine executable software or firmware, for example, which may interact with one or more hardware components or other software or firmware components.

Thus, external memory device 4270 may optionally be used with the mass storage unit 4250, which may be used for storing code that implements the methods and techniques described herein. However, any of the storage devices, such as the RAM 4240 or mass storage unit 4250, may be used for storing such code. For example, any of such storage devices may serve as a tangible computer storage medium for embodying a computer program for causing a computer or display device to perform the steps of any of the methods, code, and/or techniques described herein. Furthermore, any of the storage devices, such as the RAM 4240 or mass storage unit 4250, may be used for storing any needed database(s). Furthermore, the system 4200 may include external outputs at an output interface 4280 to allow the system to output data or other information to other servers, network components or computing devices in the overall observation capture and analysis system via one or more networks, such as described throughout this application.

In some embodiments, the computer device 4202 represents the basic components of any of the computer devices described herein. For example, the computer device 4202 may represent one or more of the local computer 110, the web application server 120, the content delivery server 140, the remote computers 130 and/or the mobile capture hardware 115 of FIG. 1, for example.

It is understood that any of the various methods described herein may be performed by one or more of the computer devices described herein as well as other computer devices known in the art. That is, in general, one or more of the steps of any of the methods described and illustrated herein may be performed by one or more computer devices such as illustrated in FIG. 42. It is further noted that in some methods, the step of displaying components such as user interface screens and various features and selectable icons, entry features, etc., may be performed by one or more computer devices. For example, some displayed items are initiated by computer devices that function as servers that output user interfaces for display on other computer devices. For example, a server or other computer device may output content and signaling containing code that will instruct a browser or other software local to another computer device to display the content. Such technologies are well known in client-server computer models. Thus, it is understood that any step of displaying a feature, a user interface, content, etc. to a user may also be expressed as outputting the feature, the user interface, content, etc. for display on a computer device for display to a user.

In one embodiment, the present application provides a method for capturing one or more content comprising a panoramic video content, processing the content to create an observation/collection and uploading the collection/observation over a network to a remote database or server for later retrieval. A method is further provided for accessing one or more content collections at a web based application from a remote computer, and viewing content comprising one or more panoramic videos, managing the content collection comprising editing one or more of the content, commenting and tagging the content, editing metadata associated with the content, and sharing the content with one or more users or user groups. Furthermore, a method is provided for viewing and evaluating content uploaded from one or more remote computers and providing comments and/or scores for the content. In one embodiment, the present application provides a method for evaluating a performance of a task, either through a captured video or through direct observation, by entering comments and associating the comments with a performance framework for scoring.

Reference throughout this specification to “one embodiment,” “an embodiment,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

Furthermore, the described features, structures, or characteristics of the invention may be combined in any suitable manner in one or more embodiments. In the following description, numerous specific details are provided, such as examples of programming, software modules, user selections, network transactions, database queries, database structures, hardware modules, hardware circuits, hardware chips, etc., to provide a thorough understanding of embodiments of the invention. One skilled in the relevant art will recognize, however, that the invention can be practiced without one or more of the specific details, or with other methods, components, materials, and so forth. In other instances, well-known structures, materials, or operations are not shown or described in detail to avoid obscuring aspects of the invention.

The following paragraphs provide examples of one or more embodiments provided herein. It is understood that the invention is not limited to these one or more examples and embodiments.

In one embodiment, a computer implemented method for recording of audio for use in remotely evaluating performance of a task by of one or more observed persons, the method comprises: receiving a first audio input from a first microphone recording the one or more observed persons performing the task; receiving a second audio input from a second microphone recording one or more persons reacting to the performance of the task; outputting, for display on a display device, a first sound meter corresponding to the volume of the first audio input; outputting, for display on the display device, a second sound meter corresponding to the volume of the second audio input; providing a first volume control for controlling an amplification level of the first audio input and a second volume control for controlling an amplification level of the second audio input, wherein a first volume of the first audio input and a second volume of the second audio input are amplified volumes, wherein, the first sound meter and the second sound meter each comprises an indicator for suggesting a volume range suitable for recording the one or more observed persons performing the task and the one or more persons reacting to the performance of the task for evaluation.

In another embodiment, a computer system for recording of audio for use in remotely evaluating performance of a task by of one or more observed persons, the system comprises: a computer device comprising at least one processor and at least one memory storing executable program instructions. Upon execution of the executable program instructions by the processor, the computer device is configured to: receive a first audio input from a first microphone recording the one or more observed persons performing the task; receive a second audio input from a second microphone recording one or more persons reacting to the performance of the task; output, to a display device, a first sound meter corresponding to the volume of the first audio input; and output, to the display device, a second sound meter corresponding to the volume of the second audio input, wherein, the first sound meter and the second sound meter each comprises an indicator for suggesting a volume range suitable for recording the one or more observed persons performing the task and the one or more persons reacting to the performance of the task for evaluation.

In another embodiment, a computer system for recording a video for use in remotely evaluating performance of one or more observed persons, the system comprises: a panoramic camera system for providing a first video feed, the panoramic camera system comprising a first camera and a convex mirror, wherein an apex of the convex mirror points towards the first camera; a user terminal for providing a user interface for calibrating a processing of the first video feed; a memory device for storing calibration parameters received through the user interface, wherein the calibration parameters comprise a size and a position of a capture area within the first video feed; and a display device for displaying the user interface and the first video feed, wherein, the calibration parameters stored in the memory device during a first session are read by the user terminal during a second session and applied to the first video feed.

In another embodiment, a computer implemented method for recording a video for use in remotely evaluating performance of one or more observed persons, the system comprises: receiving a first video feed from a panoramic camera system, the panoramic camera system comprising a first camera and a convex mirror, wherein an apex of the convex mirror points towards the first camera; providing a user interface on a display device of a user terminal for calibrating the panoramic camera system; storing calibration parameters received on the user terminal wherein the calibration parameters comprise a size and a position of a capture area of the first video feed; and retrieving the calibration parameters during a subsequent capture session; and applying the calibration parameters to the first video feed.

In another embodiment, a computer implemented method for use in evaluating performance of one or more observed persons, the method comprises: providing a comment field on a display device for a first user to enter free-form comments related to an observation of one or more observed persons performing a task to be evaluated; receiving a free-form comment entered by the first user in the comment field and relating to the observation; storing the free-form comment entered by the first user on a computer readable medium accessible by multiple users; providing a share field to the user for the user to set a sharing setting; and determining whether to display the free-form comment to a second user when the second user accesses stored data relating to the observation based on the sharing setting.

In another embodiment, a computer system for use in evaluating performance of one or more observed persons via a network, the computer system comprises: a computer device comprising at least one processor and at least one memory storing executable program instructions. Wherein, upon execution of the executable program instructions by the processor, the computer device is configured to: provide a comment field for display to a first user for the first user to enter free-form comments related to an observation of the performance of the one or more observed persons performing a task to be evaluated; receive a free-form comment entered by the first user in the comment field and relating to the observation; store the free-form comment entered by the first user on a computer readable medium accessible by multiple users; provide a share field for display to the first user for the first user to set a sharing setting; and determine whether to output the free-form comment for display to a second user when the second user accesses stored data relating to the observation based on the sharing setting.

In another embodiment, a computer implemented method for use in facilitating performance evaluation of one or more observed persons, the method comprising: providing a list of content items for display to a first user on a user interface of a computer device, the content items relating to an observation of the one or more observed persons performing a task to be evaluated, the content items stored on a memory device accessible by multiple users to a first user, wherein the content items comprise at least two of a video recording segment, an audio segment, a still image, observer comments and a text document, wherein the video recording segment, the audio segment and the still image are captured from the one or more observed persons performing the task, wherein the observer comments are from one or more observers of the one or more observed persons, and wherein a content of the text document corresponds to the performance of the task; receiving a selection of two or more content items from the list from the first user to create a collection comprising the two or more content items; providing a share field for display on the user interface to the first user to enter a sharing setting; receiving the sharing setting from the first user; and determining whether to display the collection including the two or more content items to a second user when the second user accesses the memory device based on the sharing setting.

In another embodiment, a computer system for use in evaluating performance of one or more observed persons via a network, the computer system comprises a computer device comprising at least one processor and at least one memory storing executable program instructions. Wherein, upon execution of the executable program instructions by the processor, the computer device is configured to: provide a list of content items for display to a first user on a user interface of a computer device, the content items relating to an observation of the one or more observed persons performing a task to be evaluated, the content items stored on a memory device accessible by multiple users, wherein the content items comprise at least two of a video recording segment, an audio segment, a still image, observer comments and a text document, wherein the video recording segment, the audio segment and the still image are captured from the one or more observed persons performing the task, wherein the observer comments are from one or more observers of the one or more observed persons, and wherein a content of the text document corresponds to the performance of the task; receive a selection of two or more content items from the list from the first user to create a collection comprising the two or more content items; provide a share field for display on the user interface to the first user to enter a sharing setting; receive the sharing setting from the first user; and determine whether to display the collection including the two or more content items to a second user when the second user accesses the memory device based on the sharing setting.

In another embodiment, a computer implemented method for use in remotely evaluating performance of a task by one or more observed persons, the method comprising: receiving a video recording of the one or more persons performing the task to be evaluated by one or more remote persons; storing the video recording on a memory device accessible by multiple users; appending at least one artifact to the video recording, the at least one artifact comprising one or more of a time-stamped comment, a text document, and a photograph; providing a share field for display to a first user for entering a sharing setting; receiving an entered sharing setting from the first user; storing the entered sharing setting; and determining whether to make available the video recording and the at least one artifact to a second user when the second user accesses the memory device based on the entered sharing setting.

In another embodiment, a computer system for use in remotely evaluating performance of one or more observed persons via a network, the computer system comprises a computer device comprising at least one processor and at least one memory storing executable program instructions. Wherein, upon execution of the executable program instructions by the processor, the computer device is configured to: receive a video recording of the one or more persons performing the task to be evaluated by one or more remote persons; store the video recording on a memory device accessible by multiple users; append at least one artifact to the video recording, the at least one artifact comprising one or more of a time-stamped comment, a text document, and a photograph; provide a share field for display to a first user for entering a sharing setting; receive an entered sharing setting from the first user; store the entered sharing setting; and determine whether to make available the video recording and at least one artifact to a second user when the second user accesses the memory device based on the entered sharing setting.

In another embodiment, a computer implemented method for customizing a performance evaluation rubric for evaluating performance of one or more observed persons performing a task, the method comprising: providing a user interface for display on a computer device and for allowing entry of at least a portion of a custom performance rubric by a first user; receiving, via the user interface, a plurality of first level identifiers belonging to a first hierarchical level of a custom performance rubric being implemented to evaluate the performance of the task by the one or more observed persons based at least on an observation of the performance of the task; storing the plurality of first level identifiers; receiving, via the user interface, one or more lower level identifiers belonging to one or more lower hierarchical levels of the custom performance rubric, wherein each lower level identifier is associated with at least one of the plurality of first level identifiers or at least one other lower level identifier, wherein the first level identifiers and the lower identifiers of the custom performance rubric correspond to a set of desired performance characteristics specifically associated with performance of the task; storing the one or more lower level identifiers; receiving a comment related to the observation of the performance of the task by the one or more observed persons; outputting the plurality of first level identifiers for display to a second user for selection; receiving a selected first level identifier from the second user; outputting a subset of the plurality of lower level identifiers that is associated with the selected first level identifier for display to the second user; receiving an indication to correspond the comment to a selected lower level identifier; and assigning the selected lower level identifier to the comment evaluating performance of the one or more observed persons.

In another embodiment, a computer system for facilitating evaluating performance of a task by one or more observed persons, the computer system comprises a computer device comprising at least one processor and at least one memory storing executable program instructions. Wherein, upon execution of the executable program instructions by the processor, the computer device is configured to: provide a user interface for display on a display device and for allowing entry of at least a portion of a custom performance rubric by a first user; receive, via the user interface, a plurality of first level identifiers belonging to a first hierarchical level of a custom performance rubric being implemented to evaluate the performance of the task by the one or more observed persons based at least on an observation of the performance of the task; store the plurality of first level identifiers; receive, via the user interface, one or more lower level identifiers belonging to one or more lower hierarchical levels of the custom performance rubric, wherein each lower level identifier is associated with at least one of the plurality of first level identifiers, or at least one other lower level identifier, wherein the first level identifiers and the lower identifiers of the custom performance rubric correspond to a set of desired performance characteristics specifically associated with performance of the task; store the one or more lower level identifiers; receive a comment related to the observation of the performance of the task by the one or more observed persons; output for display, the plurality of first level identifiers to a second user for selection; receive a selected first level identifier from the second user; output for display to the second user, a subset of the plurality of lower level identifiers that is associated with the selected first level identifier; receive an indication to correspond the comment to a selected lower level identifier; and assign the selected lower level identifier to the comment evaluating performance of the one or more observed persons.

In another embodiment, a computer implemented method for use in evaluating performance of a task by one or more observed persons, the method comprising: outputting a plurality of rubrics for display on a user interface of a computer device, each rubric comprising a plurality of first level identifiers; each of the plurality first level identifiers comprising a plurality of second level identifiers, wherein each of the plurality of rubrics comprise a plurality of nodes and each node corresponds to a pre-defined desired performance characteristic associated with performance of the task, the task to be performed by the one or more observed persons based at least on an observation of the performance of the task; allowing, via the user interface, selection of a selected rubric and a selected first level identifier associated with the selected rubric; receiving the selected rubric and the selected first level identifier; outputting selectable indicators for a subset of the plurality of second level identifiers associated to the selected first level identifier for display on the user interface, while also outputting selectable indicators for other ones of the plurality of rubrics and outputting selectable indicators for other ones of the plurality of first level identifiers for display on the user interface; and allowing the user to select any one of the selectable indicators to display second level identifiers associated with the selected indicator.

In another embodiment, a computer system for facilitating evaluating performance of a task by one or more observed persons, the computer system comprising: a computer device comprising at least one processor and at least one memory storing executable program instructions; wherein, upon execution of the executable program instructions by the processor, the computer device is configured to: output for display on a display device, a plurality of rubrics on a user interface of a computer device, each rubric comprising a plurality of first level identifiers; each of the plurality first level identifiers comprising a plurality of second level identifiers, wherein each of the plurality of rubrics comprise a plurality of nodes and each node corresponds to a pre-defined desired performance characteristic associated with performance of the task, the task to be performed by the one or more observed persons based at least on an observation of the performance of the task; allow, via the user interface, selection of a selected rubric and a selected first level identifier associated with the selected rubric; receive the selected rubric and the selected first level identifier; output for display on the display device, selectable indicators for a subset of the plurality of second level identifiers associated to the selected first level identifier, while also outputting selectable indicators for other ones of the plurality of rubrics and outputting selectable indicators for other ones of the plurality of first level identifiers for display on the user interface; and allow the user to select any one of the selectable indicators to display second level identifiers associated with the selected indicator.

In another embodiment, a computer-implemented method for creation of a performance rubric for evaluating performance of one or more observed persons performing a task, the method comprising: providing a user interface for display on a computer device and for allowing entry of at least a portion of a custom performance rubric by a first user; receiving machine readable commands from the first user describing a custom performance rubric hierarchy comprising a pre-defined set of desired performance characteristics specifically associated with performance of the task based at least on an observation of the performance of the task, wherein command strings are used to define a plurality of first level identifiers belonging to a first level of the custom performance rubric hierarchy and a plurality of second level identifiers belonging to a second level of the custom performance rubric hierarchy, wherein each of the plurality of second identifiers is associated with at least one of the plurality of first level identifiers; outputting the plurality of first level identifiers for display to a second user for selection; receiving a selected first level identifier from the second user; providing an subset of second level identifiers associated with the selected first level identifier from the plurality of second level identifiers to the second user for selection; and receiving a selected second level identifier.

In another embodiment, a computer system for use in evaluating performance of one or more observed persons via a network, the computer system comprising: a computer device comprising at least one processor and at least one memory storing executable program instructions; and wherein, upon execution of the executable program instructions by the processor, the computer device is configured to: provide a user interface for display on a computer device and for allowing entry of at least a portion of a custom performance rubric by a first user; receive machine readable commands from the first user describing a custom performance rubric hierarchy comprising a pre-defined set of desired performance characteristics specifically associated with performance of the task based at least on an observation of the performance of the task, wherein command strings are used to define a plurality of first level identifiers belonging to a first level of the custom performance rubric hierarchy and a plurality of second level identifiers belonging to a second level of the custom performance rubric hierarchy, wherein each of the plurality of second identifiers is associated with at least one of the plurality of first level identifiers; output the plurality of first level identifiers for display to a second user for selection; receiving a selected first level identifier from the second user; provide an subset of second level identifiers associated with the selected first level identifier from the plurality of second level identifiers to the second user for selection; and receive a selected second level identifier.

In another embodiment, a computer implemented method for facilitating performance evaluation of a task by one or more observed persons, the method comprising: creating an observation workflow associated with the performance evaluation of the task by the one or more observed persons and stored on a memory device; associating a first observation to the workflow, the first observation comprising any one of a direct observation of the performance of the task, a multimedia captured observation of the performance of the task, and a walkthrough survey of the performance of the task; providing, through a user interface of a first computer device, a list of selectable steps to a first user, wherein each step is a step to be performed to complete the first observation; receiving a step selection from the first user selecting one or more steps from the list of selectable steps; associating a second user to the workflow; and sending a first notification of the one or more steps to the second user through the user interface.

In another embodiment, a computer system for use in facilitating evaluating performance of one or more observed persons via a network, the computer system comprising: a computer device comprising at least one processor and at least one memory storing executable program instructions; and wherein, upon execution of the executable program instructions by the processor, the computer device is configured to: create an observation workflow associated with the performance evaluation of the task by the one or more observed persons and stored on a memory device; associate a first observation to the workflow, the first observation comprising any one of a direct observation of the performance of the task, a multimedia captured observation of the performance of the task, and a walkthrough survey of the performance of the task; provide, through a user interface of a first computer device, a list of selectable steps to a first user, wherein each step is a step to be performed to complete the first observation; receive a step selection from the first user selecting one or more steps from the list of selectable steps; associate a second user to the workflow; and send a first notification of the one or more steps to the second user through the user interface.

In another embodiment, a computer-implemented method for facilitating performance evaluation of a task by one or more observed persons, the method comprising: providing a user interface accessible by one or more users at one or more computer devices; allowing, via the user interface, a video observation to be assigned to a workflow, the video observation comprising a video recording of the task being performed by the one or more observed persons; allowing, via the user interface, a direct observation to be assigned to the workflow, the direct observation comprises data collected during a real-time observation of the performance of the task by the one or more observed persons; and allowing, via the user interface, a walkthrough survey to be assigned to the workflow, the walkthrough survey comprises general information gathered at a setting in which the one or more observed persons perform the task; and storing an association of at least two of an assigned video observation, an assigned direct observation, and an assigned walkthrough survey to the workflow.

In another embodiment, a computer system for use in facilitating evaluating performance of one or more observed persons via a network, the computer system comprising: a computer device comprising at least one processor and at least one memory storing executable program instructions; and wherein, upon execution of the executable program instructions by the processor, the computer device is configured to: provide a user interface accessible by one or more users at one or more computer devices; allow, via the user interface, a video observation to be assigned to a workflow, the video observation comprising a video recording of the task being performed by the one or more observed persons; allow, via the user interface, a direct observation to be assigned to the workflow, the direct observation comprises data collected during a real-time observation of the performance of the task by the one or more observed persons; and allow, via the user interface, a walkthrough survey to be assigned to the workflow, the walkthrough survey comprises general information gathered at a setting in which the one or more observed persons perform the task; and store an association of at least two of an assigned video observation, an assigned direct observation, and an assigned walkthrough survey to the workflow.

In another embodiment, a computer-implemented method for facilitating performance evaluation of a task by one or more observed persons, the method comprising: providing a user interface accessible by one or more users at one or more computer devices; associating, via the user interface, a plurality of observations of the one or more observed persons performing the task to an evaluation of the task, wherein each of the plurality of observations is a different type of observation; associating a plurality of different performance rubrics to the evaluation of the task; and receiving an evaluation of the performance of the task based on the plurality of observations and the plurality of rubrics.

In another embodiment, a computer-implemented method for use in evaluating performance of a task by one or more observed persons, the method comprising: outputting for display through a user interface on a display device, a plurality of rubric nodes to the first user for selection, wherein each rubric node corresponds to a desired characteristic for the performance of the task performed by the one or more observed persons; receiving, through an input device, a selected rubric node of the plurality of rubric nodes from the first user; outputting for display on the display device, a plurality of scores for the selected rubric nodes to the first user for selection, wherein each of the plurality of scores corresponds to a level at which the task performed satisfies the desired characteristics; receiving, through the input device, a score selected for the selected rubric node from the user, wherein the score is selected based on an observation of the performance of the task; and providing a professional development resource suggestion related to the performance of the task based at least on the score.

In another embodiment, a computer system for use in evaluating performance of one or more observed persons via a network, the computer system comprising: a computer device comprising at least one processor and at least one memory storing executable program instructions; and wherein, upon execution of the executable program instructions by the processor, the computer device is configured to: output for display on a user interface on a display device, a plurality of rubric nodes to the first user for selection, wherein each rubric node corresponds to a desired characteristic for the performance of the task performed by the one or more observed persons; receive, from an input device, a selected rubric node of the plurality of rubric nodes from the first user; output for display on the user interface of the display device, a plurality of scores for the selected rubric nodes to the first user for selection, wherein each of the plurality of scores corresponds to a level at which the task performed satisfies the desired characteristics; receive a score selected for the selected rubric node from the user, wherein the score is selected based on an observation of the performance of the task; and provide a professional development resource suggestion related to the performance of the task based at least on the score.

In another embodiment, a computer-implemented method for facilitating performance evaluation of one or more observed persons performing a task, the method comprising: receiving, through a computer user interface, at least two of multimedia captured observation scores, direct observation scores, and walkthrough survey scores corresponding to one or more observed persons performing a task to be evaluated, wherein the multimedia captured observation scores comprise scores assigned resulting from playback of a stored multimedia observation of the performance of the task, wherein the direct observation scores comprise scores assigned based on a real-time observation of the performance of the one or more observed persons performing the task, and the walkthrough survey scores comprise scores based on general information gathered at a setting in which the one or more observed persons performed the task; and generating a combined score set by combining, using computer implemented logics, the at least two of the multimedia captured observation scores, the direct observation scores, and the walkthrough survey scores.

In another embodiment, a computer system for use in evaluating performance of one or more observed persons via a network, the computer system comprising: a computer device comprising at least one processor and at least one memory storing executable program instructions; and wherein, upon execution of the executable program instructions by the processor, the computer device is configured to: receive, through a computer user interface, at least two of multimedia captured observation scores, direct observation scores and walkthrough survey scores corresponding to one or more observed persons performing a task to be evaluated, wherein the multimedia captured observation scores comprise scores assigned resulting from playback of a stored multimedia observation of the performance of the task, wherein the direct observation scores comprise scores assigned based on a real-time observation of the performance of the one or more observed persons performing the task, and the walkthrough survey scores comprise scores based on general information gathered at a setting in which the one or more observed persons performed the task; and generate a combined score set by combining, using computer implemented logics, the at least two of the multimedia captured observation scores, the direct observation scores, and the walkthrough survey scores.

In another embodiment, a computer-implemented method for facilitating an evaluation of performance of one or more observed persons performing a task, the method comprising: receiving, via a user interface of one or more computer devices, at least one of: (a) video observation scores comprising scores assigned during a video observation of the performance of the task; (b) direct observation scores comprising scores assigned during a real-time observation of the performance of the task; (c) captured artifact scores comprising scores assigned to one or more artifacts associated with the performance of the task; and (d) walkthrough survey scores comprising scores based on general information gathered at a setting in which the one or more observed persons performed the task; receiving, via the user interface, reaction data scores comprising scores based on data gathered from one or more persons reacting to the performance of the task; and generating a combined score set by combining, using computer implemented logics, the reaction data scores and the at least one of the video observation scores, the direct observation scores, the captured artifact scores and the walkthrough survey scores.

In another embodiment, a computer system for use in remotely evaluating performance of one or more observed persons via a network, the computer system comprises: a computer device comprising at least one processor and at least one memory storing executable program instructions; and wherein, upon execution of the executable program instructions by the processor, the computer device is configured to: receive, via a user interface of one or more computer devices, at least one of: (a) video observation scores comprising scores assigned during a video observation of the performance of the task; (b) direct observation scores comprising scores assigned during a real-time observation of the performance of the task; (c) captured artifact scores comprising scores assigned to one or more artifacts associated with the performance of the task; and (d) walkthrough survey scores comprising scores based on general information gathered at a setting in which the one or more observed persons performed the task; receive, via the user interface, reaction data scores comprising scores based on data from one or more persons reacting to the performance of the task; and generate a combined score set by combining, using computer implemented logics, the reaction data scores and the at least one of the video observation scores, the direct observation scores, the captured artifact scores and the walkthrough survey scores.

In another embodiment, a computer implemented method for use in developing a professional development library relating to the evaluation of the performance of a task by one or more observed persons, the method comprising: receiving, at a processor of a computer device, one or more scores associated with a multimedia captured observation of the one or more observed persons performing the task; determining by the processor and based at least in part on the one or more scores, whether the multimedia captured observation exceeds an evaluation score threshold indicating that the multimedia captured observation represents a high quality performance of at least a portion of the task; determining, in the event the multimedia captured observation exceeds the evaluation score threshold, whether the multimedia captured observation will be added to the professional development library; and storing the multimedia captured observation to the professional development library such it can be remotely accessed by one or more users.

In another embodiment, a computer system for use in developing a professional development library relating to the evaluation of the performance of a task by one or more observed persons, the computer system comprises: a computer device comprising at least one processor and at least one memory storing executable program instructions; and wherein, upon execution of the executable program instructions by the processor, the computer device is configured to: receive, at a processor of a computer device, one or more scores associated with a multimedia captured observation of the one or more observed persons performing the task; determine by the processor and based at least in part on the one or more scores, whether the multimedia captured observation exceeds an evaluation score threshold indicating that the multimedia captured observation represents a high quality performance of at least a portion of the task; determine, in the event the multimedia captured observation exceeds the evaluation score threshold, whether the multimedia captured observation will be added to the professional development library; and store the multimedia captured observation to the professional development library such it can be remotely accessed by one or more users.

While the invention herein disclosed has been described by means of specific embodiments, examples and applications thereof, numerous modifications and variations could be made thereto by those skilled in the art without departing from the scope of the invention set forth in the claims.

What is claimed is:

1. A computer implemented method for recording of audio for use in remotely evaluating performance of a task by of one or more observed persons, the method comprising:
receiving a first audio input from a first microphone recording the one or more observed persons performing the task;
receiving a second audio input from a second microphone recording one or more persons reacting to the performance of the task;
outputting, for display on a display device, a first sound meter corresponding to the volume of the first audio input;
outputting, for display on the display device, a second sound meter corresponding to the volume of the second audio input;
providing a first volume control for controlling an amplification level of the first audio input and a second volume control for controlling an amplification level of the second audio input,
wherein a first volume of the first audio input and a second volume of the second audio input are amplified volumes,
wherein, the first sound meter and the second sound meter each comprises an indicator for suggesting a volume range suitable for recording the one or more observed persons performing the task and the one or more persons reacting to the performance of the task for evaluation.

2. The method of claim 1, wherein the indicators for suggesting the volume comprise text descriptions describing a volume suitability of the first audio input and the second audio input.

3. The method of claim 1, wherein the indicators for suggesting the volume range comprise a color coded visual representation of volume ranges.

4. The method of claim 1, further comprising:
providing a test audio module for recording a test audio segment for playback.

5. The method of claim 1, wherein a first volume of the first audio input and a second volume of the second audio input are amplified volumes, and default amplification levels are initially applied to the first audio input and the second audio input.

6. The method of claim 5 wherein the default amplification level of the first audio input is higher than the default amplification level of the second audio input.

7. The method of claim 1 wherein the first audio input has a first default sensitivity level specific to the fact that the first microphone is recording the one or more observed persons performing the task, and wherein second audio input has a second default sensitivity specific to the fact that the second microphone is recording the one or more persons reacting to the performance of the task.

8. A computer system for recording a video for use in remotely evaluating performance of one or more observed persons, the system comprising:
a panoramic camera system for providing a first video feed, the panoramic camera system comprising a first camera and a convex mirror, wherein an apex of the convex mirror points towards the first camera;
a user terminal for providing a user interface for calibrating a processing of the first video feed;
a memory device for storing calibration parameters received through the user interface, wherein the calibration parameters comprise a size and a position of a capture area within the first video feed; and
a display device for displaying the user interface and the first video feed,
wherein, the calibration parameters stored in the memory device during a first session are read by the user terminal during a second session and applied to the first video feed.

9. The system for claim 8, further comprising:
a user input device for a user to set the size and the position of the capture area of the first video feed.

10. The system of claim 9, wherein the user input device controls a pointer on the display screen, the user uses the cursor to resize and to position the capture area.

11. The system of claim 8, wherein the display device further displays a representation of the capture area of the first video feed overlaying the first video feed.

12. The system of claim 8, wherein:
the display device further displays controls for adjusting a brightness setting and a focus setting of the first video feed;
the memory device further stores the brightness setting and the focus setting of the first video feed during the first session; and
and the brightness setting and the focus setting are applied to the first video feed during the second session.

13. The system of claim 8, further comprising:
a second camera for providing a second video feed to the user terminal.

14. The system of claim 13, wherein the memory device further stores a brightness setting, a focus setting, and a zoom setting of the second video feed during the first session, and applies the brightness setting, the focus setting, and the zoom setting to the second video feed during the second session.

15. The system of claim 8, wherein:
the user terminal is able to analyze the first video feed and automatically calibrate the size and the position of the capture area of the first video feed.
